(19) United States
(12) Patent Application Publication
(10) Pub. No.: US 2015/0166888 A1
(43) Pub. Date: Jun. 18, 2015

(54) LIGHT-EMITTING DEVICE, WAVELENGTH CONVERSION MEMBER, PHOSPHOR COMPOSITION AND PHOSPHOR MIXTURE

(71) Applicants: MITSUBISHI CHEMICAL CORPORATION, Chiyoda-ku (JP); MITSUBISHI ENGINEERING-PLASTICS CORPORATION, Minato-ku (JP)

(72) Inventors: Tadahiro Katsumoto, Yokohama-shi (JP); Minoru Soma, Yokohama-shi (JP); Tomoyuki Kurushima, Yokohama-shi (JP); Hisashi Yoshida, Yokohama-shi (JP)

(73) Assignees: MITSUBISHI CHEMICAL CORPORATION, Chiyoda-ku (JP); MITSUBISHI ENGINEERING-PLASTICS CORPORATION, Minato-ku (JP)

(21) Appl. No.: 14/594,981

(22) Filed: Jan. 12, 2015

Related U.S. Application Data
(63) Continuation of application No. PCT/JP2013/069607, filed on Jul. 19, 2013.

(30) Foreign Application Priority Data
Jul. 20, 2012 (JP) 2012-161508
Nov. 30, 2012 (JP) 2012-262614
Mar. 5, 2013 (JP) 2013-043101
Jul. 1, 2013 (JP) 2013-138464

(51) Int. Cl. C09K 11/77; H01L 33/50

(52) U.S. Cl. CPC C09K 11/7774; H01L 33/502

(57) ABSTRACT

Provided is a light-emitting device having good binning characteristics with suppressed changes in color derived from shifts in excitation wavelength.

The present invention achieves the above object by way of a light-emitting device that comprises a blue semiconductor light-emitting element, and a wavelength conversion member, wherein the wavelength conversion member comprises:
a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)
(x=3, 4.5≦y≦5.5, 10.85≦z≦13.4); and
a phosphor G represented by formula (G1) below and having a peak wavelength of 520 nm or more and 540 nm or less in an emission wavelength spectrum when excited at 450 nm.

(Y,Ce,Tb,Lu)ₓ(Ga,Sc,Al)_{y}O_{z} (G1)
(x=3, 4.5≦y≦5.5, 10.8≦z≦13.4)

### CROSS-REFERENCE TO RELATED APPLICATION

This is a continuation of International Application PCT/JP2013/069607, filed on Jul. 20, 2013, and designated the U.S., (and claims priority from Japanese Patent Application 2012-161508 which was filed on Jul. 20, 2012, Japanese Patent Application 2012-262614 which was filed on Nov. 30, 2012, Japanese Patent Application 2013-043101 which was filed on Mar. 5, 2013 and Japanese Patent Application 2013-138464 which was filed on Jul. 1, 2013) the entire contents of which are incorporated herein by reference.

### TECHNICAL FIELD

The present invention relates to a light-emitting device, and more particularly, to a light-emitting device comprising a blue semiconductor light-emitting element. The present invention also relates to a wavelength conversion member provided in a light-emitting device.

### BACKGROUND ART

Light-emitting devices that utilize semiconductor light-emitting elements are becoming ever more pervasive as energy-saving light-emitting devices. The ongoing development of light-emitting devices that utilize semiconductor light-emitting elements, however, has brought in its wake various problems.

For instance, Patent Document 1 acknowledges the problem of occurrence of color unevenness, in illumination light, as lighting time wears on. To address this problem, it has been proposed (Patent Document 1) to provide two types of phosphor that emit visible light of identical color, but where the gradients of the excitation spectra of the two phosphors are set to be opposite to each other at the emission peak wavelength of the semiconductor light-emitting element.

Meanwhile, Patent Document 2, which deals with the issue of “LED binning”, discloses a multi-cell LED circuit that has a plurality of impedance elements and a plurality of cells having a binning class that depends on emission wavelength characteristics and luminance characteristics (Patent Document 2).

Patent Document 3 discloses the feature of binning LEDs, from the viewpoint of any one parameter from among the peak wavelength of light, the peak intensity of light, and forward voltage, and discloses, in particular, a “smart” phosphor composition that enables self-adjustment of chromaticity in response to variations in LED excitation wavelength (Patent Document 3).

In addition, Patent Document 4 discloses a semiconductor light-emitting device in which chromaticity variations are reduced with respect to variations in the peak wavelength of a semiconductor light-emitting element. Specifically, Patent Document 4 discloses a semiconductor light-emitting device having a first phosphor the excitation intensity whereof increases with increasing wavelength, and a second phosphor the excitation intensity whereof remains flat or decreases with increasing wavelength, in the vicinity of the peak wavelength of the semiconductor light-emitting element (Patent Document 4).

### CITATION LIST

Patent Document 1: Japanese Patent Application Laid-open No. 2005-228833
Patent Document 2: Japanese Patent Application Domestic Laid-open No. 2009-503831
Patent Document 3: Japanese Patent Application Domestic Laid-open No. 2010-500444
Patent Document 4: Japanese Patent Application Laid-open No. 2008-135725

### SUMMARY OF INVENTION

### Technical Problem

Although LED binning is pointed out in several citations, the latter lack specific proposals that are conducive to practical use. The inventors have studied combinations of phosphors in the above citations. Against this background, Patent Document 3 attempts to solve a relevant problem through addition of an orange phosphor to a yellow phosphor, but chromaticity changes fail to be suppressed, and this approach is insufficient for practical application. Patent Document 4 attempts to curtail chromaticity changes by combining a yellow phosphor with an orange phosphor, but the resulting color rendering properties and emission efficiency are insufficient.

To solve such problems, it is an object of the present invention to provide a light-emitting device having binning characteristics that are amenable to practical use, while preserving sufficient color rendering properties and emission efficiency. The present invention relates also to a phosphor composition capable of forming a wavelength conversion member that allows providing a light-emitting device having binning characteristics amenable to practical use, when the wavelength conversion member is used in a light-emitting device, and relates further to a wavelength conversion member that is obtained through molding of the phosphor composition.

As a result of diligent research aimed at solving the above problems, the inventors found that a light-emitting device can be provided that has sufficient binning characteristics, by using a wavelength conversion member that contains a yellow phosphor and a green phosphor, a wavelength conversion member that contains no yellow phosphor but contains a specific green phosphor, or a wavelength conversion member that contains a specific yellow-green phosphor, in a light-emitting device that utilizes a blue semiconductor light-emitting element, and perfected the present invention on the basis of that finding.

The present invention includes the first to fourth inventions below.

The first invention of the present invention is an invention relating to a light-emitting device. A first embodiment of the first invention is as follows.

A light-emitting device comprising a blue semiconductor light-emitting element, and a wavelength conversion member,

wherein the wavelength conversion member comprises:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4); and

a phosphor G represented by formula (G1) below and having a peak wavelength of 520 nm or more and 540 nm or less in an emission wavelength spectrum when excited at 450 nm.

(Y,Ce,Tb,Lu)ₓ(Ga,Sc,Al)_{y}O_{z} (G1)

(x=3, 4.5≦y≦5.5, 10.8≦z≦13.4)

As a second embodiment, preferably,

a variation in excitation spectrum intensity of the wavelength conversion member at an emission wavelength of 540 nm is equal to or smaller than 0.25.

The variation in excitation spectrum intensity of the wavelength conversion member is expressed as the difference between a maximum value and a minimum value of excitation spectrum intensity in the range from 435 nm to 465 nm, taking 1.0 as the excitation spectrum intensity of the wavelength conversion member at 450 nm.

As a third embodiment, preferably,

the phosphor Y is a phosphor represented by formula (Y2) below,

the phosphor G is a phosphor represented by formula (G2) below, and

the variation in excitation spectrum intensity of the wavelength conversion member at an emission wavelength of 540 nm is equal to or smaller than 0.23.

Yₐ(Ce,Tb,Lu)_{b}(Ga,Sc)_{c}Al_{d}Oₑ (Y2)

(a+b=3, 0≦b≦0.2, 4.5≦c+d≦5.5, 0≦c≦0.2, 10.8≦e≦13.4)

Yₐ(Ce,Tb,Lu)_{b}(Ga,Sc)_{c}Al_{d}Oₑ (G2)

(a+b=3, 0≦b≦0.2, 4.5≦c+d≦5.5, 1.2≦c≦2.6, 10.8≦e≦13.4)

The variation in excitation spectrum intensity of the wavelength conversion member is expressed as the difference between a maximum value and a minimum value of excitation spectrum intensity in the range from 435 nm to 470 nm, taking 1.0 as the excitation spectrum intensity of the wavelength conversion member at 450 nm.

As a fourth embodiment, preferably,

the phosphor Y is a phosphor represented by formula (Y3) below,

the phosphor G is a phosphor represented by formula (G3) below, and

the variation in excitation spectrum intensity of the wavelength conversion member at an emission wavelength of 540 nm is equal to or smaller than 0.33.

Yₐ(Ce,Tb,Lu)_{b}(Ga,Sc)_{c}Al_{d}Oₑ (Y3)

(a+b=3, 0≦b≦0.2, 4.5≦c+d≦5.5, 0≦c≦0.2, 10.8≦e≦13.4)

Lu_{f}(Ce,Tb,Y)_{g}(Ga,Sc)ₕAlᵢOⱼ (G3)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

In the third and fourth embodiments, preferably,

the variation in combined excitation spectrum intensity combined by calculation expression (Z) below is equal to or smaller than 0.15,

the combined excitation spectrum being an excitation spectrum in which the excitation spectrum intensity at each wavelength is expressed by calculation expression (Z) below.

Combined excitation spectrum intensity=(excitation spectrum intensity of phosphor Y)×(weight fraction of phosphor Y)+(excitation spectrum intensity of phosphor G)×(weight fraction of phosphor G) (Z)

The weight fraction of the phosphor Y is given by phosphor Y/(phosphor Y+phosphor G).

The same applies to the variation in combined excitation spectrum intensity of the phosphor G and to the weight fraction of the phosphor G.

The each variation in excitation spectrum intensity is expressed as the difference between a maximum value and a minimum value of the combined excitation spectrum intensity in the range from 430 nm to 470 nm, taking 1.0 as the excitation spectrum intensity at 450 nm in the excitation spectrum.

In the light-emitting device of the first to fourth embodiments described above, preferably,

the excitation spectrum intensity at 430 nm of the phosphor Y is smaller than the excitation spectrum intensity at 470 nm, in the excitation spectrum for an emission wavelength of 540 nm, and the excitation spectrum intensity at 430 nm of the phosphor G is greater than the excitation spectrum intensity at 470 nm, in the excitation spectrum for an emission wavelength of 540 nm.

The light-emitting device of the first to fourth embodiments described above, preferably, further comprises a blue-green phosphor represented by formula (B1) below and having a peak wavelength of 500 nm or more and 520 nm or less in an emission wavelength spectrum when excited at 450 nm.

(Y,Ce,Tb,Lu)ₓ(Ga,Sc,Al)_{y}O_{z} (B1)

(x=3, 4.5≦y≦5.5, 10.8≦z≦13.4)

In the light-emitting device of the first to fourth embodiments described above, preferably, a composition ratio of the phosphor Y and the phosphor G is 10:90 or more and 90:10 or less.

A fifth embodiment of the first invention is as follows.

A light-emitting device comprising a blue semiconductor light-emitting element, and a wavelength conversion member,

wherein the wavelength conversion member comprises:

a phosphor G represented by formula (G4) below and having a peak wavelength of 520 nm or more and 540 nm or less in an emission wavelength spectrum when excited at 450 nm, and

the variation in excitation spectrum intensity of the wavelength conversion member at an emission wavelength of 540 nm is equal to or smaller than 0.33.

Lu_{f}(Ce,Tb,Y)_{g}(Ga,Sc)ₕAlᵢOⱼ (G4)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

In the light-emitting device according to the first to fifth embodiments, preferably,

when the emission wavelength of the blue semiconductor light-emitting element is caused to vary continuously from 445 nm to 455 nm, a chromaticity change Δu′v′ of light emitted by the light-emitting device satisfies Δu′v′≦0.004.

The value Δu′v′ denotes a distance between chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

In the first to fifth embodiments, preferably,

when the emission wavelength of the blue semiconductor light-emitting element is caused to vary continuously from 435 nm to 470 nm, a chromaticity change Δu′v′ of light emitted by the light-emitting device satisfies Δu′v′≦0.015.

The value Δu′v′ denotes a distance between chromaticity (u′ᵢ,v′ᵢ) at any wavelength i nm from 435 nm to 470 nm and an average value (u′ₐᵥₑ,v′ₐᵥₑ) of chromaticity at 435 nm to 470 nm.

In the first to fifth embodiments, preferably,

a red phosphor is further incorporated. Preferably, the red phosphor includes a red phosphor having an emission peak wavelength of 600 nm or more and less than 640 nm, and a full width at half maximum of 2 nm or more and 120 nm or less, at a content of 30% or greater in a composition weight ratio with respect to a total amount of red phosphor.

Preferably, the red phosphor having an emission peak wavelength of 600 nm or more and less than 640 nm, and a full width at half maximum of 2 nm or more and 120 nm or less is (Sr,Ca)AlSiN₃:Eu or Ca₁₋ₓAl₁₋ₓSi₁₊ₓN₃₋ₓOₓ:Eu (where 0≦x≦0.5).

A red phosphor having an emission peak wavelength of 640 nm or more and 670 nm or less and a full width at half maximum of 2 nm or more and 120 nm or less is preferably incorporated as the red phosphor.

Preferably, light emitted by the light-emitting device exhibits a deviation duv from a black body radiation locus of light color ranging from −0.0200 to 0.0200, and a color temperature of 1800 K or more and 7000 K or less. Yet more preferably, the color temperature is 2500 or more and 3500 K or less. Preferably, the average color rendering index Ra is 80 or greater.

A sixth embodiment of the first invention is as follows.

A light-emitting device, comprising a blue semiconductor light-emitting element, and a wavelength conversion member,

wherein the wavelength conversion member comprises a yellow-green phosphor represented by formula (YG1) below and having a peak wavelength of 530 nm or more and 550 nm or less in an emission wavelength spectrum when excited at 450 nm, and

the variation in excitation spectrum intensity of the wavelength conversion member at an emission wavelength of 540 nm is equal to or smaller than 0.25.

(Y,Ce,Tb,Lu)ₓ(Ga,Sc,Al)_{y}O_{z} (YG1)

(x=3, 4.5≦y≦5.5, 10.8≦z≦13.4)

The variation in excitation spectrum intensity of the wavelength conversion member is expressed as the difference between a maximum value and a minimum value of excitation spectrum intensity in the range from 430 nm to 470 nm, taking 1.0 as the excitation spectrum intensity of the wavelength conversion member at 450 nm.

Preferably, the variation in excitation spectrum intensity of the yellow-green phosphor is equal to or smaller than 0.13. The variation in excitation spectrum intensity of the yellow-green phosphor is expressed as the difference between a maximum value and a minimum value of the excitation spectrum intensity in the range from 430 nm to 465 nm, taking 1.0 as the excitation spectrum intensity of the yellow-green phosphor at 450 nm.

Preferably, when the emission wavelength of the blue semiconductor light-emitting element is caused to vary continuously from 445 nm to 455 nm, a chromaticity change Δu′v′ of light emitted by the light-emitting device satisfies Δu′v′50.005. The value Δu′v′ denotes a distance between chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

Preferably, the yellow-green phosphor is the yellow-green phosphor represented by formula (YG2) below.

MₐA_{b}E_{c}Al_{d}Oₑ (YG2)

(where M is Ce; A is one, two or more elements selected from the group of Y and Lu, such that the content of Y is 90% or more; E is Ga, or Ga and Sc; and a+b=3, 4.5≦c+d≦5.5, 10.8≦e≦13.2, 0≦a≦0.9, 0.8≦c≦11.2)

Preferably, an excitation spectrum intensity change of the yellow-green phosphor at 440 nm to 460 nm is equal to or smaller than 4.0% of the intensity of the excitation light spectrum at 450 nm.

A seventh embodiment of the first invention is as follows.

A light-emitting device, provided with:

a blue semiconductor light-emitting element; and

a wavelength conversion member comprising a yellow-green phosphor,

wherein the yellow-green phosphor is a phosphor, represented by formula (YG3) below, having a difference equal to or smaller than 0.05 between a maximum value and a minimum value of normalized excitation spectrum intensity at 450 nm, when excited at an excitation wavelength ranging from 440 nm to 460 nm,

(Y,Ce)₃(Ga,Al)_{f}O_{g} (YG3)

(4.5≦f≦5.5, 10.8≦g≦13.2), and

a chromaticity change Δu′v′, from an average chromaticity of light emitted by the wavelength conversion member when excited at an excitation wavelength ranging from 445 nm to 455 nm, is equal to or smaller than 0.005.

The value Δu′v′ denotes the distance between the chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

In the sixth to seventh embodiments, preferably, a red phosphor is further incorporated, and preferably, an excitation spectrum intensity change of the red phosphor at 440 nm to 460 nm is equal to or smaller than 4.0% of the intensity of the excitation light spectrum at 450 nm.

Preferably, the red phosphor includes a red phosphor having an emission peak wavelength ranging from 620 nm to 640 nm, and a full width at half maximum of 2 nm or more and 100 nm or less, at a content of 50% or greater in a composition weight ratio with respect to a total amount of red phosphor. Preferably, the red phosphor is SCASN.

A red phosphor having an emission peak wavelength ranging from 640 nm to 670 nm and a full width at half maximum of 2 nm or more and 120 nm or less is preferably further incorporated as the red phosphor.

In a preferred form, light emitted by the light-emitting device exhibits a deviation duv from a black body radiation locus of light color ranging from −0.0200 to 0.0200, and a color temperature of 1800 K or more and 7000 K or less. In another preferred form, the color temperature of light emitted by the light-emitting device is 7000 K or more and 20000 K or less.

In the sixth to seventh embodiments,

the blue semiconductor light-emitting element and the wavelength conversion member comprising the yellow-green phosphor may be disposed with a space interposed therebetween.

An illumination device comprising any of the foregoing light-emitting devices, and a backlight provided with any of the foregoing light-emitting devices, are likewise preferred inventions.

A second invention of the present invention is an invention relating to a wavelength conversion member. A first embodiment of the second invention is as follows.

A wavelength conversion member, comprising:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4);

a phosphor G represented by formula (G1) below and having a peak wavelength of 520 nm or more and 540 nm or less in an emission wavelength spectrum when excited at 450 nm,

(Y,Ce,Tb,Lu)ₓ(Ga,Sc,Al)_{y}O_{z} (G1)

(x=3, 4.5≦y≦5.5, 10.8≦z≦13.4); and

a transparent material.

As a second embodiment, preferably,

the variation in excitation spectrum intensity at an emission wavelength of 540 nm is equal to or smaller than 0.25.

The variation in excitation spectrum intensity of the wavelength conversion member is expressed as the difference between a maximum value and a minimum value of excitation spectrum intensity in the range from 435 nm to 465 nm, taking 1.0 as the excitation spectrum intensity of the wavelength conversion member at 450 nm.

As a third embodiment, preferably,

the phosphor Y is a phosphor represented by formula (Y2) below,

the phosphor G is a phosphor represented by formula (G2) below, and

the variation in excitation spectrum intensity of the wavelength conversion member at an emission wavelength of 540 nm is equal to or smaller than 0.23.

Yₐ(Ce,Tb,Lu)_{b}(Ga,Sc)_{c}Al_{d}Oₑ (Y2)

(a+b=3, 0≦b≦0.2, 4.5≦c+d≦5.5, 0≦c≦0.2, 10.8≦e≦13.4)

Yₐ(Ce,Tb,Lu)_{b}(Ga,Sc)_{c}Al_{d}Oₑ (G2)

(a+b=3, 0≦b≦0.2, 4.5≦c+d≦5.5, 1.2≦c≦2.6, 10.8≦e≦13.4)

The variation in excitation spectrum intensity of the wavelength conversion member is expressed as the difference between a maximum value and a minimum value of excitation spectrum intensity in the range from 435 nm to 470 nm, taking 1.0 as the excitation spectrum intensity of the wavelength conversion member at 450 nm.

As a fourth embodiment, preferably,

the phosphor Y is a phosphor represented by formula (Y3) below,

the phosphor G is a phosphor represented by formula (G3) below, and

the variation in excitation spectrum intensity of the wavelength conversion member at an emission wavelength of 540 nm is equal to or smaller than 0.33.

Yₐ(Ce,Tb,Lu)_{b}(Ga,Sc)_{c}Al_{d}Oₑ (Y3)

(a+b=3, 0≦b≦0.2, 4.5≦c+d≦5.5, 0≦c≦0.2, 10.8≦e≦13.4)

Lu_{f}(Ce,Tb,Y)_{g}(Ga,Sc)ₕAlᵢOⱼ (G3)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

In the third and fourth embodiments, preferably,

the variation in combined excitation spectrum intensity combined by calculation expression (Z) below is equal to or smaller than 0.15.

The combined excitation spectrum being an excitation spectrum in which the excitation spectrum intensity at each wavelength is expressed by calculation expression (Z) below.

Combined excitation spectrum intensity=(excitation spectrum intensity of phosphor Y)×(weight fraction of phosphor Y)+(excitation spectrum intensity of phosphor G)×(weight fraction of phosphor G) (Z)

The weight fraction of the phosphor Y is given by phosphor Y/(phosphor Y+phosphor G).

The same applies to the variation in combined excitation spectrum intensity of the phosphor G and to the weight fraction of the phosphor G.

The each variation in excitation spectrum intensity is expressed as the difference between a maximum value and a minimum value of the combined excitation spectrum intensity in the range from 430 nm to 470 nm, taking 1.0 as the excitation spectrum intensity at 450 nm in the excitation spectrum.

In the first to fourth embodiments, preferably,

the excitation spectrum intensity at 430 nm of the phosphor Y in the wavelength conversion member described above is smaller than the excitation spectrum intensity at 470 nm, in the excitation spectrum for an emission wavelength of 540 nm, and the excitation spectrum intensity at 430 nm of the phosphor G is greater than the excitation spectrum intensity at 470 nm, in the excitation spectrum for an emission wavelength of 540 nm.

In the first to fourth embodiments, preferably,

the wavelength conversion member described above further comprises a blue-green phosphor represented by formula (B1) below and having a peak wavelength of 500 nm or more and 520 nm or less in an emission wavelength spectrum when excited at 450 nm.

(Y,Ce,Tb,Lu)ₓ(Ga,Sc,Al)_{y}O_{z} (B1)

(x=3, 4.5≦y≦5.5, 10.8≦z≦13.4)

In the first to fourth embodiments, preferably,

a composition ratio of the phosphor Y and the phosphor G in the wavelength conversion member described above is 10:90 or more and 90:10 or less.

A fifth embodiment of the second invention is as follows.

A wavelength conversion member, comprising:

a phosphor G represented by formula (G4) below and having a peak wavelength of 520 nm or more and 540 nm or less in an emission wavelength spectrum when excited at 450 nm; and

a transparent material,

wherein the variation in excitation spectrum intensity of the wavelength conversion member at an emission wavelength of 540 nm is equal to or smaller than 0.33.

Lu_{f}(Ce,Tb,Y)_{g}(Ga,Sc)ₕAlᵢOⱼ (G4)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

In the wavelength conversion member according to the first to fifth embodiments, preferably,

when the excitation wavelength is caused to vary continuously from 445 nm to 455 nm, a chromaticity change Δu′v′ of light emitted by the wavelength conversion member satisfies Δu′v′≦0.004.

The value Δu′v′ denotes a distance between chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

In the first to fifth embodiments, preferably,

when the excitation wavelength is caused to vary continuously from 435 nm to 470 nm, a chromaticity change Δu′v′ of light emitted by the wavelength conversion member satisfies Δu′v′≦0.015.

The value Δu′v′ denotes a distance between chromaticity (u′ᵢ,v′ᵢ) at any wavelength i nm from 435 nm to 470 nm and an average value (u′ₐᵥₑ,v′ₐᵥₑ) of chromaticity at 435 nm to 470 nm.

A sixth embodiment of the second invention is as follows.

A wavelength conversion member, comprising:

a yellow-green phosphor represented by formula (YG1) below and having a peak wavelength of 530 nm or more and 550 nm or less in an emission wavelength spectrum when excited at 450 nm; and

a transparent material.

The variation in excitation spectrum intensity of the wavelength conversion member at an emission wavelength of 540 nm is equal to or smaller than 0.25.

(Y,Ce,Tb,Lu)ₓ(Ga,Sc,Al)_{y}O_{z} (YG1)

(x=3, 4.5≦y≦5.5, 10.8≦z≦13.4)

The variation in excitation spectrum intensity of the wavelength conversion member is expressed as the difference between a maximum value and a minimum value of excitation spectrum intensity in the range from 430 nm to 470 nm, taking 1.0 as the excitation spectrum intensity of the wavelength conversion member at 450 nm.

Preferably, the variation in excitation spectrum intensity of the yellow-green phosphor is equal to or smaller than 0.13. The variation in excitation spectrum intensity of the yellow-green phosphor is expressed as the difference between a maximum value and a minimum value of the excitation spectrum intensity in the range from 430 nm to 465 nm, taking 1.0 as the excitation spectrum intensity of the yellow-green phosphor at 450 nm.

Preferably, when the excitation wavelength is caused to vary continuously from 445 nm to 455 nm, a chromaticity change Δu′v′ of light emitted by the light-emitting device satisfies Δu′v′≦0.005. The value Δu′v′ denotes a distance between chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

Preferably, the yellow-green phosphor is the yellow-green phosphor represented by formula (YG2) below.

MₐA_{b}E_{c}Al_{d}Oₑ (YG2)

(where M is Ce; A is one, two or more elements selected from the group of Y and Lu, such that the content of Y is 90% or more; E is Ga, or Ga and Sc; and a+b=3, 4.5≦c+d≦5.5, 10.8≦e≦13.2, 0≦a≦0.9, 0.8≦c≦1.2)

A third invention of the present invention is an invention relating to a phosphor composition. A first embodiment of the third invention is as follows.

A phosphor composition, comprising:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4);

a phosphor G represented by formula (G1) below and having a peak wavelength of 520 nm or more and 540 nm or less in an emission wavelength spectrum when excited at 450 nm,

(Y,Ce,Tb,Lu)ₓ(Ga,Sc,Al)_{y}O_{z} (G1)

(x=3, 4.5≦y≦5.5, 10.8≦z≦13.4); and

a transparent material.

As a second embodiment, preferably,

upon molding of the phosphor composition to yield a wavelength conversion member, the variation in excitation spectrum intensity of the wavelength conversion member at an emission wavelength of 540 nm is equal to or smaller than 0.25.

The variation in excitation spectrum intensity of the wavelength conversion member is expressed as the difference between a maximum value and a minimum value of excitation spectrum intensity in the range from 435 nm to 465 nm, taking 1.0 as the excitation spectrum intensity of the wavelength conversion member at 450 nm.

As a third embodiment, preferably,

the phosphor Y is a phosphor represented by formula (Y2) below,

the phosphor G is a phosphor represented by formula (G2) below, and

upon molding of the phosphor composition to yield a wavelength conversion member, the variation in excitation spectrum intensity of the wavelength conversion member at an emission wavelength of 540 nm is equal to or smaller than 0.23.

Yₐ(Ce,Tb,Lu)_{b}(Ga,Sc)_{c}Al_{d}Oₑ (Y2)

(a+b=3, 0≦b≦0.2, 4.5≦c+d≦5.5, 0≦c≦0.2, 10.8≦e≦13.4)

Yₐ(Ce,Tb,Lu)_{b}(Ga,Sc)_{c}Al_{d}Oₑ (G2)

(a+b=3, 0≦b≦0.2, 4.5≦c+d≦5.5, 1.2≦c≦2.6, 10.8≦e≦13.4)

The variation in excitation spectrum intensity of the wavelength conversion member is expressed as the difference between a maximum value and a minimum value of excitation spectrum intensity in the range from 435 nm to 470 nm, taking 1.0 as the excitation spectrum intensity of the wavelength conversion member at 450 nm.

As a fourth embodiment, preferably,

the phosphor Y is a phosphor represented by formula (Y3) below,

the phosphor G is a phosphor represented by formula (G3) below, and

upon molding of the phosphor composition to yield a wavelength conversion member, the variation in excitation spectrum intensity of the wavelength conversion member at an emission wavelength of 540 nm is equal to or smaller than 0.33.

Yₐ(Ce,Tb,Lu)_{b}(Ga,Sc)_{c}Al_{d}Oₑ (Y3)

(a+b=3, 0≦b≦0.2, 4.5≦c+d≦5.5, 0≦c≦0.2, 10.8≦e≦13.4)

Lu_{f}(Ce,Tb,Y)_{g}(Ga,Sc)ₕAlᵢOⱼ (G3)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

In the first to fourth embodiments, preferably,

upon molding of the phosphor composition described above to yield a wavelength conversion member, the excitation spectrum intensity at 430 nm of the phosphor Y in the wavelength conversion member is smaller than the excitation spectrum intensity at 470 nm, in the excitation spectrum for an emission wavelength of 540 nm, and the excitation spectrum intensity at 430 nm of the phosphor G in the wavelength conversion member is greater than the excitation spectrum intensity at 470 nm, in the excitation spectrum for an emission wavelength of 540 nm.

In the first to fourth embodiments, preferably,

the phosphor composition described above further comprises a blue-green phosphor represented by formula (B1) below and having a peak wavelength of 500 nm or more and 520 nm or less in an emission wavelength spectrum when excited at 450 nm.

(Y,Ce,Tb,Lu)ₓ(Ga,Sc,Al)_{y}O_{z} (B1)

(x=3, 4.5≦y≦5.5, 10.8≦z≦13.4)

In the first to fourth embodiments, preferably,

a composition ratio of the phosphor Y and the phosphor G in the phosphor composition described above is 10:90 or more and 90:10 or less.

A fifth embodiment of the third invention is as follows.

A phosphor composition, comprising:

a phosphor G represented by formula (G4) below and having a peak wavelength of 520 nm or more and 540 nm or less in an emission wavelength spectrum when excited at 450 nm; and

a transparent material,

wherein upon molding of the phosphor composition to yield a wavelength conversion member, the variation in excitation spectrum intensity of the wavelength conversion member at an emission wavelength of 540 nm is equal to or smaller than 0.33.

Lu_{f}(Ce,Tb,Y)_{g}(Ga,Sc)ₕAlᵢOⱼ (G4)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

A sixth embodiment of the third invention is as follows.

A phosphor composition, comprising:

a yellow-green phosphor represented by formula (YG1) below and having a peak wavelength of 530 nm or more and 550 nm or less in an emission wavelength spectrum when excited at 450 nm; and

a transparent material,

wherein upon molding of the phosphor composition to yield a wavelength conversion member, the variation in excitation spectrum intensity of the wavelength conversion member at an emission wavelength of 540 nm is equal to or smaller than 0.25.

(Y,Ce,Tb,Lu)ₓ(Ga,Sc,Al)_{y}O_{z} (YG1)

(x=3, 4.5≦y≦5.5, 10.8≦z≦13.4)

The variation in excitation spectrum intensity of the wavelength conversion member is expressed as the difference between a maximum value and a minimum value of excitation spectrum intensity in the range from 430 nm to 470 nm, taking 1.0 as the excitation spectrum intensity of the wavelength conversion member at 450 nm.

Preferably, the yellow-green phosphor is the yellow-green phosphor represented by formula (YG2) below.

MₐA_{b}E_{c}Al_{d}Oₑ (YG2)

(where M is Ce; A is one, two or more elements selected from the group of Y and Lu, such that the content of Y is 90% or more; E is Ga, or Ga and Sc; and a+b=3, 4.5≦c+d≦5.5, 10.8≦e≦13.2, 0≦a≦0.9, 0.8≦c≦1.2)

In the present embodiment a red phosphor is preferably further incorporated.

A fourth invention of the present invention is an invention relating to a phosphor mixture. A first embodiment of the fourth invention is as follows.

A phosphor mixture, comprising:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4); and

a phosphor G represented by formula (G1) below and having a peak wavelength of 520 nm or more and 540 nm or less in an emission wavelength spectrum when excited at 450 nm.

(Y,Ce,Tb,Lu)ₓ(Ga,Sc,Al)_{y}O_{z} (G1)

(x=3, 4.5≦y≦5.5, 10.8≦z≦13.4)

As a second embodiment, preferably,

the variation in excitation spectrum intensity at an emission wavelength of 540 nm is equal to or smaller than 0.40.

The variation in excitation spectrum intensity of the phosphor mixture is expressed as the difference between a maximum value and a minimum value of excitation spectrum intensity in the range from 430 nm to 470 nm, taking 1.0 as the excitation spectrum intensity of the phosphor mixture at 450 nm.

As a third embodiment, preferably,

the phosphor Y is a phosphor represented by formula (Y2) below,

the phosphor G is a phosphor represented by formula (G2) below, and

the variation in excitation spectrum intensity at an emission wavelength of 540 nm is equal to or smaller than 0.30.

Yₐ(Ce,Tb,Lu)_{b}(Ga,Sc)_{c}Al_{d}Oₑ (Y2)

(a+b=3, 0≦b≦0.2, 4.5≦c+d≦5.5, 0≦c≦0.2, 10.8≦e≦13.4)

Yₐ(Ce,Tb,Lu)_{b}(Ga,Sc)_{c}Al_{d}Oₑ (G2)

(a+b=3, 0≦b≦0.2, 4.5≦c+d≦5.5, 1.2≦c≦2.6, 10.8≦e≦13.4)

The variation in excitation spectrum intensity of the phosphor mixture is expressed as the difference between a maximum value and a minimum value of excitation spectrum intensity in the range from 435 nm to 470 nm, taking 1.0 as the excitation spectrum intensity of the phosphor mixture at 450 nm.

As a fourth embodiment, preferably,

the phosphor Y is a phosphor represented by formula (Y3) below,

the phosphor G is a phosphor represented by formula (G3) below, and

the variation in excitation spectrum intensity at an emission wavelength of 540 nm is equal to or smaller than 0.25.

Yₐ(Ce,Tb,Lu)_{b}(Ga,Sc)_{c}Al_{d}Oₑ (Y3)

(a+b=3, 0≦b≦0.2, 4.5≦c+d≦5.5, 0≦c≦0.2, 10.8≦e≦13.4)

Lu_{f}(Ce,Tb,Y)_{g}(Ga,Sc)ₕAlᵢOⱼ (G3)

(f+g=3, 0≦g≦0.2, 4.5≦h+i≦5.5, 0≦h≦0.2, 10.8≦j≦13.4)

The variation in excitation spectrum intensity of the phosphor mixture is expressed as the difference between a maximum value and a minimum value of excitation spectrum intensity in the range from 435 nm to 465 nm, taking 1.0 as the excitation spectrum intensity of the phosphor mixture at 450 nm.

In the first to fourth embodiments, preferably,

the excitation spectrum intensity at 430 nm of the phosphor Y is smaller than the excitation spectrum intensity at 470 nm, in the excitation spectrum for an emission wavelength of 540 nm, and the excitation spectrum intensity at 430 nm of the phosphor G is greater than the excitation spectrum intensity at 470 nm, in the excitation spectrum for an emission wavelength of 540 nm.

In the first to fourth embodiments, preferably,

there is further incorporated a blue-green phosphor represented by formula (B1) below and having a peak wavelength of 500 nm or more and 520 nm or less in an emission wavelength spectrum when excited at 450 nm.

(Y,Ce,Tb,Lu)ₓ(Ga,Sc,Al)_{y}O_{z} (B1)

(x=3, 4.5≦y≦5.5, 10.8≦z≦13.4)

In the first to fourth embodiments, preferably,

a composition ratio of the phosphor Y and the phosphor G ranges from 10:90 to 90:10.

A fifth embodiment of the fourth invention is as follows.

A phosphor mixture, comprising:

a phosphor G represented by formula (G4) below and having a peak wavelength of 520 nm or more and 540 nm or less in an emission wavelength spectrum when excited at 450 nm,

wherein a variation in excitation spectrum intensity of the phosphor mixture at an emission wavelength of 540 nm is equal to or smaller than 0.25.

Lu_{f}(Ce,Tb,Y)_{g}(Ga,Sc)ₕAlᵢOⱼ (G4)

(f+g=3, 0≦g≦0.2, 4.5≦h+i≦5.5, 0≦h≦0.2, 10.8≦j≦13.4)

The variation in excitation spectrum intensity of a phosphor mixture is expressed as the difference between a maximum value and a minimum value of excitation spectrum intensity in the range from 435 nm to 465 nm, taking 1.0 as the excitation spectrum intensity of the phosphor mixture at 450 nm.

A sixth embodiment of the fourth invention is as follows.

A phosphor mixture, comprising:

a yellow-green phosphor represented by formula (YG1) below and having a peak wavelength of 530 nm or more and 550 nm or less in an emission wavelength spectrum when excited at 450 nm,

wherein the variation in excitation spectrum intensity of the phosphor mixture at an emission wavelength of 575 nm is equal to or smaller than 0.12.

(Y,Ce,Tb,Lu)ₓ(Ga,Sc,Al)_{y}O_{z} (YG1)

(x=3, 4.5≦y≦5.5, 10.8≦z≦13.4)

The variation in excitation spectrum intensity of the phosphor mixture is expressed as the difference between a maximum value and a minimum value of excitation spectrum intensity in the range from 430 nm to 465 nm, taking 1.0 as the excitation spectrum intensity of the phosphor mixture at 450 nm.

In the present embodiment a red phosphor is preferably further incorporated.

Upon mixing of the phosphor mixture with a silicone resin or kneading with a polycarbonate resin, and molding to yield a wavelength conversion member, preferably, the variation in excitation spectrum intensity of the wavelength conversion member at an emission wavelength of 540 nm is equal to or smaller than 0.05.

The variation in excitation spectrum intensity of the wavelength conversion member is expressed as the difference between a maximum value and a minimum value of excitation spectrum intensity in the range from 440 nm to 460 nm, taking 1.0 as the excitation spectrum intensity of the wavelength conversion member at 450 nm.

Preferably, the yellow-green phosphor is the yellow-green phosphor represented by formula (YG2) below.

MₐA_{b}E_{c}Al_{d}Oₑ (YG2)

(where M is Ce; A is one, two or more elements selected from the group of Y and Lu, such that the content of Y is 90% or more; E is Ga, or Ga and Sc; and a+b=3, 4.5≦c+d≦5.5, 10.8≦e≦13.2, 0≦a≦0.9, 0.8≦c≦1.2)

### Advantageous Effects of Invention

The first to seventh embodiments of the first embodiment of the present invention allow providing a light-emitting device excellent in binning characteristics and having high emission efficiency and color rendering properties. In particular, using a combination of the phosphor Y and the phosphor G allows achieving higher total luminous flux as compared with an instance where a YAG phosphor, being a typical example of the phosphor Y, is used singly, or an instance where a GYAG phosphor, being a typical example of the phosphor G is used singly. Accordingly, it becomes possible to further save energy in that the amount of power that the light-emitting device draws upon to achieve the target total luminous flux is reduced.

By using singly a LuAG phosphor, being a typical example of the phosphor G, the fifth embodiment of the first invention allows achieving a high total luminous flux as compared with an instance where a YAG phosphor, being a typical example of the phosphor Y, is used singly. The LuAG phosphor allows achieving higher color rendering properties, while preserving a high total luminous flux, as compared with an instance where a YAG phosphor is used, in particular at a high color temperature region, namely a color temperature of 4000 K or higher. Accordingly, it is possible to refrain from using a phosphor other than a LuAG phosphor.

By using singly a specific yellow-green phosphor, the sixth and seventh embodiments of the first invention allow achieving higher total luminous flux as compared with an instance where a YAG phosphor, being a typical example of the phosphor Y, is used singly. A light-emitting device can also be provided that is excellent in binning characteristics. These light-emitting devices are excellent not only in binning characteristics, but afford also high emission efficiency as well as high color rendering properties. Accordingly, these light-emitting devices can be put to practical use as illumination devices and backlights in which the light-emitting devices are mounted. The first invention is also economically advantageous in that emission efficiency is high and thus the use amount of phosphor is reduced.

Through the second invention of the present invention a wavelength conversion member can be provided that allows providing a light-emitting device that is excellent in binning characteristics, as described above, and that has high emission efficiency and color rendering properties.

Through e third and fourth inventions of the present invention it becomes possible to provide a phosphor composition or a phosphor mixture that allows providing a light-emitting device excellent in binning characteristics, and having high emission efficiency and color rendering properties, such as the above one.

### BRIEF DESCRIPTION OF DRAWINGS

FIG. 1 is a graph illustrating the change in emission intensity upon changes in excitation wavelength from 430 nm to 470 nm, for YAG, GYAG, SCASN and CASN phosphors, being examples of an embodiment of a first invention;

FIG. 2 is a cross-sectional schematic diagram of a light-emitting device according to an embodiment of the present invention;

FIG. 3 is a cross-sectional schematic diagram of a light-emitting device according to an embodiment of the present invention;

FIG. 4 is a diagram with plotted simulation results that denote a relationship between color rendering properties and emission efficiency, depending on phosphor type;

FIG. 5 is a diagram with plotted simulation results that denote a relationship between color rendering properties and emission efficiency, depending on phosphor type;

FIG. 6-1 is a graph illustrating the relationship between excitation emission spectrum and the formula composition of phosphors represented by formula (m3);

FIG. 6-2 is a graph illustrating the relationship between excitation emission spectrum and the formula composition of phosphors represented by formula (m5);

FIG. 7 is a graph illustrating the change in emission intensity upon changes in excitation wavelength from 430 nm to 465 nm, for YAG, LuAG 1, LuAG 2, SCASN and CASN phosphors, along with the change in combined excitation spectrum intensity that is calculated as a 1:1 weighted average of YAG and LuAG 1;

FIG. 8 is a graph illustrating the change in emission intensity upon changes in excitation wavelength from 430 nm to 470 nm, for GYAG 1, LuAG 1, GLuAG and YAG phosphors;

FIG. 9-1 is a graph illustrating the excitation spectrum intensity change, at an emission wavelength of 540 nm, of test pieces produced in Experimental Examples 1 to 3;

FIG. 9-2 is a graph illustrating the excitation spectrum intensity change, at an emission wavelength of 540 nm, of test pieces produced in Experimental Examples 4 to 8;

FIG. 9-3 is a graph illustrating the excitation spectrum intensity change, at an emission wavelength of 540 nm, of test pieces produced in Experimental Examples 9 to 12;

FIG. 10-1 is a graph illustrating binning characteristics of light-emitting devices produced in Experimental Examples 1 to 3;

FIG. 10-2 is a graph illustrating binning characteristics of light-emitting devices produced in Experimental Examples 4 to 8;

FIG. 10-3 is a graph illustrating binning characteristics of light-emitting devices produced in Experimental Examples 9 to 12;

FIG. 11-1 is a graph illustrating binning characteristics of light-emitting devices produced in Experimental Examples 1 to 3 and 9 to 12;

FIG. 11-2 is a graph illustrating binning characteristics of light-emitting devices produced in Experimental Examples 4 to 8;

FIG. 12-1 is a graph illustrating excitation spectrum intensity change, at an emission wavelength of 540 nm, of phosphor mixtures produced in Experimental Examples 13 and 14;

FIG. 12-2 is a graph illustrating excitation spectrum intensity change, at an emission wavelength of 540 nm, of phosphor mixtures produced in Experimental Examples 15 to 20;

FIG. 12-3 is a graph illustrating excitation spectrum intensity change, at an emission wavelength of 540 nm, of phosphor mixtures produced in Experimental Examples 21 and 22;

FIG. 13 is a graph illustrating binning characteristics of light-emitting devices produced in Experimental Examples 23 to 27;

### DESCRIPTION OF EMBODIMENTS

Embodiments of the present invention are explained next, but the present invention is not limited to specific embodiments alone.

Each composition formula of the phosphors in this Description is punctuated by a comma (,). Further, when two or more elements are juxtaposed with a comma (,) in between, one kind of or two or more kinds of the juxtaposed elements can be contained in the composition formula in any combination and in any composition.

A light-emitting device according to a first to seventh embodiments of a first invention comprises a blue semiconductor light-emitting element, and a wavelength conversion member.

The blue semiconductor light-emitting element is a semiconductor light-emitting element that emits light having an emission peak of 420 nm or more and 475 nm or less. Preferably, the blue semiconductor light-emitting element emits light having an emission peak of 430 nm or more and 465 nm or less, and preferably emits light having an emission peak of 445 nm or more and 455 nm or less.

Preferably, the full width at half maximum of emission spectrum of the blue semiconductor light-emitting element is 5 nm or more and 30 nm or less, from the viewpoint of emission efficiency.

The blue semiconductor light emitting element is preferably a light-emitting diode element having a light-emitting section of a pn junction type that is formed by a gallium nitride, zinc oxide or silicon carbide semiconductor.

The wavelength conversion member converts the wavelength of at least part of incident light, and emits outgoing light of a wavelength different from that of the incident light. The wavelength conversion member comprises a phosphor that converts the wavelength of at least part of the incident light and that emits outgoing light having a wavelength different from that of the incident light. Preferably, the phosphor is dispersed or the like in a transparent or semi-transparent material having low absorption towards visible light, for instance a resin or the like. The wavelength conversion member may in some instances retain a free-standing shape, depending on, for instance, the transparent material contained in the wavelength conversion member. In yet another form of the wavelength conversion member, a transparent substrate such as glass may be coated with a phosphor that is mixed, as needed, with a resin or the like.

The wavelength conversion member used in the first embodiment of the first invention comprises:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4); and

a phosphor G represented by formula (G1) below and having a peak wavelength of 520 nm or more and 540 nm or less in an emission wavelength spectrum when excited at 450 nm.

(Y,Ce,Tb,Lu)ₓ(Ga,Sc,Al)_{y}O_{z} (G1)

(x=3, 4.5≦y≦5.5, 10.8≦z≦13.4)

The phosphor Y is a yellow phosphor having a peak wavelength of 540 nm or more and 570 nm or less in an emission wavelength spectrum when excited at 450 nm, i.e. having a peak wavelength of an emission wavelength spectrum in the yellow region.

Typical examples of the phosphor Y include, for instance, phosphors represented by formula (l) below, referred to as YAG phosphors, but the phosphor Y is not limited thereto.

Yₐ(Ce,Tb,Lu)_{b}(Ga,Sc)_{c}Al_{d}Oₑ (l)

(a+b=3, 0≦b≦0.2, 4.5≦c+d≦5.5, 0≦c≦0.2, 10.8≦e≦13.4)

The phosphor G is a green phosphor having a peak wavelength of 520 nm or more and 540 nm or less in an emission wavelength spectrum when excited at 450 nm, i.e. having a peak wavelength of an emission wavelength spectrum in the green region.

Typical examples of the phosphor G include, for instance, phosphors represented by formula (m1) below, referred to as GYAG phosphors, and phosphors represented by formula (m2) below, referred to as LuAG phosphors, but the phosphor G is not limited thereto.

Yₐ(Ce,Tb,Lu)_{b}(Ga,Sc)_{c}Al_{d}Oₑ (m1)

(a+b=3, 0≦b≦0.2, 4.5≦c+d≦5.5, 1.2≦c≦2.6, 10.8≦e≦13.4)

Lu_{f}(Ce,Tb,Y)_{g}(Ga,Sc)ₕAlᵢOⱼ (m2)

(f+g=3, 0≦g≦0.2, 4.5≦h+i≦5.5, 0≦h≦0.2, 10.8≦j≦13.4)

By satisfying the above requirements, the light-emitting device according to the first embodiment of the first invention exhibits superior binning characteristics and is capable of withstanding practical use. Often, the variability of the emission peak wavelength of the blue semiconductor light-emitting element that constitutes a light source of the light-emitting device is ordinarily of about 10 nm. The light-emitting device according to the first embodiment of the first invention is excellent in so-called binning characteristics, i.e. the light-emitting device exhibits small chromaticity changes in emitted light with respect to the variability of the emission peak wavelength of the blue semiconductor light-emitting element that constitutes such a light source.

Such a light-emitting device excellent in binning characteristics can be achieved by using concomitantly the phosphor Y represented by formula (Y1) above and the phosphor G represented by formula (G1) above.

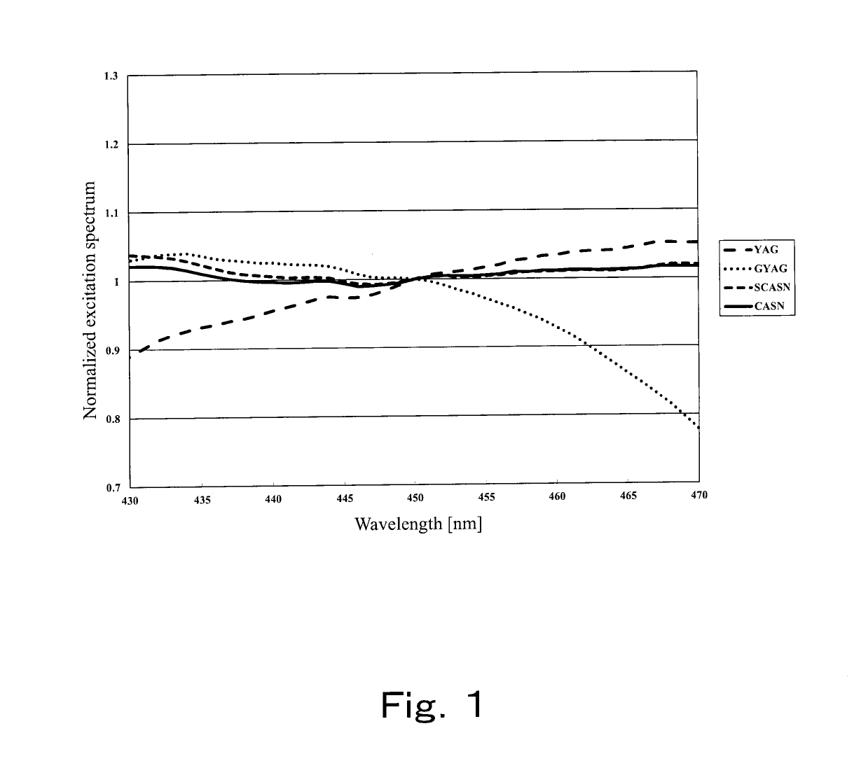

Regarding this feature, an instance of concomitant use of the YAG phosphor, being a typical example of the phosphor Y, and a GYAG phosphor, being a typical example of the phosphor G, will be explained with reference to FIG. 1.

FIG. 1 is a graph illustrating the change in excitation emission spectra of YAG, GYAG, SCASN and CASN phosphors when the excitation wavelength is modified from 430 nm to 470 nm.

As FIG. 1 reveals, YAG represented by formula (Y1) exhibits increasing emission intensity as the excitation wavelength increases, for an excitation wavelength from 445 nm up to 455 nm.

By contrast, GYAG represented by formula (G1) exhibits a decreasing emission intensity with increasing excitation wavelength, for an excitation wavelength from 445 nm up to 455 nm.

This indicates that the excellent binning characteristics of the light-emitting device according to the first embodiment of the first invention can be achieved by using concomitantly the phosphor Y represented by formula (Y1) and the phosphor G represented by formula (G1).

In a second embodiment of the light-emitting device according to the first invention, preferably, the variation in excitation spectrum intensity of the wavelength conversion member at an emission wavelength of 540 nm is equal to or smaller than 0.25.

The variation in excitation spectrum intensity of the wavelength conversion member is expressed as the difference between a maximum value and a minimum value of excitation spectrum intensity in the range from 435 nm to 465 nm, taking 1.0 as the excitation spectrum intensity of the wavelength conversion member at 450 nm. The variation in excitation spectrum intensity is calculated using the intensity at an emission wavelength of 540 nm.

The inventors focused on the excitation spectrum intensities of phosphors, which denote what is the degree of intensity of light emitted by the phosphor, at which excitation wavelength, and, in particular, studied in detail the excitation spectrum intensity for light of about 450 nm, which is the wavelength of light emitted by the blue semiconductor light-emitting element. As a result, the inventors conjectured that, in addition to good binning characteristics, a high total luminous flux can be achieved by prescribing the variation in excitation spectrum intensity of the wavelength conversion member at an emission wavelength of 540 nm to be equal to or smaller than 0.25.

In a case where the excitation wavelength changes as a result of a significant change in the excitation spectrum intensity, the fluorescence intensity emitted by the phosphor changes likewise significantly, and deviation occurs in the chromaticity of the light emitted by the light-emitting device. In the present embodiment, deviation in the chromaticity of light emitted by the wavelength conversion member is suppressed by prescribing the variation in excitation spectrum intensity of the wavelength conversion member at an emission wavelength of 540 nm to be equal to or smaller than 0.25.

Preferably, the variation in excitation spectrum intensity of the wavelength conversion member at an emission wavelength of 540 nm is prescribed to be equal to or smaller than 0.24, and more preferably equal to or smaller than 0.23.

The variation in excitation spectrum intensity is preferably equal to or greater than 0.03, more preferably equal to or greater than 0.05. When the variation in excitation spectrum intensity is equal to or smaller than 0.03, the emission spectrum intensity of a case where the excitation wavelength changes remains the same, but photopic sensitivity varies and, as a result, luminance and chromaticity may in some instances vary substantially.

As a third embodiment of the first invention, preferably,

the phosphor Y is a phosphor represented by formula (Y2) below,

the phosphor G is a phosphor represented by formula (G2) below, and

the variation in excitation spectrum intensity of the wavelength conversion member at an emission wavelength of 540 nm is equal to or smaller than 0.23.

Yₐ(Ce,Tb,Lu)_{b}(Ga,Sc)_{c}Al_{d}Oₑ (Y2)

(a+b=3, 0≦b≦0.2, 4.5≦c+d≦5.5, 0≦c≦0.2, 10.8≦e≦13.4)

Yₐ(Ce,Tb,Lu)_{b}(Ga,Sc)_{c}Al_{d}Oₑ (G2)

(a+b=3, 0≦b≦0.2, 4.5≦c+d≦5.5, 1.2≦c≦2.6, 10.8≦e≦13.4)

The variation in excitation spectrum intensity of the wavelength conversion member is expressed as the difference between a maximum value and a minimum value of excitation spectrum intensity in the range from 435 nm to 470 nm, taking 1.0 as the excitation spectrum intensity of the wavelength conversion member at 450 nm.

Preferably, the variation in excitation spectrum intensity of the wavelength conversion member at an emission wavelength of 540 nm is prescribed to be equal to or smaller than 0.21, and more preferably equal to or smaller than 0.20.

The variation in excitation spectrum intensity is preferably equal to or greater than 0.03, more preferably equal to or greater than 0.05.

If the phosphor is a YAG phosphor, the full width at half maximum is preferably 100 nm or more and 130 nm or less, from the viewpoint of color rendering properties. If the phosphor G is a GYAG phosphor, the full width at half maximum is preferably 105 nm or more and 120 nm or less, from the viewpoint of color rendering properties.

As a fourth embodiment of the first invention, preferably,

the phosphor Y is a phosphor represented by formula (Y3) below,

the phosphor G is a phosphor represented by formula (G3) below, and

the variation in excitation spectrum intensity of the wavelength conversion member at an emission wavelength of 540 nm is prescribed to be equal to or smaller than 0.33.

Yₐ(Ce,Tb,Lu)_{b}(Ga,Sc)_{c}Al_{d}Oₑ (Y3)

(a+b=3, 0≦b≦0.2, 4.5≦c+d≦5.5, 0≦c≦0.2, 10.8≦e≦13.4)

Lu_{f}(Ce,Tb,Y)_{g}(Ga,Sc)ₕAlᵢOⱼ (G3)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

Preferably, the variation in excitation spectrum intensity of the wavelength conversion member at an emission wavelength of 540 nm is prescribed to be equal to or smaller than 0.30, and more preferably equal to or smaller than 0.28.

The variation in excitation spectrum intensity is preferably equal to or greater than 0.03, more preferably equal to or greater than 0.05.

If the phosphor is a YAG phosphor, the full width at half maximum is preferably 100 nm or more and 130 nm or less, from the viewpoint of color rendering properties. If the phosphor G is a LuAG phosphor, the full width at half maximum is preferably 30 nm or more and 120 nm or less, from the viewpoint of color rendering properties.

In the third and fourth embodiments of the first invention,

preferably, the variation in combined excitation spectrum intensity combined by calculation expression (Z) below is equal to or smaller than 0.15.

The combined excitation spectrum is an excitation spectrum wherein the excitation spectrum intensity at each wavelength is expressed by calculation expression (Z) below.

Combined excitation spectrum intensity=(excitation spectrum intensity of phosphor Y)×(weight fraction of phosphor Y)+(excitation spectrum intensity of phosphor G)×(weight fraction of phosphor G) (Z)

The weight fraction of the phosphor Y is given by phosphor Y/(phosphor Y+phosphor G).

The variation in combined excitation spectrum intensity of the phosphor G and the weight fraction of the phosphor G are expressed similarly.

The each variation in excitation spectrum intensity is expressed as the difference between a maximum value and a minimum value of the combined excitation spectrum intensity in the range from 430 nm to 470 nm, taking 1.0 as the excitation spectrum intensity at 450 nm in the excitation spectrum.

Similarly to the case above, the inventors focused on the excitation spectrum intensities of phosphors, which denote what is the degree of intensity of light emitted by the phosphor, at which excitation wavelength, and, in particular, studied in detail the excitation spectrum intensity for light of about 450 nm, which is the wavelength of light emitted by the blue semiconductor light-emitting element. In both the third and fourth embodiments, the variation in combined excitation spectrum intensity of the phosphors Y and G were set to be equal to or smaller than 0.15, as a result of which overall changes in the intensity of fluorescence emitted by the phosphors Y and G were curtailed, and chromaticity deviation was suppressed.

In order to set the variation in excitation spectrum intensity of the wavelength conversion member at the emission wavelength of 540 nm to be equal to or smaller than 0.23, and 0.33, respectively, in the third and fourth embodiments described above, it is sufficient to set the variation in combined excitation spectrum intensity to be equal to or smaller than 0.15 in both embodiments, to which end it suffices to adjust, as appropriate, the type and content of the phosphor Y and the phosphor G.

The respective single variation in excitation spectrum intensity of the phosphor Y and the phosphor G that are used in all the above embodiments are not limited, so long as the combined excitation spectrum intensity is equal to or smaller than 0.15; thus, the combined excitation spectrum intensity of the phosphor Y and/or the phosphor G may be single and may be equal to or smaller than 0.15.

More preferably, the variation in combined excitation spectrum intensity is equal to or smaller than 0.14, and yet more preferably is 0.12, in all embodiments.

The variation in combined excitation spectrum intensity is preferably equal to or greater than 0.02, more preferably equal to or greater than 0.04.

In the first to fourth embodiments of the first invention, preferably,

the excitation spectrum intensity at 430 nm of the phosphor Y is smaller than the excitation spectrum intensity at 470 nm, in the excitation spectrum for an emission wavelength of 540 nm, and

the excitation spectrum intensity at 430 nm of the phosphor G is greater than the excitation spectrum intensity at 470 nm, in the excitation spectrum for an emission wavelength of 540 nm.

By satisfying the above conditions, the emission spectrum other than for the excitation wavelength changes from an emission color of high degree of contribution from the phosphor G to an emission color of high degree of contribution from the phosphor Y, when the excitation wavelength varies from 430 nm to 470 nm, such that the substantial emission color, including the excitation wavelength, can be set to be constant at all times, independently from the excitation wavelength.

The first to fourth embodiments of the first invention, preferably,

further comprise a blue-green phosphor represented by formula (B1) below and having a peak wavelength of 500 nm or more and 520 nm or less in an emission wavelength spectrum when excited at 450 nm.

(Y,Ce,Tb,Lu)ₓ(Ga,Sc,Al)_{y}O_{z} (B1)

(x=3, 4.5≦y≦5.5, 10.8≦z≦13.4)

Examples of the blue-green phosphor having a peak wavelength of 500 nm or more and 520 nm or less in an emission wavelength spectrum when excited at 450 nm, include for instance a blue-green phosphor resulting from adjusting the emission wavelength to a range of 500 nm or more and 520 nm or less by substituting Ga for part of Al in a LuAG phosphor, such as the one illustrated in formula (B2) below (hereafter also referred to as GLuAG).

Lu_{f}Ce_{g}GaₕAlᵢOⱼ (B2)

(f+g=3, 0≦g≦0.2, 4.5≦h+i≦5.5, 0≦h≦4.0, 10.8≦j≦13.4)

By incorporating the blue-green phosphor, it becomes possible to adjust the emission intensity in the wavelength region from 500 to 520 nm, which cannot be reproduced by the phosphor G and the phosphor Y, and to achieve yet better binning characteristics.

In the first to fourth embodiments of the first invention,

the composition ratio of the phosphor Y and the phosphor G is ordinarily 10:90 or more and 90:10 or less, preferably 12:88 or more and 88:12 or less, and more preferably 15:85 or more and 85:15 or less.

Satisfying the above condition allows significantly adjusting the shape of the emission spectrum other than for excitation light, upon changes in the excitation wavelength. Outside the above range, the adjustable emission spectrum shape is limited, which is undesirable in that binning characteristics may fail thus to be enhanced.

A wavelength conversion member used in the fifth embodiment of the first invention comprises

a phosphor G represented by formula (G4) below and having a peak wavelength of 520 nm or more and 540 nm or less in an emission wavelength spectrum when excited at 450 nm,

wherein the variation in excitation spectrum intensity of the wavelength conversion member at an emission wavelength of 540 nm is equal to or smaller than 0.33.

Lu_{f}(Ce,Tb,Y)_{g}(Ga,Sc)ₕAlᵢOⱼ (G4)

(f+g=3, 0≦g≦0.2, 4.5≦h+i≦5.5, 0≦h≦0.2, 10.8≦j≦13.4)

The variation in excitation spectrum intensity of the wavelength conversion member is expressed as the difference between a maximum value and a minimum value of excitation spectrum intensity in the range from 430 nm to 465 nm, taking 1.0 as the excitation spectrum intensity of the wavelength conversion member at 450 nm.

Preferably, the variation in excitation spectrum intensity of the wavelength conversion member at an emission wavelength of 540 nm is prescribed to be equal to or smaller than 0.30, and more preferably equal to or smaller than 0.28.

The variation in excitation spectrum intensity is preferably equal to or greater than 0.03, more preferably equal to or greater than 0.05.

In the light-emitting device according to the first to fifth embodiments, a good binning effect is elicited, in the range from about 430 nm to 465 nm, by setting the variation in excitation spectrum intensity of the wavelength conversion member at an emission wavelength of 540 nm to be equal to or smaller than the above value, and preferably setting the variation in combined excitation spectrum intensity given by Expression (Z) to be equal to or smaller than the above value. From a practical point of view, when the emission wavelength of the blue semiconductor light-emitting element is caused to vary continuously from 445 nm to 455 nm, a chromaticity change Δu′v′ of the light emitted by the light-emitting device satisfies Δu′v′≦0.004. More preferably, the chromaticity charge satisfies Δu′v′≦0.0035.

Herein, the value Δu′v′ denotes the distance between the chromaticity (u′ᵢ,v′ᵢ) at any wavelength i nm from 445 nm to 455 nm and an average value (u′ₐᵥₑ, v′ₐᵥₑ) of chromaticity at 445 nm to 455 nm.

Preferably, when the emission wavelength of the blue semiconductor light-emitting element is caused to vary continuously from 435 nm to 470 nm, the chromaticity change Δu′v′ of the light emitted by the light-emitting device satisfies Δu′v′≦0.015. More preferably, the chromaticity charge satisfies Δu′v′≦0.012.

Herein, the value Δu′v′ denotes the distance between the chromaticity (u′ᵢ,v′ᵢ) at any wavelength i nm from 435 nm to 470 nm and an average value (u′ₐᵥₑ, v′ₐᵥₑ) of chromaticity at 435 nm to 470 nm.

A wavelength conversion member used in a sixth embodiment of the first invention comprises

a yellow-green phosphor represented by formula (YG1) below and having a peak wavelength of 530 nm or more and 550 nm or less in an emission wavelength spectrum when excited at 450 nm,

wherein the variation in excitation spectrum intensity of the wavelength conversion member at an emission wavelength of 540 nm is equal to or smaller than 0.25.

(Y,Ce,Tb,Lu)ₓ(Ga,Sc,Al)_{y}O_{z} (YG1)

(x=3, 4.5≦y≦5.5, 10.8≦z≦13.4)

The variation in excitation spectrum intensity of the wavelength conversion member is expressed as the difference between a maximum value and a minimum value of excitation spectrum intensity in the range from 430 nm to 470 nm, taking 1.0 as the excitation spectrum intensity of the wavelength conversion member at 450 nm.

Preferably, the variation in excitation spectrum intensity of the yellow-green phosphor is equal to or smaller than 0.13.

The variation in excitation spectrum intensity of the yellow-green phosphor is expressed as the difference between a maximum value and a minimum value of the excitation spectrum intensity in the range from 430 nm to 465 nm, taking 1.0 as the excitation spectrum intensity of the yellow-green phosphor at 450 nm.

Preferably, when the emission wavelength of the blue semiconductor light-emitting element is caused to vary continuously from 445 nm to 455 nm, the chromaticity change Δu′v′ of the light emitted by the light-emitting device satisfies Δu′v′≦0.005.

Herein, the value Δu′v′ denotes the distance between the chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

Preferably, the yellow-green phosphor is represented by formula (YG2) below.

MₐA_{b}E_{c}Al_{d}Oₑ (YG2)

(where M is Ce; A is one, two or more elements selected from the group of Y and Lu, such that the content of Y is 90% or more; E is Ga, or Ga and Sc; and a+b=3, 4.5≦c+d≦5.5, 10.8≦e≦13.2, 0≦a≦0.9, 0.8≦c≦1.2)

Phosphors represented by formula (YG1) include phosphors, ordinarily referred to as GYAG, having a peak wavelength of the emission wavelength spectrum of 530 nm or more and 550 nm or less, i.e. having a peak wavelength of the emission wavelength spectrum in the yellow-green region when excited at 450 nm.

Preferably, the excitation spectrum intensity change of the yellow-green phosphor at 440 nm to 460 nm is equal to or smaller than 4.0% of the intensity of the excitation light spectrum at 450 nm. The excitation spectrum intensity change is calculated on the basis of the intensity at 540 nm.

The inventors focused on the excitation spectrum intensities of phosphors, which denote what is the degree of intensity of light emitted by the phosphor, at which excitation wavelength, and, in particular, studied in detail the excitation spectrum intensity for light of about 450 nm, which is the wavelength of light emitted by the blue semiconductor light-emitting element. As a result, the inventors conjectured that, in addition to good binning characteristics, a high luminance can be achieved by virtue of the fact that the variation in excitation spectrum intensity of the wavelength conversion member at an emission wavelength of 540 nm is equal to or smaller than 0.25.

In a case where the excitation wavelength changes as a result of a significant change in the excitation spectrum intensity, the fluorescence intensity emitted by the phosphor changes likewise significantly, and deviation occurs in the chromaticity of the light emitted by the light-emitting device. In the present embodiment, deviation in the chromaticity of light emitted by the wavelength conversion member is suppressed by prescribing the variation in excitation spectrum intensity of the wavelength conversion member at an emission wavelength of 540 nm to be equal to or smaller than 0.25.

Often, the variability of the emission peak wavelength of the blue semiconductor light-emitting element that constitutes a light source of the light-emitting device is ordinarily of about ±5 nm. The variability in the emission peak wavelength is of about ±20 nm even in blue semiconductor light-emitting elements of largest variability. The light-emitting device according to the present embodiment is preferred in that, by satisfying the above requirements, the light-emitting device is excellent in so-called binning characteristics, i.e. the light-emitting device exhibits small chromaticity changes in emitted light with respect to the variability of the emission peak wavelength of the blue semiconductor light-emitting element that constitutes a light source.

A wavelength conversion member used in a seventh embodiment of the first invention comprises

a yellow-green phosphor, represented by formula (YG3) below, and having a difference equal to or smaller than 0.05 between a maximum value and a minimum value of normalized excitation spectrum intensity at 450 nm, when excited at an excitation wavelength ranging from 440 nm to 460 nm.

(Y,Ce)₃(Ga,Al)_{f}O_{g} (YG3)

(4.5≦f≦5.5, 10.8≦g≦13.2)

The excitation spectrum intensity normalized by the excitation intensity at 450 nm upon excitation at an excitation wavelength ranging from 440 nm to 460 nm depends on the Ga concentration. Accordingly, the difference between the maximum value and the minimum value of the excitation spectrum intensity can be reduced, and kept equal to or smaller than 0.05, by adjusting the Ga concentration within the range 4.5≦f≦5.5.

In a case where the phosphor represented by formula (YG2) and formula (YG3) is a GYAG phosphor, the full width at half maximum is preferably 105 nm or more and 120 nm or less, from the viewpoint of color rendering properties.

In the present embodiment, deviation in the chromaticity of the light emitted by the wavelength conversion member is suppressed by setting the difference between the maximum value and the minimum value of normalized excitation spectrum intensity for an excitation intensity of 450 nm, upon excitation at an excitation wavelength ranging from 440 nm to 460 nm, to be equal to or smaller than 0.05.

By being provided with the above wavelength conversion member, therefore, the light-emitting device of the present embodiment exhibits a chromaticity change Δu′v′, from the average chromaticity of light emitted by the wavelength conversion member when excited at an excitation wavelength ranging from 445 nm to 455 nm, that is equal to or smaller than 0.005.

Herein, the value Δu′v′ denotes the distance between the chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

Often, the variability of the emission peak wavelength of the blue semiconductor light-emitting element that constitutes a light source of the light-emitting device is ordinarily of about ±5 nm. The variability in the emission peak wavelength is of about ±20 nm even in blue semiconductor light-emitting elements of largest variability. The light-emitting device according to the first to seventh embodiments of the first invention is preferred in that, by satisfying the above requirements, it constitutes a light-emitting device excellent in so-called binning characteristics, i.e. the light-emitting device exhibits small chromaticity changes in emitted light with respect to the variability of the emission peak wavelength of the blue semiconductor light-emitting element that constitutes a light source.

The chromaticity (u′ᵢ,v′ᵢ) of light emitted by the light-emitting device at any wavelength i nm, and the average value (u′ₐᵥₑ, v′ₐᵥₑ) of the chromaticity of light emitted by the light-emitting device at a wavelength in a specific region are calculated on the basis of the CIE 1976 UCS chromaticity diagram. Specifically, a spectrum of light emitted by the light-emitting device is obtained using a 20-inch integrating sphere (LMS-200) by Labsphere, Inc., and a spectroscope (Solid Lambda UV-Vis, by Carl Zeiss), and the chromaticity (u′ᵢ,v′ᵢ) is calculated on the basis of the obtained spectrum. The calculated chromaticity (u′ᵢ,v′ᵢ) is plotted on a u′v′chromaticity diagram, and the distance with respect to the average value (u′ₐᵥₑ, V′ₐᵥₑ) is worked out on the basis of the expression below, to yield the chromaticity change Δu′v′:

\sqrt{(u′ᵢ−u′ₐᵥₑ)²+(v′ᵢ−v′ₐᵥₑ)²} [Expression 1]

In the light-emitting device according to first to seventh embodiments of the first invention, the chromaticity (u′ᵢ,v′ᵢ) at any wavelength i nm emitted by the light-emitting device is measured by modifying the excitation wavelength at least every 5 nm, preferably every 3 nm, more preferably every 2 nm, and yet more preferably every 1 nm, to calculate the average value (u′ₐᵥₑ, v′ₐᵥₑ). The distance between the chromaticity (u′ᵢ,v′ᵢ) and the (u′ₐᵥₑ, v′ₐᵥₑ) at the wavelength i nm is then worked out.

The interval of modification of the wavelength in the measurement of the average value of the chromaticity of light emitted by light-emitting device may be set to be constant or to be random.

In the wavelength conversion member pertaining to the light-emitting device of the sixth to seventh embodiments of the first invention, the contents of the phosphor represented by formula (YG1), of the phosphor represented by formula (YG2) and of the phosphor represented by formula (YG3) are not particularly limited, and may be set as appropriate in accordance with requirements such as the color temperature of the light to be emitted by the light-emitting device.

Ordinarily, the particle size of the phosphors used in the first to fifth embodiments of the first invention involves preferably a volume-basis median diameter D₅₀ᵥ of 0.1 μm or more, and more preferably of 1 μm or more. The particle diameter is preferably 30 μm or less, more preferably 20 μm or less. Here, the volume-basis median diameter D₅₀ᵥ is defined as the particle diameter with a volumetric basis relative particle amount of 50% when a sample is measured and the particle distribution (cumulative distribution) is determined by using a particle distribution measurement device which is based on the laser diffraction and scatter method. Measurement methods include, for example, placing the phosphor in ultrapure water, using an ultrasonic nano-dispersion device (made by Kaijo Corporation) to set the frequency at 19 KHz, setting the intensity of the ultrasonic waves at 5 W, and, after ultrasonic-dispersing the sample for twenty five seconds, using a flow cell for adjustment to an 88% to 92% transmittance and, after checking that there is no particle cohesion, performing measurement in a 0.1 μm to 600 μm particle range by means of a laser diffraction particle distribution measurement device (LA-300, made by Horiba, Ltd). Further, in the foregoing method, if the phosphor particles are subjected to cohesion, a dispersant may be added, for example, the phosphor may be placed in an aqueous solution containing 0.0003% by weight of Tamol (made by BASF) or the like, and similarly to the foregoing method, measurement may be performed after dispersion using ultrasonic waves.

Indicators for the extent of the particle diameter distribution include the ratio (Dᵥ/Dₙ) between a volumetric basis average particle diameter Dᵥ and a number mean diameter Dₙ of the phosphor. In the invention of this application, Dᵥ/Dₙ is preferably at least 1.0, more preferably at least 1.2, and even more preferably at least 1.4. Meanwhile, Dᵥ/Dₙ is preferably no more than 25, more preferably no more than 10, and particularly preferably no more than 5. If Dᵥ/Dₙ is too large, phosphor particles whose weight greatly varies are present and there tends to be a non-uniform distribution of phosphor particles in the phosphor layer.

The phosphor that is used may have the surface thereof coated beforehand with a third component. The type of third component that is used for coating, and the coating technique, are not particularly limited, and any known third component and technique may be resorted to.

Examples of the third component include, for instance, organic acids, inorganic acids, silane treating agents, silicone oil, liquid paraffin and the like. Preferred among the foregoing are, for instance, silane coupling agents (monoalkyltrisilanol, dialkyldisilanol, trialkylsilanol, monoalkyltrialkoxysilane, dialkyldialkoxysilane, trialkylalkoxysilane), substituted siloxanes, and silicones. Treating the surface of the phosphor, or covering the surface using such a third component, tends to result in enhanced affinity of the resin or the like with the wavelength conversion member, and enhanced dispersibility, thermal stability, fluorescence chromogenic properties and so forth. The surface treatment amount and coating amount range ordinarily from 0.01 to 10 parts by weight with respect to 100 parts by weight of phosphor. If the amount is smaller than 0.01 part by weight, it is difficult to achieve an improvement effect as regards affinity, dispersibility, thermal stability, fluorescence chromogenic properties and so forth, while if the amount of is greater than 10 parts by weight, problems such as impaired thermal stability, mechanical characteristics and fluorescence chromogenic properties are likelier to arise.

The content of phosphor in the wavelength conversion member of the first to fifth embodiments of the first invention varies depending on the types of light diffusing material and resin described below. In the case of a polycarbonate resin, for instance, the content of phosphor is ordinarily 0.1 part by weight or greater, preferably 0.5 parts by weight or greater, more preferably 1 part by weight or greater, and ordinarily 50 parts by weight or less, preferably 40 parts by weight or less, more preferably 30 parts by weight or less, and yet more preferably 20 parts by weight or less, with respect to 100 parts by weight of polycarbonate resin. An excessively small content of phosphor is undesirable, since this tends to render the wavelength conversion effect of the phosphor difficult to bring out, while an excessive content may translate into impaired mechanical characteristics, which is likewise undesirable.

In the case of, for instance, a silicone resin, the content of phosphor in the wavelength conversion member is ordinarily 0.1 part by weight or greater, preferably 1 part by weight or greater, and more preferably 3 parts by weight or greater, and ordinarily 80 parts by weight or less, preferably 60 parts by weight or less, more preferably 50 parts by weight or less, and yet more preferably 40 parts by weight or less, with respect to 100 parts by weight of the silicone resin. An excessively small content of phosphor is undesirable, since this tends to render the wavelength conversion effect of the phosphor difficult to bring out, while an excessive content may translate into impaired mechanical characteristics, which is likewise undesirable.

In the first to fifth embodiments of the first invention, preferably, the wavelength conversion member further comprises a red phosphor (also referred to as first red phosphor). The color rendering properties of the light emitted by the light-emitting device can be enhanced, while adjustment at the comparatively low color temperature of the light-emitting device is made easier, by incorporating the first red phosphor.

The excitation spectrum intensity change upon varying the excitation light wavelength of the first red phosphor from 445 nm to 455 nm is preferably equal to or smaller than 5.0%, more preferably equal to or smaller than 3.0%, and yet more preferably equal to or smaller than 1.0% of the intensity of the excitation spectrum by excitation light of 455 nm. Using such a red phosphor results in a light-emitting device having sufficient binning characteristics, while making it possible to further enhance color rendering properties. The lower limit value of the intensity change is not particularly limited, but is equal to or greater than 0%.

Examples of red phosphors that satisfy such requirements include, for instance, (Sr,Ca)AlSiN₃:Eu, Ca₁₋ₓAl₁₋ₓSi₁₊ₓN₃₋ₓOₓ:Eu (where 0<x<0.5), K₂SiF:Mn⁴⁺, Eu_{y}(Sr,Ca,Ba)_{1-y}:Al₁₊ₓSi₄₋ₓOₓN₇₋ₓ (where 0≦x<4, 0≦y<0.2) and the like, preferably (Sr,Ca)AlSiN₃:Eu or Ca₁₋ₓAl₁₋ₓSi₁₊ₓN₃₋ₓOₓ:Eu (where 0<x<0.5)

As the first red phosphor there is preferably incorporated a red phosphor having an emission peak wavelength of 600 nm or more and less than 640 nm, and a full width at half maximum of 2 nm or more and 120 nm or less. Examples of red phosphors satisfying such requirements include, for instance, (Sr,Ca)AlSiN₃:Eu, Ca₁₋ₓAl₁₋ₓSi₁₊ₓN₃₋ₓOₓ:Eu (where 0<x<0.5), Eu_{y} (Sr,Ca,Ba)_{1-y}:Al₁₊ₓSi₄₋ₓOₓN₇₋ₓ (where 0≦x<4, 0≦y<0.2) and K₂SiF:Mn⁴⁺, preferably (Sr,Ca)AlSiN₃:Eu or Ca₁₋ₓAl₁₋ₓSi₁₊ₓN₃₋ₓOₓ:Eu (where 0<x<0.5).

The content of the first red phosphor, having an emission peak wavelength of 600 nm or more and less than 640 nm and a full width at half maximum of 2 nm or more and 120 nm or less is preferably 30% or more, yet more preferably 40% or more, and particularly preferably 50% or more in a composition weight ratio with respect to a total amount of red phosphor. The weight ratio is preferably 95% or less, more preferably 90% or less, and particularly preferably 85% or less.

In the first to fifth embodiments of the first invention, preferably, a red phosphor (hereafter also referred to as second red phosphor) is incorporated in addition to, or in place of, the above-described first red phosphor. More preferably, there are incorporated two types of red phosphor.

By incorporating the second red phosphor in addition to the first red phosphor, the light-emitting device comprises then at least four types of phosphor, together with the phosphor X and the phosphor Y. The light-emitting device comprising thus four types of phosphor allows achieving high conversion efficiency, in addition to good color rendering properties derived from addition of the red phosphor. This increases as a result the degree of freedom as regards the types and amount of phosphors that can be selected. This feature will be explained on the basis of the results of the simulation described below.

The excitation spectrum intensity change upon varying the excitation light wavelength of the second red phosphor from 445 nm to 455 nm is preferably equal to or smaller than 5.0%, more preferably equal to or smaller than 3.0%, and yet more preferably equal to or smaller than 1.0% of the intensity of the excitation spectrum by excitation light of 455 nm.

A red phosphor is preferred that has an emission peak wavelength of 640 nm or more and 670 nm or less, and a full width at half maximum of 2 nm or more and 120 nm or less. Examples of such phosphors include, for instance, a CaAlSiN₃:Eu phosphor and a 3.5MgO.0.5MgF₂.GeO₂:Mn⁴⁺ phosphor, preferably a CaAlSiN₃:Eu phosphor.

If a second red phosphor is incorporated, the content of the second red phosphor is not particularly limited, so long as the effect of the present invention is not impaired thereby, but the content is preferably 0.0% or more and 50.0% or less, in a composition weight ratio, with respect to the total content of red phosphor.

If a second red phosphor is incorporated and the latter is mixed with a first red phosphor, the excitation spectrum intensity change of the red phosphor mixture at a time where the excitation light wavelength thereof varies from 445 nm to 455 nm is preferably equal to or smaller than 5.0%, more preferably equal to or smaller than 3.0%, and yet more preferably equal to or smaller than 1.0%, of the intensity of the excitation spectrum by excitation light of 455 nm.

Preferably, the sixth to seventh embodiments of the first invention further comprise a red phosphor (also referred to as first red phosphor). The color rendering properties of the light emitted by the light-emitting device can be enhanced, and adjustment at the comparatively low color temperature of the light-emitting device is made easier, by incorporating the first red phosphor.

The excitation spectrum intensity change upon varying the excitation light wavelength of the first red phosphor from 440 nm to 460 nm is preferably equal to or smaller than 4.0%, more preferably equal to or smaller than 3.0%, and yet more preferably equal to or smaller than 1.0% of the intensity of the excitation spectrum by excitation light of 450 nm. Using such a red phosphor results in a light-emitting device having sufficient binning characteristics, while making it possible to further enhance color rendering properties. The lower limit value of the intensity change is not particularly limited, but is equal to or greater than 0%.

Examples of red phosphors that satisfy such requirements include, for instance, (Sr,Ca)AlSiN₃:Eu, Ca₁₋ₓAl₁₋ₓSi₁₊ₓN₃₋ₓOₓ:Eu (where 0<x<0.5), K₂SiF:Mn⁴⁺, Eu_{y}(Sr,Ca,Ba)_{1-y}:Al₁₊ₓSi₄₋ₓOₓN₇₋ₓ (where 0≦x<4, 0≦y<0.2) and the like, preferably (Sr,Ca)AlSiN₃:Eu or Ca₁₋ₓAl₁₋ₓSi₁₊ₓN₃₋ₓOₓ:Eu (where 0<x<0.5).

As the first red phosphor there is preferably incorporated a red phosphor having an emission peak wavelength of 620 nm or more and less than 640 nm, and a full width at half maximum of 2 nm or more and 100 nm or less. Examples of red phosphors satisfying such requirements include, for instance, (Sr,Ca)AlSiN₃:Eu, Ca₁₋ₓAl₁₋ₓSi₁₊ₓN₃₋ₓOₓ:Eu (where 0<x<0.5), Eu_{y}(Sr,Ca,Ba)_{1-y}:Al₁₊ₓSi₄₋ₓOₓN₇₋ₓ (where 0≦x<4, 0≦y<0.2) and K₂SiF:Mn⁴⁺, preferably (Sr,Ca)AlSiN₃:Eu or Ca₁₋ₓAl₁₋ₓSi₁₊ₓN₃₋ₓOₓ:Eu (where 0<x<0.5)

The above (Sr,Ca)AlSiN₃:Eu may be represented by formula MₐA_{b}D_{c}E_{d}Xₑ (in the formula, M is Eu, A is one, two or more elements selected from the group consisting of Mg, Ca, Sr and Ba, D is Si, E is one, two or more elements selected from the group consisting of B, Al, Ga, In, Sc, Y, La, Gd and Lu and having Al as an essential element, X is one, two or more elements selected from the group consisting of O, N and F, and having N as essential element. Further, the values of a, b, c, d and e are selected from among values that satisfy all the conditions 0.00001≦a≦0.1, a+b=1, 0.5≦c≦1.8, 0.5≦d≦1.8, 0.8×(2/3+4/3×c+d)≦e, and e≦1.2×(2/3+4/3×c+d)).

The content of the first red phosphor, having an emission peak wavelength of 620 nm or more and less than 640 nm and a full width at half maximum of 2 nm or more and 100 nm or less is preferably 30% or more, yet more preferably 40% or more, and particularly preferably 50% or more in a composition weight ratio with respect to a total amount of red phosphor.

Preferably, a red phosphor (hereafter also referred to as second red phosphor) is incorporated in addition to, or in place of, the above-described first red phosphor. More preferably, there are incorporated two types of red phosphor.

By incorporating the second red phosphor, a light-emitting device is obtained that allows achieving high conversion efficiency, in addition to good color rendering properties derived from addition of the red phosphor. This increases as a result the degree of freedom as regards the types and amount of phosphors that can be selected.

The excitation spectrum intensity change upon varying the excitation light wavelength of the second red phosphor from 440 nm to 460 nm is preferably equal to or smaller than 5.0%, more preferably equal to or smaller than 3.0%, and yet more preferably equal to or smaller than 1.0% of the intensity of the excitation spectrum by excitation light of 450 nm.

A red phosphor is preferred that has an emission peak wavelength of 640 nm or more and 670 nm or less, and a full width at half maximum of 2 nm or more and 120 nm or less. Examples of such phosphors include, for instance, a CaAlSiN₃:Eu phosphor and a 3.5MgO.0.5MgF₂.GeO₂:Mn⁴⁺ phosphor, and preferably a CaAlSiN₃:Eu phosphor.

If a second red phosphor is incorporated, the content of the second red phosphor is not particularly limited, so long as the effect of the present invention is not impaired thereby, but the content is preferably 0.0% or more and 50.0% or less, in a composition weight ratio, with respect to the total content of red phosphor.

If a second red phosphor is incorporated and the latter is mixed with a first red phosphor, the excitation spectrum intensity change of the red phosphor mixture at a time where the excitation light wavelength thereof varies from 440 nm to 460 nm is preferably equal to or smaller than 5.0%, more preferably equal to or smaller than 3.0%, and yet more preferably equal to or smaller than 1.0%, of the excitation spectrum by excitation light at 450 nm.

So long as the effect of the present invention is not impaired thereby, other known phosphors can be added to the wavelength conversion member of the first to seventh embodiments of the first invention. The resulting wavelength conversion member is encompassed within the scope of the present invention.

The wavelength conversion member according to the first to seventh embodiments of the first invention comprises a transparent material. The transparent material is not particularly limited so long as it can transmit light with substantially no absorption and is used is used when dispersing the phosphor, but, preferably, the refractive index of the transparent material is 1.3 or more and 1.7 or less. The method for measuring the refractive index of the transparent material is as follows. The measurement temperature is 20° C., and the refractive index is measured in accordance with a prism coupler method. The measurement wavelength is 450 nm.

Table 1 sets out the refractive indices of resins ordinarily used as the transparent material. The refractive indices of the resins in Table 1 are ordinary reference values, but the refractive indices of the resins are not necessarily limited to the values of Table 1.

TABLE 1
Refractive indices of resins ordinarily
used as the transparent material

| Transparent material | Representative refractive indices |
|---|---|
| polycarbonate resins | 1.58~1.62 |
| polyester resins | 1.64~1.67 |
| acrylic resins | 1.48~1.57 |
| epoxy resins | 1.55~1.61 |
| silicone resins | 1.41~1.44 |
| Polystyrene resins | 1.54~1.60 |

The resin that is used as the above-described transparent material may be used as a single type alone; alternatively, two or more types of resin can be used in combination. These resins may be copolymers.

Examples of the transparent material that can be used include, for instance, resins such as various thermoplastic resins, thermosetting resins and photocurable resins, or glass, in accordance with the intended application. However, polycarbonate resins and silicone resins can be preferably used in that they are excellent in transparency, heat resistance, mechanical characteristics and flame retardancy. Polycarbonate resins are more preferred in terms of versatility, while silicone resins are preferred in terms of heat resistance.

Polycarbonate resins are explained in detail next.

The polycarbonate resin used in the first to seventh embodiments of the first invention are polymers, represented by Chemical formula (l) below, the basic structure whereof has carbonate bonds.

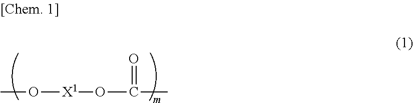

In Chemical formula (l), X¹ is ordinarily a hydrocarbon, but an X¹ having a heteroatom or a hetero-bond introduced thereinto may also be used, in order to impart various characteristics.

Polycarbonate resins can be classified into aromatic polycarbonate resins in which the carbon atoms that are directly bonded to the carbonate bond are aromatic carbons, and aliphatic polycarbonate resins in which such carbons are aliphatic carbons. Both types can be used herein. Aromatic polycarbonate resins are preferred among the foregoing, in terms of, for instance, heat resistance, mechanical properties and electric characteristics.

The specific type of the polycarbonate resin is not limited, but may be, for instance, a polycarbonate polymer resulting from reacting a dihydroxy compound with a carbonate precursor. In addition to the dihydroxy compound and the carbonate precursor, a polyhydroxy compound or the like may be set to participate in the reaction. A method may be resorted to wherein carbon dioxide as a carbonate precursor is caused to react with a cyclic ether. The polycarbonate polymer may be linear or branched. Further, the polycarbonate polymer may be a homopolymer made up of one single type of repeating unit, or a copolymer having two or more types of repeating unit. The copolymerized form of the copolymer can be selected from among various types, for instance that of a random copolymer or a block copolymer. Such a polycarbonate polymer is ordinarily a thermoplastic resin.

Examples of aromatic dihydroxy compounds, from among the monomers that constitute starting materials of aromatic polycarbonate resins, include, for instance, dihydroxybenzenes such as 1,2-dihydroxybenzene, 1,3-dihydroxybenzene (i.e. resorcinol) and 1,4-dihydroxybenzene; dihydroxybiphenyls such as 2,5-dihydroxybiphenyl, 2,2′-dihydroxybiphenyl and 4,4′-dihydroxybiphenyl; dihydroxynaphthalenes such as 2,2′-dyhydroxy-1,1′-binaphthyl, 1,2-dihydroxynaphthalene, 1,3-dihydroxynaphthalene, 2,3-dihydroxynaphthalene, 1,6-dihydroxynaphthalene, 2,6-dihydroxynaphthalene, 1,7-dihydroxynaphthalene and 2,7-dihydroxynaphthalene; dihydroxydiaryl ethers such as 2,2′-dihydroxydiphenyl ether, 3,3′-dihydroxydiphenyl ether, 4,4′-dihydroxydiphenyl ether, 4,4′-dyhydroxy-3,3′-dimethyldiphenyl ether, 1,4-bis(3-hydroxyphenoxy)benzene and 1,3-bis(4-hydroxyphenoxy)benzene; bis(hydroxyaryl)alkanes such as 2,2-bis(4-hydroxyphenyl)propane (that is, bisphenol A), 1,1-bis(4-hydroxyphenyl)propane, 2,2-bis(3-methyl-4-hydroxyphenyl)propane, 2,2-bis(3-methoxy-4-hydroxyphenyl)propane, 2-(4-hydroxyphenyl)-2-(3-methoxy-4-hydroxyphenyl)propane, 1,1-bis(3-tert-butyl-4-hydroxyphenyl)propane, 2,2-bis(4-hydroxy-3,5-dimethylphenyl)propane, 2,2-bis(3-cyclohexyl-4-hydroxyphenyl)propane, 2-(4-hydroxyphenyl)-2-(3-cyclohexyl-4-hydroxyphenyl)propane, α,α′-bis(4-hydroxyphenyl)-1,4-diisopropylbenzene, 1,3-bis[2-(4-hydroxyphenyl)-2-propyl]benzene, bis(4-hydroxyphenyl)methane, bis(4-hydroxyphenyl)cyclohexylmethane, bis(4-hydroxyphenyl)phenylmethane, bis(4-hydroxyphenyl)(4-propenylphenyl)methane, bis(4-hydroxyphenyl)diphenylmethane, bis(4-hydroxyphenyl)naphthylmethane, 1-bis(4-hydroxyphenyl)ethane, 2-bis(4-hydroxyphenyl)ethane, 1,1-bis(4-hydroxyphenyl)-1-phenylethane, 1,1-bis(4-hydroxyphenyl)-1-naphthylethane, 1-bis(4-hydroxyphenyl)butane, 2-bis(4-hydroxyphenyl)butane, 2,2-bis(4-hydroxyphenyl)pentane, 1,1-bis(4-hydroxyphenyl)hexane, 2,2-bis(4-hydroxyphenyl)hexane, 1-bis(4-hydroxyphenyl)octane, 2-bis(4-hydroxyphenyl)octane, 1-bis(4-hydroxyphenyl)hexane, 2-bis(4-hydroxyphenyl)hexane, 4,4-bis(4-hydroxyphenyl)heptane, 2,2-bis(4-hydroxyphenyl)nonane, 10-bis(4-hydroxyphenyl)decane and 1-bis(4-hydroxyphenyl)dodecane; bis(hydroxyaryl)cycloalkanes such as 1-bis(4-hydroxyphenyl)cyclopentane, 1-bis(4-hydroxyphenyl)cyclohexane, 4-bis(4-hydroxyphenyl)cyclohexane, 1,1-bis(4-hydroxyphenyl)-3,3-dimethylcyclohexane, 1-bis(4-hydroxyphenyl)-3,4-dimethylcyclohexane, 1,1-bis(4-hydroxyphenyl)-3,5-dimethylcyclohexane, 1,1-bis(4-hydroxyphenyl)-3,3,5-trimethylcyclohexane, 1,1-bis(4-hydroxy-3,5-dimethylphenyl)-3,3,5-trimethylcyclohexane, 1,1-bis(4-hydroxyphenyl)-3-propyl-5-methylcyclohexane, 1,1-bis(4-hydroxyphenyl)-3-tert-butylcyclohexane, 1,1-bis(4-hydroxyphenyl)-3-tert-butylcyclohexane, 1,1-bis(4-hydroxyphenyl)-3-phenylcyclohexane and 1,1-bis(4-hydroxyphenyl)-4-phenylcyclohexane; cardo structure-containing bisphenols such as 9,9-bis(4-hydroxyphenyl)fluorene, and 9,9-bis(4-hydroxy-3-methylphenyl)fluorene; dihydroxydiaryl sulfides such as 4,4′-dihydroxydiphenyl sulfide and 4,4′-dyhydroxy-3,3′-dimethyldiphenyl sulfide; dihydroxydiaryl sulfoxides such as 4,4′-dihydroxydiphenyl sulfoxide and 4,4′-dyhydroxy-3,3′-dimethyldiphenyl sulfoxide; and dihydroxydiaryl sulfones such as 4,4′-dihydroxydiphenyl sulfone and 4,4′-dyhydroxy-3,3′-dimethyldiphenyl sulfone.

Among the foregoing, bis(hydroxyaryl)alkanes are preferable, bis(4-hydroxyphenyl)alkanes are more preferable, and 2,2-bis(4-hydroxyphenyl)propane (i.e., bisphenol A) is particularly preferable, from the viewpoint of impact resistance and heat-resistance.

The aromatic dihydroxy compounds may be used either as a single kind thereof or as a mixture of more than one kind in any combination and in any ratio.

Examples of monomers that constitute starting materials of aliphatic polycarbonate resins include, for instance, alkanediols such as ethane-1,2-diol, propane-1,2-diol, propane-1,3-diol, 2,2-dimethylpropane-1,3-diol, 2-methyl-2-propylpropane-1,3-diol, butane-1,4-diol, pentane-1,5-diol, hexane-1,6-diol and decane-1,10-diol; cycloalkanediols such as cyclopentane-1,2-diol, cyclohexane-1,2-diol, cyclohexane-1,4-diol, 1,4-cyclohexanedimethanol, 4-(2-hydroxyethyl)cyclohexanol, and 2,2,4,4-tetramethyl-cyclobutane-1,3-diol; glycols such as 2,2′-oxydiethanol (that is, ethylene glycol), diethylene glycol, triethylene glycol, propylene glycol and spiro glycol; aralkyldiols such as 1,2-benzenedimethanol, 1,3-benzenedimethanol, 1,4-benzenedimethanol, 1,4-benzenediethanol, 1,3-bis(2-hydroxyethoxy)benzene, 1,4-bis(2-hydroxyethoxy)benzene, 2,3-bis(hydroxymethyl)naphthalene, 1,6-bis(hydroxyethoxy)naphthalene, 4,4′-biphenyldimethanol, 4,4′-biphenyldiethanol, 1,4-bis(2-hydroxyethoxy)biphenyl, bisphenol A bis(2-hydroxyethyl)ether and bisphenol S bis(2-hydroxyethyl)ether; and cyclic ethers such as 1,2-epoxyethane (that is, ethylene oxide), 1,2-epoxypropane (that is, propylene oxide), 1,2-epoxycyclopentane, 1,2-epoxycyclohexane, 1,4-epoxycyclohexane, 1-methyl-1,2-epoxycyclohexane, 2,3-epoxynorbornane and 1,3-epoxypropane. The foregoing may be used as a single type; alternatively, two or more types may be used concomitantly in any combination and ratios.

Examples of carbonate precursors from among monomers that constitute starting materials of the aromatic polycarbonate resin include, for instance, carbonyl halides, carbonate esters and the like. The carbonate precursors can be used either as a single one or as a combination of two or more kinds in any combination and in any ratio.

Specific examples of carbonyl halides include phosgene, as well as haloformates such as bischloroformate products of dihydroxy compounds and monochloroformate products of dihydroxy compounds.

Specific examples of the carbonate esters include diaryl carbonates such as diphenyl carbonate and ditolyl carbonate; dialkyl carbonates such as dimethyl carbonate and diethyl carbonate; and carbonate products of dihydroxy compounds, such as biscarbonate products of dihydroxy compounds, monocarbonate products of dihydroxy compounds, and cyclic carbonates.

The method for producing the polycarbonate resin is not particularly limited, and any method can be resorted to. Examples thereof include, for instance, interfacial polymerization, melt transesterification, a pyridine method, ring-opening polymerization of cyclic carbonate compounds and solid phase transesterification of prepolymers. Interfacial polymerization and melt transesterification, which are particularly appropriate among these methods, will be explained specifically below.

(Interfacial Polymerization)

In interfacial polymerization, a dihydroxy compound and a carbonate precursor (preferably, phosgene) are caused to react in the presence of an organic solvent that is reaction-inert and in the presence of an alkali aqueous solution while the pH is maintained at 9 or more; thereafter, interfacial polymerization is performed in the presence of a polymerization catalyst, to yield a polycarbonate resin. A molecular weight-adjusting agent (terminating agent) may be present, as needed, in the reaction system. An antioxidant may be present in order to prevent oxidation of the dihydroxy compound.

The dihydroxy compound and the carbonate precursor are as described above. Preferably, phosgene is used among carbonate precursors. A method in which phosgene is used is referred to as a phosgene method.

Examples of organic solvents that are reaction-inert include, for instance: chlorinated hydrocarbons such as dichloromethane, 1,2-dichloroethane, chloroform, monochlorobenzene and dichlorobenzene; and aromatic hydrocarbons such as benzene, toluene and xylene. The organic solvents may be used either as a single kind thereof or as a mixture of more than one kind in any combination and in any ratio.

Examples of the alkali compound contained in the alkali aqueous solution include, for instance, alkali metal compounds such as sodium hydroxide, potassium hydroxide, lithium hydroxide and sodium hydrogen carbonate, as well as alkaline earth metal compounds, but preferably sodium hydroxide and potassium hydroxide among the foregoing. The alkaline compounds may be used either as a single kind thereof or as a mixture of more than one kind in any combination and in any ratio.

The concentration of the alkali compound in the alkali aqueous solution is not particularly limited, but the alkali compound is ordinarily used in an amount of 5 to 10 wt %, in order to control the pH of the alkali aqueous solution in the reaction so as to range from 10 to 12. Upon blowing of phosgene, for instance, the molar ratio of the bisphenol compound and the alkali compound is ordinarily set to 1:1.9 or more, preferably 1:2.0 or more, and ordinarily 1:3.2 or less, preferably 1:2.5 or less, in order to control the solution so that the pH of the water phase ranges from 10 to 12, preferably from 10 to 11.

Examples of the polymerization catalyst include, for instance, aliphatic tertiary amines such as trimethylamine, triethylamine, tributylamine, tripropylamine and trihexylamine; alicyclic tertiary amines such as N,N′-dimethylcyclohexylamine and N,N′-diethylcyclohexylamine; aromatic tertiary amines such as N,N′-dimethylaniline and N,N′-diethylaniline; quaternary ammonium salts such as trimethylbenzylammonium chloride, tetramethylammonium chloride and triethylbenzylammonium chloride; as well as salts of pyridine, guanine and guanidine and the like. The polymerization catalysts may be used either as a single kind thereof or as a mixture of more than one kind in any combination and in any ratio.

Examples of the molecular weight-adjusting agent include, for instance, aromatic phenols having a monovalent phenolic hydroxyl group; aliphatic alcohols such as methanol and butanol; as well as mercaptan and phthalimide, and preferably aromatic phenols among the foregoing. Specific examples of such aromatic phenols include, for instance, alkyl group-substituted phenols such as m-methyl phenol, p-methyl phenol, m-propyl phenol, p-propyl phenol, p-tert-butyl phenol and p-long chain alkyl-substituted phenols; vinyl group-containing phenols such as isopropanil phenol; epoxy group-containing phenols; and carboxyl group-containing phenols such as o-oxybenzoic acid and 2-methyl-6-hydroxyphenyl acetate. The molecular weight adjusting agents may be used either as a single kind thereof or as a mixture of more than one kind in any combination and in any ratio.

The molecular weight adjusting agent is used in an amount that is ordinarily 0.5 moles or more, preferably 1 mole or more, and ordinarily 50 moles or less, preferably 30 moles or less, with respect to 100 moles of the dihydroxy compound. The thermal stability and the hydrolysis resistance of the polycarbonate resin composition can be enhanced by setting the use amount of the molecular weight adjusting agent to lie within the above ranges.

The order in which the reaction substrates, reaction medium, catalyst, additives and so forth are mixed during the reaction may be set arbitrarily to an appropriate order, so long as the desired polycarbonate resin can be obtained. In a case where, for instance, phosgene is used as the carbonate precursor, the molecular weight adjusting agent can be mixed at any time, from the reaction of the dihydroxy compound and phosgene (phosgenation) until the polymerization reaction starts. The reaction temperature ranges ordinarily from 0 to 40° C., and the reaction time ranges ordinarily from several minutes (for instance, 10 minutes) to several hours (for instance, 6 hours).

(Melt Transesterification)

The melt transesterification method involves a transesterification reaction between a carbonic acid diester and a dihydroxy compound.

Examples of the dihydroxy compound include those described above. Examples of carbonic acid diesters include, for instance, dialkyl carbonate compounds such as dimethyl carbonate, diethyl carbonate and di-tert-butyl carbonate; diphenyl carbonate; and substituted diphenyl carbonates such as ditolyl carbonate. Preferred among the foregoing are diphenyl carbonate and substituted diphenyl carbonate, and particularly preferably diphenyl carbonate. The carbonic acid diesters can be used either as a single one or as a mixture of two or more kinds in any combination and in any ratio.

The ratio between the dihydroxy compound and the carbonic acid diester may be any arbitrary ratio, so long as the desired polycarbonate resin can be obtained, but preferably the carbonic acid diester is used in an equimolar amount or greater, and more preferably in an amount of 1.01 moles or more with respect to 1 mole of the dihydroxy compound. The upper limit is set ordinarily at 1.30 moles or less. The amount of terminal hydroxyl groups can be adjusted so as to lie within an appropriate range, by prescribing the above ranges.

The amount of terminal hydroxyl groups in a polycarbonate resin tends to exert a significant influence on the thermal stability, hydrolysis stability, color tone and so forth of the polycarbonate resin. Accordingly, the amount of terminal hydroxyl groups may be adjusted, as needed, in accordance with any known method. A polycarbonate resin in which the amount of terminal hydroxyl groups is adjusted can be ordinarily obtained, in the transesterification reaction, by adjusting, among others, the mixing ratio of the carbonic acid diester and the aromatic dihydroxy compound, and the degree of pressure reduction during the transesterification reaction. Ordinarily, also the molecular weight of the obtained polycarbonate resin can be adjusted as a result of the above operations.

The mixing ratio of carbonic acid diester and dihydroxy compound when adjusting the amount of terminal hydroxyl groups is the above-described mixing ratio. Examples of more aggressive adjustment methods include, for instance, mixing in a terminating agent, separately, during the reaction. Examples of the terminating agents used in such methods include, for instance, monovalent phenols, monovalent carboxylic acids, carbonic acid diesters and the like. The terminating agent may be used either as a single kind thereof or as a mixture of more than one kind in any combination and in any ratio.

A transesterification catalyst is ordinarily utilized when the polycarbonate resin is produced by melt transesterification. Any transesterification catalyst can be used herein. For instance, alkali metal compounds and/or alkaline earth metal compounds are preferably used among such transesterification catalysts. A basic compound, such as a basic boron compound, a basic phosphorous compound, a basic ammonium compound or an amine-based compound, may be supplementarily used concomitantly with the transesterification catalyst. The transesterification catalysts may be used either as a single kind thereof or as a mixture of more than one kind in any combination and in any ratio.

The reaction temperature in melt transesterification ranges ordinarily from 100 to 320° C. The pressure at the time of the reaction is ordinarily lowered to 2 mmHg or less. As a specific operation, it suffices to perform a melt polycondensation reaction, while under removal of by-products such as aromatic hydroxy compounds, under the above conditions.

The melt polycondensation reaction can be conducted according to a batch-wise or continuous method. In the case of a batch-wise scheme, the order in which the reaction substrates, reaction medium, catalyst, additives and so forth are mixed during the reaction may be set to an arbitrary appropriate order, so long as the desired aromatic polycarbonate resin is obtained. In consideration, for instance, of the stability of the polycarbonate resin and the polycarbonate resin composition, however, the melt polycondensation reaction is preferably conducted according to a continuous scheme.

A catalyst deactivator may be used, as needed, in the melt transesterification. Any compound that neutralizes the transesterification catalyst can be used as the catalyst deactivator. Examples thereof include, for instance, sulfur-containing acidic compounds and derivatives thereof. The catalyst deactivators may be used either as a single kind thereof or as a mixture of more than one kind in any combination and in any ratio.

The use amount of the catalyst deactivator is ordinarily 0.5 equivalents or more, preferably 1 equivalent or more, and ordinarily 10 equivalents or less, preferably 5 equivalents or less, with respect to the alkali metal or alkaline earth metal contained in the transesterification catalyst. The use amount of catalyst deactivator is ordinarily 1 ppm or more, and ordinarily 100 ppm or less, and preferably 20 ppm or less, with respect to the aromatic polycarbonate resin.

The molecular weight of the polycarbonate resin may be any appropriately selected and established molecular weight. A viscosity average molecular weight (Mv) converted from solution viscosity is ordinarily 10,000 or greater, preferably 16,000 or greater, more preferably 18,000 or greater, and ordinarily 40,000 or smaller, preferably 30,000 or smaller. By setting the viscosity average molecular weight to be equal to or greater than the lower limit value of the above ranges it becomes possible to further enhance the mechanical strength of the polycarbonate resin composition of the present invention, and to afford a more preferable member in uses where a high mechanical strength is required. By setting the viscosity average molecular weight to be equal to or smaller than the upper limit value of the above range, it becomes possible to improve the polycarbonate resin composition of the present invention, by curtailing drops in the fluidity of the composition, and to enhance moldability, so that the molding process can be performed easily. Two or more types of polycarbonate resin having different viscosity average molecular weights may be used mixed with each other. In this case, the mixture may include a polycarbonate resin the viscosity average molecular weight whereof lies outside the above preferred range.

The viscosity average molecular weight (Mv) denotes herein a value obtained by working out the intrinsic viscosity (η) (units dl/g) at a temperature of 20° C., with an Uberode viscometer using methylene chloride as a solvent, and calculating thereupon the value of the viscosity average molecular weight on the basis of the Schnell's viscosity equation, namely η=1.23×10⁻⁴Mv^{0.83}. The intrinsic viscosity (η) is a value obtained by measuring specific viscosities (ηₛₚ) at respective solution concentrations (C) (g/dl), and calculating then the value of intrinsic viscosity in accordance with Expression (1) below.

$$\begin{matrix}[ Expression 2 ] & \\ η = {lim}_{c 0} {η}_{sp} / c & ( 1 )\end{matrix}$$

The concentration of terminal hydroxyl groups in the polycarbonate resin is arbitrary and may be selected and established as appropriate, but is ordinarily 1,000 ppm or lower, preferably 800 ppm or lower, and more preferably 600 ppm or lower. As a result it becomes possible to further enhance the retention thermal stability and color tone of the polycarbonate resin composition of the present invention. The concentration of terminal hydroxyl groups in the polycarbonate resin is ordinarily 10 ppm or higher, preferably 30 ppm or higher, and more preferably 40 ppm or higher. As a result it becomes possible to suppress drops in molecular weight, while further enhancing the mechanical characteristics of the polycarbonate resin composition of the present invention. The units of terminal hydroxyl group concentration are expressed as the weight (ppm) of the terminal hydroxyl groups with respect to the weight of the polycarbonate resin. The method for measuring the terminal hydroxyl group concentration is herein colorimetry relying on a titanium tetrachloride/acetic acid method (method described in Macromol. Chem. 88 215 (1965)).

The polycarbonate resins may be used either as a single kind thereof or as a mixture of more than one kind in any combination and in any ratio.

The polycarbonate resin may be used as a polycarbonate resin alone (the meaning of the language “polycarbonate resin alone” herein is not limited to a form where the composition comprises only one type of polycarbonate resin, but encompasses also forms where the composition comprises a plurality of types of polycarbonate resin of mutually different monomer compositions and/or molecular weights), or may be in the form of an alloy (mixture) in which the polycarbonate resin is combined with another thermoplastic resin. Further, the polycarbonate resin may be constituted in the form of: a copolymer having a polycarbonate resin as a main constituent, for instance in the form of a copolymer with an oligomer or polymer having a siloxane structure, with a view to further enhancing flame resistance and/or impact resistance; a copolymer with a monomer, oligomer or polymer having phosphorous atoms, with a view to further enhancing thermo-oxidative stability and/or flame retardancy; a copolymer with a monomer, oligomer or polymer having a dihydroxyanthraquinone structure, with a view to enhancing thermo-oxidative stability; a copolymer with an oligomer or polymer having an olefin structure, such as polystyrene, in order to improve optical properties; or a copolymer with a polyester resin oligomer or polymer, with a view to enhancing chemical resistance. If the polycarbonate resin is used in combination with another thermoplastic resin, the proportion of the polycarbonate resin in the resin component is preferably 50 wt % or higher, more preferably 60 wt % or higher, and yet more preferably 70 wt % or higher.

The polycarbonate resin may contain a polycarbonate oligomer in order to improve the external appearance of a molded article and enhance fluidity. The viscosity average molecular weight [Mv] of this polycarbonate oligomer is usually 1,500 or more, preferably 2,000 or more, and usually 9,500 or less, preferably 9,000 or less. Preferably, the content of the polycarbonate oligomer is 30 wt % or less in the polycarbonate resin (including the polycarbonate oligomer).

The polycarbonate resin may be not only a virgin starting material, but also a polycarbonate resin recycled from used articles (so-called material-recycled polycarbonate resin). Examples of such used articles include, for instance, optical recording media such as optical disks; light guide plates; transparent members for vehicles such as automotive window glass, automotive head lamp lenses, windshields and the like; containers such as water bottles; spectacle lenses; and building members such as sound barriers, glass windows and corrugated sheets. Herein there can be used also pulverized products obtained from nonconforming products, sprues, runners and the like, as well as pellets or the like obtained by melting the foregoing.

The content of the regenerated polycarbonate resin is preferably 80 wt % or less, more preferably 50 wt % or less, in the polycarbonate resin of the polycarbonate resin composition of the present invention. The regenerated polycarbonate resin is very likely to degrade on account of thermal degradation or degradation with the passage of time, and, accordingly, using such a polycarbonate resin in an amount greater than that in the above ranges may result in impaired hue and impaired mechanical properties.

Various known additives may be incorporated, as needed, into the transparent material described above, in amounts such that the characteristics of the present invention are not impaired. Examples of such additives include, for instance, heat stabilizers, antioxidants, release agents, flame retardants, flame retardant aids, ultraviolet absorbers, lubricants, light stabilizers, plasticizers, antistatic agents, thermal conductivity improvers, conductivity improvers, colorants, impact improvers, antimicrobial agents, chemical resistance improvers, reinforcing agents, laser marking improvers, refractive index modifiers and the like. The specific types and amounts of these additives can be selected from among known types and amounts that are appropriate for transparent materials.

Examples of preferred additives that are blended with the polycarbonate resin are described next.

Examples of heat stabilizers include, for instance, phosphorous-based compounds. Any known compound may be used as the phosphorous-based compound. Specific examples thereof include oxo acids of phosphorous such as phosphoric acid, phosphonic acid, phosphorous acid, phosphinic acid and polyphosphoric acid; metal acid pyrophosphates such as sodium acid pyrophosphate, potassium acid pyrophosphate and calcium acid pyrophosphate; phosphates of group I or group X metals such as potassium phosphate, sodium phosphate, cesium phosphate and zinc phosphate; and organic phosphate compounds, organic phosphite compounds, and organic phosphonite compounds.

Preferred among the foregoing are organic phosphites such as triphenyl phosphite, tris(monononylphenyl)phosphite, tris(monononyl/dinonyl phenyl)phosphite, tris(2,4-di-tert-butylphenyl)phosphite, monooctyldiphenyl phosphite, dioctylmonophenyl phosphite, monodecyldiphenyl phosphite, didecylmonophenyl phosphite, tridecyl phosphite, trilauryl phosphite, tristearyl phosphite, 2,2-methylenebis(4,6-di-tert-butylphenyl)octyl phosphite and the like.

The content of the heat stabilizer is ordinarily 0.0001 part by weight or greater, preferably 0.001 part by weight or greater, more preferably 0.01 part by weight or greater, and ordinarily 1 part by weight or smaller, preferably 0.5 parts by weight or smaller, more preferably 0.3 parts by weight or smaller and yet more preferably 0.1 part by weight or smaller, with respect 100 parts by weight of the polycarbonate resin. If the content of heat stabilizer is excessively small, the thermal stability improvement effect is difficult to achieve, whereas an excessive content may result in impaired thermal stability.

Examples of antioxidants include hindered phenolic antioxidants. Specific examples thereof include, for instance, pentaerythritoltetrakis[3-(3,5-di-tert-butyl-4-hydroxyphenyl)propionate], octadecyl-3-(3,5-di-tert-butyl-4-hydroxyphenyl)propionate, thiodiethylenebis[3-(3,5-di-tert-butyl-4-hydroxyphenyl)propionate], N,N′-hexane-1,6-diylbis[3-(3,5-di-tert-butyl-4-hydroxyphenyl propionamide), 2,4-dimethyl-6-(1-methylpentadecyl)phenol, diethyl[[3,5-bis(1,1-dimethylethyl)-4-hydroxyphenyl]methyl]phosphate, 3,3′,3″,5,5′,5″-hexa-tert-butyl-α,α′,α″-(mesitylene-2,4,6-triyl)tri-p-cresol, 4,6-bis(octylthiomethyl)-o-cresol, ethylenebis(oxyethylene)bis[3-(5-tert-butyl-4-hydroxy-m-tolyl)propionate], hexamethylenebis[3-(3,5-di-tert-butyl-4-hydroxyphenyl)propionate], 1,3,5-tris(3,5-di-tert-butyl-4-hydroxybenzyl)-1,3,5-triazine-2,4,6(1H,3H,5H)-trione, 2,6-di-tert-butyl-4-(4,6-bis(octylthio)-1,3,5-triazine-2-yl amino)phenol and the like.

Preferred among the foregoing are pentaerythritoltetrakis[3-(3,5-di-tert-butyl-4-hydroxyphenyl)propionate] and octadecyl-3-(3,5-di-tert-butyl-4-hydroxyphenyl)propionate.

The content of the antioxidant is ordinarily 0.001 part by weight or greater, preferably 0.01 part by weight or greater and ordinarily 1 part by weight or smaller, preferably 0.5 parts by weight or smaller, and yet more preferably 0.3 parts by weight or smaller, with respect 100 parts by weight of the polycarbonate resin. If the content of antioxidant is smaller than the lower limit value of the above range, the effect as an antioxidant may fail to be sufficiently brought out, whereas if the content of antioxidant exceeds the upper limit value of the above range, the effect that is achieved may reach a plateau and cease to be economical.

Examples of the release agent include, for instance, aliphatic carboxylic acids, esters of aliphatic carboxylic acids and alcohols, aliphatic hydrocarbon compounds having a number-average molecular weight ranging from 200 to 15000, polysiloxane-based silicone oils and the like.

Examples of aliphatic carboxylic acids include saturated or unsaturated aliphatic monobasic, dibasic and tribasic carboxylic acids. Aliphatic carboxylic acids encompasses herein also alicyclic carboxylic acids. Preferred aliphatic carboxylic acids among the foregoing are monobasic or dibasic carboxylic acids having 6 to 36 carbon atoms, and yet more preferably aliphatic saturated monobasic carboxylic acids having 6 to 36 carbon atoms. Specific examples of such aliphatic carboxylic acids include, for instance, palmitic acid, stearic acid, caproic acid, capric acid, lauric acid, arachidic acid, behenic acid, lignoceric acid, cerotinic acid, melissic acid, tetrariacontanoic acid, montanic acid, adipic acid, azelaic acid and the like.

Examples of aliphatic carboxylic acids in esters of aliphatic carboxylic acids and alcohols include, for instance, the same aliphatic carboxylic acids as listed above. The alcohol may be for instance a saturated monohydric or polyhydric alcohol. The alcohol may have substituents such as fluorine atoms and aryl groups. Preferred among the foregoing are saturated monohydric or polyhydric saturated alcohols having 30 or fewer carbon atoms, and yet more preferably aliphatic or alicyclic saturated or unsaturated monohydric alcohols or aliphatic saturated polyhydric alcohols having 30 or fewer carbon atoms.

Specific examples of such alcohols include, for instance, octanol, decanol, dodecanol, stearyl alcohol, behenyl alcohol, ethylene glycol, diethylene glycol, glycerin, pentaerythritol, 2,2-dihydroxyperfluoropropanol, neopentylene glycol, ditrimethylolpropane, dipentaerythritol and the like.

Specific examples of esters of aliphatic carboxylic acids and alcohols include, for instance, bees wax (mixture containing myricyl palmitate as a main component), stearyl stearate, behenyl behenate, stearyl behenate, glycerin monopalmitate, glycerin monostearate, glycerin distearate, glycerin tristearate, pentaerythritol monopalmitate, pentaerythritol monostearate, pentaerythritol distearate, pentaerythritol tristearate, pentaerythritol tetrastearate and the like.

Examples of aliphatic hydrocarbon compounds having a number average molecular weight ranging from 200 to 15,000 include, for instance, liquid paraffin, paraffin wax, micro wax, polyethylene wax, Fischer-Tropsch wax and α-olefin oligomers having 3 to 12 carbon atoms. Aliphatic hydrocarbons include herein alicyclic hydrocarbons.

Preferred among the foregoing are paraffin wax, polyethylene wax and partially oxidized polyethylene wax, and yet more preferably paraffin wax and polyethylene wax.

The number average molecular weight of the aliphatic hydrocarbon is preferably 5,000 or lower.

Examples of polysiloxane-based silicone oils include for instance dimethylsilicone oil, methylphenylsilicone oil, diphenylsilicone oil, fluorinated alkyl silicone and the like.

The content of the release agent is ordinarily 0.001 part by weight or greater, preferably 0.01 part by weight or greater, and ordinarily 5 parts by weight or smaller, preferably 3 parts by weight or smaller, more preferably 1 part by weight or smaller, and yet more preferably 0.5 parts by weight or smaller, with respect 100 parts by weight of the polycarbonate resin. If the content of the release agent is below the lower limit value of the above range, the releasing property effect may in some instances fail to be elicited sufficiently, whereas if the content of the release agent exceeds the upper limit value of the above range, hydrolysis resistance may be impaired, and for instance mold contamination at the time of injection molding may occur.

Examples of flame retardants include, for instance, organic flame retardants and inorganic flame retardants such as halogen-based, phosphorus-based, organic acid metal salt-based and silicone-based flame retardants, as well as organic halogen compounds, antimony compounds, phosphorus compounds, nitrogen compounds and the like. Examples of flame retardant aids include, for instance, fluororesin-based flame retardant aids.

The flame retardant and the flame retardant aid can be used concomitantly, and a plurality of types thereof can be used in combination. Preferred among the foregoing are phosphorus-based flame retardants, organic acid metal salt-based flame retardants and fluororesin-based flame retardant aids.

Examples of phosphorus-based flame retardants include, for instance, aromatic phosphate esters and phosphazene compounds such as phenoxyphosphazene or aminophosphazene having bonds between phosphorus atoms and nitrogen atoms in the main chain.

Specific examples of the aromatic phosphate ester-based flame retardant include, for instance, triphenyl phosphate, resorcinol bis(dixylenyl phosphate), hydroquinone bis(dixylenyl phosphate), 4,4′-biphenol bis(dixylenyl phosphate), bisphenol A bis(dixylenyl phosphate), resorcinol bis(diphenyl phosphate), hydroquinone bis(diphenyl phosphate), 4,4′-biphenol bis(diphenyl phosphate), bisphenol A bis(diphenyl phosphate) and the like. The content of the flame retardant ranges ordinarily from 0.01 to 30 parts by weight with respect to 100 parts by weight of resin.

Examples of the organic acid metal salt-based flame retardant include, preferably, metal salts of organic sulfonic acids, in particular metal salts of fluorine-containing organic sulfonic acids, specifically potassium perfluorobutanesulfonate.

Examples of organic halogen compounds include, for instance, brominated polycarbonates, brominated epoxy resins, brominated phenoxy resins, brominated polyphenylene ether resins, brominated polystyrene resins, brominated bisphenol A, pentabromobenzyl polyacrylate and the like. Examples of antimony compounds include, for instance, antimony trioxide, antimony pentoxide, sodium antimonate and the like. Examples of nitrogen compounds include, for instance, melamine, cyanuric acid, melamine cyanurate and the like. Examples of inorganic flame retardants include, for instance, aluminum hydroxide, magnesium hydroxide, silicon compounds, boron compounds and the like.

Examples of fluorine-based flame retardant aids include, preferably, fluoroolefin resins, for instance a tetrafluoroethylene resin having a fibril structure. The fluorine-based flame retardant aid may be in any form, for instance in powder form, dispersion form, or powder form where the fluororesin is coated with another resin.

Examples of ultraviolet absorbers include, for instance, inorganic ultraviolet absorbers such as cerium oxide and zinc oxide; and organic ultraviolet absorbers such as benzotriazole compounds, benzophenone compounds, salicylate compounds, cyanoacrylate compounds, triazine compounds, oxanilide compounds, malonic acid ester compounds, hindered amine compounds and the like. Preferred among the foregoing are organic ultraviolet absorbers, more preferably benzotriazole compounds. Through selection of the organic ultraviolet absorber, the polycarbonate resin composition of the present invention tends thus to exhibit better transparency and mechanical properties.

Specific examples of benzotriazole compounds include, for instance, 2-(2′-hydroxy-5′-methylphenyl)benzotriazole, 2-[2′-hydroxy-3′,5′-bis(α,α-dimethylbenzyl)phenyl]-benzotriazole, 2-(2′-hydroxy-3′,5′-di-tert-butylphenyl)-benzotriazole, 2-(2′-hydroxy-3′-tert-butyl-5′-methylphenyl)-5-chlorobenzotriazole, 2-(2′-hydroxy-3′,5′-di-tert-butylphenyl)-5-chlorobenzotriazole), 2-(2′-hydroxy-3′,5′-di-tert-amyl)-benzotriazole, 2-(2′-hydroxy-5′-tert-octylphenyl)benzotriazole, 2,2′-methylenebis[4-(1,1,3,3-tetramethylbutyl)-6-(2N-benzotriazole-2-yl)phenol] and the like. Preferred among the foregoing are 2-(2′-hydroxy-5′-tert-octylphenyl)benzotriazole and 2,2′-methylenebis[4-(1,1,3,3-tetramethylbutyl)-6-(2N-benzotriazole-2-yl)phenol], and particularly preferably 2-(2′-hydroxy-5′-tert-octylphenyl)benzotriazole.

Specific examples of such benzotriazole compounds include “SEESORB 701” (a trade name, the same hereinafter), “SEESORB 702”, “SEESORB 703”, “SEESORB 704”, “SEESORB 705” and “SEESORB 709” by Shiprokasei Kaisha. Ltd.; “BioSorb 520”, “BioSorb 580”, “BioSorb 582” and “BioSorb 583” by Kyodo Chemical Co., Ltd., “ChemiSorb 71” and “ChemiSorb 72” by Chemiprokasei Kaisha, Ltd.; “Cyasorb UV5411” by Cytec Industries Inc.; “LA-32”, “LA-38”, “LA-36”, “LA-34” and “LA-31” by Adeka Corporation; and “TINUVIN P”, “TINUVIN 234”, “TINUVIN 326”, “TINUVIN 327” and “TINUVIN 328” by Ciba Specialty Chemicals Corporation.

The preferred content of ultraviolet absorber is 0.01 part by weight or greater, more preferably 0.1 part by weight or greater, and 5 parts by weight or smaller, preferably 3 parts by weight or smaller, more preferably 1 part by weight or smaller, and yet more preferably 0.5 parts by weight or smaller, with respect to 100 parts by weight of the polycarbonate resin. If the content of ultraviolet absorber is smaller than the lower limit value of the above range, the weatherability improving effect may be insufficient, whereas if the content of the ultraviolet absorber exceeds the upper limit value of the above range, mold deposits or the like may form, giving rise to mold contamination. The ultraviolet absorbers may be contained either as a single kind thereof or as a mixture of more than one kind in any combination and in any ratio.

The silicone resin will be explained in detail next.

The silicone resin used in the first to seventh embodiments of the first invention is not particularly limited, but, preferably, the smaller the absorption of visible light by the silicone resin, the smaller is the light loss that is incurred. A liquid silicone resin or the like is preferred herein in terms of mixing with phosphors and workability in the wavelength conversion member. A liquid silicone resin of addition curing type, where curing is accomplished as a result of a hydrosilylation reaction, is particularly preferred since in such a case no by-products are generated during curing, and there occur no problems such as abnormal increases in pressure within the mold, with sink marks and bubbles less likely to occur in the molded article, and is also preferred in that the curing rate is high, which allows shortening the molding cycle.

Liquid silicone resins of addition curing type contain an organopolysiloxane (first component) having hydrosilyl groups, an organopolysiloxane (second component) having alkenyl groups, and a curing catalyst.

Typical examples of the first component include polydiorganosiloxanes having two or more hydrosilyl groups in the molecule, specifically polydiorganosiloxanes having hydrosilyl groups at both ends, as well as polymethylhydrosiloxane and methylhydrosiloxane-dimethylsiloxane copolymers and the like in which both ends are capped with trimethylsilyl groups. As the second component there is preferably used an organopolysiloxane having, per molecule, at least two vinyl groups bonded to silicon atoms. An organopolysiloxane may also be used that doubles as the first component and the second component, i.e. an organopolysiloxane that has both hydrosilyl groups and alkenyl groups in the molecule. The first component and the second component may be each used singly. Alternatively, two or more types of the first component and/or the second component may be used concomitantly.

The purpose of the curing catalyst is to accelerate the addition reaction between the hydrosilyl groups in the first component and the alkenyl groups in the second component. Examples of the curing catalyst include, for instance, platinum-based catalysts such as platinum black, platinum (II) chloride, chloroplatinic acid, reaction products of a monohydric alcohol and chloroplatinic acid, complexes of olefins and chloroplatinic acid, platinum bisacetoacetate and the like; as well as palladium-based catalysts, rhodium-based catalysts, and other metal catalysts of the platinum group. The curing catalyst may be used singly, or two or more types can be used concomitantly.

Further, fumed silica can be added to the silicone resin with a view to imparting thixotropy to a starting material composition.

Fumed silica is in the form of ultra-microparticles having a large specific surface area, for instance 50 m²/g or greater. Examples of commercially available fumed silica include, for instance, Aerosil (registered trademark), by Nippon Aerosil Co., Ltd., and WACKER HDK (registered trademark), by Asahi Kasei Wacker Silicone Co., Ltd. Imparting thixotropy is effective in preventing the composition of the starting material composition from becoming uneven due to phosphor settling.

In particular, thixotropy can be imparted to the starting material composition, without incurring excessive thickening, by using hydrophobic fumed silica the surface whereof has been modified with, for instance, trimethylsilyl groups, dimethylsilyl groups, dimethylsilicone chains or the like. In other words, a starting material composition can be obtained that combines high fluidity, suitable for injection molding, with a phosphor anti-settling effect.

The addition amount of fumed silica is not particularly limited, but is ordinarily 0.1 part by weight or more, preferably 0.5 parts by weight or more, and particularly preferably 1 part by weight or more, and ordinarily 20 parts by weight or less, preferably 18 parts by weight or less, and particularly preferably 15 parts by weight or less, with respect to 100 parts by weight of the silicone resin. A content smaller than 0.1 part by weight is undesirable, since this precludes achieving sufficiently high fluidity suitable for injection molding, or a sufficient phosphor anti-settling effect. A content in excess of 20 parts by weight is likewise undesirable in that viscosity becomes then high, and sufficient fluidity during injection molding cannot be achieved.

The starting material composition may have added thereto, as needed, other additives, for instance, curing rate controlling agents, antioxidants, radical inhibitors, ultraviolet absorbers, adhesion improvers, flame retardants, surfactants, storage stability improvers, antiozonants, light stabilizers, plasticizers, coupling agents, antioxidants, heat stabilizers, antistatic agents, release agents and the like.

The wavelength conversion member of the first to seventh embodiments of the first invention may contain a diffusing material. By containing the diffusing material, the wavelength conversion member can be imparted with light diffusion properties.

If the wavelength conversion member contains a diffusing material, the diffusing material is preferably an inorganic light diffusing material, an organic light diffusing material, or bubbles.

Specific examples of inorganic light diffusing materials include, for instance, materials such as silicon dioxide (silica), white carbon, fused silica, talc, magnesium oxide, zinc oxide, titanium oxide, aluminum oxide, zirconium oxide, boron oxide, boron nitride, aluminum nitride, silicon nitride, calcium carbonate, barium carbonate, magnesium carbonate, aluminum hydroxide, calcium hydroxide, magnesium hydroxide, aluminum hydroxide, barium sulfate, calcium silicate, magnesium silicate, aluminum silicate, sodium aluminosilicate, zinc silicate, zinc sulfide, glass particles, glass fibers, glass flakes, mica, wollastonite, zeolites, sepiolite, bentonite, montmorillonite, hydrotalcite, kaolin and potassium titanate.

These inorganic light diffusing materials may be treated using various surface treatment agents such as silane coupling agents, titanate coupling agents, methylhydrogenpolysiloxane, fatty acid-containing hydrocarbon compounds and the like, or may have the surface thereof covered with an inert inorganic compound.

Examples of organic light diffusing materials include, for instance, materials such as styrene (co)polymers, acrylic (co)polymers, siloxane (co)polymers, polyamide (co)polymers and the like. Part or the entirety of the molecules of the organic diffusing material may be crosslinked or not crosslinked. The language “(co)polymer” denotes both “polymer” and “copolymer”.

Preferably, the diffusing material includes at least one type selected from the group consisting of silica, glass, calcium carbonate, mica, crosslinked acrylic (co)polymer particles and siloxane (co)polymer particles. Moreover, the average particle diameter is preferably 1 μm or larger and preferably 30 μm or smaller. The average particle size is measured herein on the basis of, for instance, a cumulative weight percentage, or using a particle size distribution meter.

Preferably, the Mohs hardness of the diffusing material is smaller than 8, and more preferably smaller than 7. Discoloration of the molded body is suppressed, while precluding vessel damage and impurity intrusion, by using a diffusing material of such hardness.

Preferably, the ratio L/D of the major axis L and the minor axis D of the diffusing material is equal to or smaller than 200. Discoloration of the molded body is suppressed, while precluding vessel damage and impurity intrusion, by using a diffusing material that satisfies the above range. The ratio of L/D is preferably equal to or smaller than 50.

To adjust the transmittance of the wavelength conversion member by way of the diffusing material, for instance, there is added a diffusing material of small average particle size, or a diffusing material of large refractive index difference with respect to that of the transparent material. Alternatively, the transmittance of the wavelength conversion member can be adjusted to a lower one by increasing the addition amount of the diffusing material. The average particle size of the diffusing material is ordinarily 100 μm or smaller, and ranges preferably from 0.1 to 30 μm, more preferably from 0.1 to 15 μm and yet more preferably from 1 to 5 μm.

From among the materials described above, a material is preferably selected that affords a large difference between the refractive index of the selected diffusing material and the refractive index of the transparent material, in order to enhance the light diffusion effect while using a small amount of the diffusing material. A material having high transparency is preferably selected to preclude a significant drop in emission efficiency.

In a case, for instance, where the transparent material is a polycarbonate resin, the diffusing material that is used is preferably crosslinked acrylic (co)polymer particles, crosslinked particles of a copolymer of an acrylic compound and a styrenic compound, siloxane (co)polymer particles, or hybrid-type crosslinked particles of an acrylic compound and a compound comprising silicon atoms, and more preferably, crosslinked acrylic (co)polymer particles or siloxane (co)polymer particles.

The crosslinked acrylic (co)polymer particles are more preferably polymer particles made up of a non-crosslinkable acrylic monomer and a crosslinkable monomer, and yet more preferably polymer particles resulting from crosslinking of methyl methacrylate and trimethylolpropane tri(meth)acrylate. The siloxane (co)polymer is more preferably polyorganosilsesquioxane particles and yet more preferably polymethylsilsesquioxane particles.

In the present invention, in particular, polymethylsilsesquioxane particles are preferably used on account of the excellent thermal stability that they afford.

The dispersion shape of the diffusing material in the wavelength conversion member may be any one from among substantially spherical, plate-like, needle-like or irregular shapes, but is preferably substantially spherical, since in that case the light scattering effect exhibits no anisotropy. The average dimension of the diffusing material is ordinarily 100 μm or smaller, preferably 30 μm or smaller and more preferably 10 μm or smaller, and ordinarily 0.01 μm or greater, and preferably 0.1 μm or greater. If the average dimension of the diffusing material lies outside the above ranges, light diffusion properties are prone to vary significantly as a result of small variations in the content or the particle size of the diffusing material. This may render stable control of the light diffusion properties difficult, and sufficient light diffusion properties, as required in the present invention, may be difficult to bring out. As a result, moreover, the wavelength conversion efficiency may be difficult to control stably within a preferred range. The average dimension of the diffusing material is herein a 50% average dimension, on volume basis, i.e. the value of median diameter (D50) of a volume-basis particle size distribution as measured in accordance with a laser or diffraction scattering method.

The particle size distribution of the diffusing material may be monodisperse, or polydisperse having several peak tops, or may have a narrow or wide particle size distribution, with one peak top, but preferably the particle size distribution is narrow, of substantially single particle size (particle size distribution that is monodisperse or nearly monodisperse).

Indicators for the extent of the particle diameter distribution of the diffusing material include the ratio (Dᵥ/Dₙ) between a volumetric basis average particle diameter Dᵥ and a number mean diameter Dₙ of the diffusing material. In the invention of the present application, Dᵥ/Dₙ is preferably 1.0 or higher. Preferably, Dᵥ/Dₙ is 5 or lower. If Dᵥ/Dₙ is too large, diffusing materials whose weight greatly varies are present and there tends to be a non-uniform distribution of diffusing materials in the wavelength conversion member.

The inorganic light diffusing material, organic light diffusing material and bubbles that are utilized as the diffusing material described above may be used singly or as a combination of two or more types of different substances or dimensions. If a combination of two or more types is resorted to, the refractive index of the diffusing material is calculated on the basis of the volume average of the plurality of diffusing materials.

Preferably, the refractive index of the diffusing material is 1.0 or more and 1.9 or less. Preferably, the diffusing material has high transparency and excellent optical transmissivity, and may have for instance an extinction coefficient of 10⁻² or smaller, preferably 10⁻³ or smaller, yet more preferably 10⁻⁴ or smaller, and particularly preferably 10⁻⁶ or smaller. The refractive index of the diffusing material can be measured in accordance with the immersion method by Yoshiyama et al. (Journal of Aerosol Research, Vol. 9, No. 1 Spring pp. 44-50 (1994)). The measurement temperature is 20° C. and the measurement wavelength is 450 nm.

Table 2 sets out the refractive indices of materials ordinarily used as a diffusing material. The refractive indices of the materials in Table 2 are ordinary reference values, but the refractive indices of the materials are not necessarily limited to the values of Table 2.

TABLE 2
Refractive indices of materials ordinarily used as
a diffusing material

| | | | Representative |
|---|---|---|---|
| Diffusing material | | | refractive indices |
| inorganic | Metal | silicon oxide | 1.44~1.46 |
| | oxide | aluminum oxide | 1.76~1.79 |
| | | titanium oxide | 2.5~2.7 |
| | | zinc oxide | 1.9~2.0 |
| | | magnesium oxide | 1.72~1.75 |
| | | zirconium oxide | 1.8~2.1 |
| | Metal | calcium carbonate | 1.48~1.68 |
| | salt | barium carbonate | 1.53~1.60 |
| | | magnesium carbonate | 1.51~1.53 |
| | | barium sulfate | 1.63~1.65 |
| | | aluminum hydroxide | 1.64~1.67 |
| | | calcium hydroxide | 1.56~1.58 |
| | | magnesium hydroxide | 1.55~1.59 |
| | The | clay | 1.62 |
| | others | talc | 1.57 |
| | | kaolin | 1.55 |
| | | mica | 1.58 |

| organic | styrene (co)polymers | 1.54~1.60 |
|---|---|---|
| | acrylic (co)polymers | 1.48~1.57 |
| | siloxane (co)polymers | 1.35~1.55 |

The content of the diffusing material in the wavelength conversion member varies also depending on the type of transparent material. In a case where, for instance, the transparent material is a polycarbonate resin and the diffusing material is polymethylsilsesquioxane particles, the content of the diffusing material is ordinarily 0.1 part by weight or greater, preferably 0.3 parts by weight or greater, more preferably 0.5 parts by weight or greater, and ordinarily 10.0 parts by weight or smaller, preferably 7.0 parts by weight or smaller, and more preferably 3.0 parts by weight or smaller, with respect to 100 parts by weight of the polycarbonate resin. If the content of the diffusing material is excessively small, the diffusion effect may be insufficient, whereas if the content is excessively large, mechanical characteristics may in some instances impaired, all of which is undesirable.

The second invention of the present invention pertains to a wavelength conversion member, such that in a first embodiment of the invention, the wavelength conversion member comprises:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4);

a phosphor G represented by formula (G1) below and having a peak wavelength of 520 nm or more and 540 nm or less in an emission wavelength spectrum when excited at 450 nm,

(Y,Ce,Tb,Lu)ₓ(Ga,Sc,Al)_{y}O_{z} (G1)

(x=3, 4.5≦y≦5.5, 10.8≦z≦13.4); and

a transparent material.

The wavelength conversion member according to the first to sixth embodiments of the second invention is a member that absorbs part or the entirety of excitation light, and converts the absorbed light to light of another wavelength. The explanation on the first to sixth embodiments of the first invention applies also to the configuration of the present wavelength conversion member.

The method for producing the wavelength conversion member is not particularly limited, and a known method may be resorted to. In a case where, for instance, the transparent material is a polycarbonate resin, an ordinary production method may be as follows.

The phosphors and other components that are formulated as needed, such as the diffusing material, are added to the polycarbonate resin, and the whole is mixed in various mixing equipment such as a Henschel mixer or a tumbler mixer. Mixing may be accomplished by mixing all the starting materials at once, or in a staggered fashion by dividing some of the starting materials. Thereafter, the whole is melted and kneaded using a Banbury mixer, a roll, a Brabender, a single-screw kneading extruder, a twin-screw extruder, a kneader or the like, to yield resin composition pellets.

If the transparent material is a polycarbonate resin, preferred conditions are exemplified in further detail for a case where diffusing material other than bubbles is incorporated.

The polycarbonate resin, the phosphors, the diffusing material and other additives are mixed in a tumbler mixer, and thereafter the whole is melt-kneaded using a single-screw or a twin-screw extruder. As a melt-kneading condition, a screw is used that is configured with a screw in the form of a forward-feed flight screw element in the center, so as not to apply an excessive shearing force. Frequent use of a screw element that bears a significant load of shearing forces, for instance a reverse-feed flight screw or a kneading screw element, is undesirable, since this may result in resin discoloration. A material that is not readily abraded and that has been subjected to an abrasion-resistance treatment is preferably used as the material of the screws and cylinders, in the case of a solid phosphor.

The kneading temperature ranges preferably from 230 to 340° C. An actually measured resin temperature in excess of 340° C. is likely to result in discoloration, and is thus undesirable. A resin temperature lower than 230° C. translates into an excessively high melt viscosity of the polycarbonate resin, and thus into a significant mechanical load on the extruder, and is accordingly undesirable. Particularly preferably, the kneading temperature ranges from 240 to 300° C.

The screw revolutions and the discharge amount may be appropriately selected in consideration of the production rate, extruder load and state of the resin pellets. Preferably, the extruder has disposed therein, at one or more sites, a venting structure in which air that is engulfed together with the starting material, as well as gas generated through heating, can be discharged out of the extruder system.

The wavelength conversion member is molded using the polycarbonate resin composition pellets thus obtained.

The molding method of the wavelength conversion member is not particularly limited, and any known molding method may be resorted to, in accordance with the required specifications. Examples include, for instance, extrusion molding of sheets, films or the like, profile extrusion molding, vacuum molding, injection molding, blow molding, injection blow molding, rotational molding, foam molding and the like. Injection molding is preferably resorted to among the foregoing. The resulting molded body can then be worked, for instance welded, bonded, cut or the like, as needed. If the diffusing material is bubbles, the latter can be formed inside the member by relying on a technique such as blowing-agent blending, nitrogen gas injection, supercritical gas injection or the like.

The wavelength conversion member may be of a form where only the phosphor composition is molded, or may be a wavelength conversion member resulting from molding of a transparent substrate, such as a glass or acrylic plate, coated with the phosphor composition.

The above polycarbonate resin composition pellets are one example of the phosphor composition that is a third invention of the present invention.

A third invention of the present invention pertains to the phosphor composition. A first embodiment of the third invention is a phosphor composition comprising:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4);

a phosphor G represented by formula (G1) below and having a peak wavelength of 520 nm or more and 540 nm or less in an emission wavelength spectrum when excited at 450 nm,

(Y,Ce,Tb,Lu)ₓ(Ga,Sc,Al)_{y}O_{z} (G1)

(x=3, 4.5≦y≦5.5, 10.8≦z≦13.4); and

a transparent material.

The phosphor composition is not limited to being in pellet form, but is preferably in pellet form, in terms of fluidity and ease of handling. The explanation on the first to sixth embodiments of the second invention above applies to the method for molding the phosphor composition according to the first to sixth embodiments of the third invention to yield a wavelength conversion member. The explanation on the first to seventh embodiments of the first invention applies also to the features of the phosphor composition.

A fourth invention of the present invention pertains to a phosphor mixture. In a first embodiment of the present invention, the phosphor mixture comprises:

a phosphor Y represented by formula (Y1) below and having a peak wavelength of 540 nm or more and 570 nm or less in an emission wavelength spectrum when excited at 450 nm,

(Y,Ce,Tb,Lu)ₓ(Ga,Sc,Al)_{y}O_{z} (Y1)

(x=3, 4.5≦y≦5.5, 10.8≦z≦13.4); and

a phosphor G represented by formula (G1) below and having a peak wavelength of 520 nm or more and 540 nm or less in an emission wavelength spectrum when excited at 450 nm.

(Y,Ce,Tb,Lu)ₓ(Ga,Sc,Al)_{y}O_{z} (G1)

(x=3, 4.5≦y≦5.5, 10.8≦z≦13.4)

As a second embodiment, preferably, the variation in excitation spectrum intensity at an emission wavelength of 540 nm is equal to or smaller than 0.40.

The variation in excitation spectrum intensity of the phosphor mixture is expressed as the difference between a maximum value and a minimum value of excitation spectrum intensity in the range from 430 nm to 470 nm, taking 1.0 as the excitation spectrum intensity of the phosphor mixture at 450 nm. The variation in excitation spectrum intensity is calculated using the intensity at an emission wavelength of 540 nm.

The variation in excitation spectrum intensity can be worked out by measuring the excitation spectrum of the phosphor mixture using a fluorescence spectrophotometer F-4500, by Hitachi, Ltd., at room temperature (25° C.). More specifically, the variation in excitation spectrum intensity is obtained by monitoring the emission peak at 540 nm, obtaining thereby the excitation spectrum in a wavelength range of 430 nm or more and 470 nm or less, and then calculating the excitation spectrum intensity change upon modifying the excitation wavelength from 430 nm to 470 nm, taking 1.0 as the excitation spectrum intensity at the excitation wavelength of 450 nm.

Preferably, the variation in excitation spectrum intensity of the wavelength conversion member at an emission wavelength of 540 nm is prescribed to be equal to or smaller than 0.36, and more preferably equal to or smaller than 0.33. Adopting the above range elicits the effects of curtailing abrupt changes in the emission spectrum in response to excitation wavelength changes, and obtaining good binning characteristics. The variation in excitation spectrum intensity is preferably equal to or greater than 0.03, more preferably equal to or greater than 0.05. When the variation in excitation spectrum intensity is equal to or smaller than 0.03, the emission spectrum intensity of a case where the excitation wavelength changes remains the same, but photopic sensitivity varies and, as a result, luminance and chromaticity may in some instances vary substantially, which is undesirable.

As a third embodiment, preferably

the phosphor Y is a phosphor represented by formula (Y2) below,

the phosphor G is a phosphor represented by formula (G2) below, and

the variation in excitation spectrum intensity at an emission wavelength of 540 nm is equal to or smaller than 0.30.

Yₐ(Ce,Tb,Lu)_{b}(Ga,Sc)_{c}Al_{d}Oₑ (Y2)

(a+b=3, 0≦b≦0.2, 4.5≦c+d≦5.5, 0≦c≦0.2, 10.8≦e≦13.4)

Yₐ(Ce,Tb,Lu)_{b}(Ga,Sc)_{c}Al_{d}Oₑ (G2)

(a+b=3, 0≦b≦0.2, 4.5≦c+d≦5.5, 1.2≦c≦2.6, 10.8≦e≦13.4)

The variation in excitation spectrum intensity of the phosphor mixture is expressed as the difference between a maximum value and a minimum value of excitation spectrum intensity in the range from 435 nm to 470 nm, taking 1.0 as the excitation spectrum intensity of the wavelength conversion member at 450 nm. The variation in excitation spectrum intensity is calculated using the intensity at an emission wavelength of 540 nm.

The variation in excitation spectrum intensity can be measured in the same way as above. More specifically, the variation in excitation spectrum intensity is obtained by monitoring the emission peak at 540 nm, obtaining thereby the excitation spectrum in a wavelength range of 435 nm or more and 470 nm or less, and then calculating the excitation spectrum intensity change upon modifying the excitation wavelength from 435 nm to 470 nm, and taking 1.0 as the excitation spectrum intensity at the excitation wavelength of 450 nm.

Preferably, the variation in excitation spectrum intensity of the wavelength conversion member at an emission wavelength of 540 nm is prescribed to be equal to or smaller than 0.28, and more preferably equal to or smaller than 0.25. Adopting the above range elicits the effects of curtailing abrupt changes in the emission spectrum in response to excitation wavelength changes, and obtaining good binning characteristics. The variation in excitation spectrum intensity is desirably at least 0.03, and more preferably at least 0.05.

If the phosphor is a YAG phosphor, the full width at half maximum is preferably 100 nm or more and 130 nm or less, from the viewpoint of color rendering properties. If the phosphor G is a GYAG phosphor, the full width at half maximum is preferably 105 nm or more and 120 nm or less, from the viewpoint of color rendering properties.

As a fourth embodiment, preferably,

the phosphor Y is a phosphor represented by formula (Y3) below,

the phosphor G is a phosphor represented by formula (G3) below, and

the variation in excitation spectrum intensity at an emission wavelength of 540 nm is equal to or smaller than 0.25.

Yₐ(Ce,Tb,Lu)_{b}(Ga,Sc)_{c}Al_{d}Oₑ (Y3)

(a+b=3, 0≦b≦0.2, 4.5≦c+d≦5.5, 0≦c≦0.2, 10.8≦e≦13.4)

Lu_{f}(Ce,Tb,Y)_{g}(Ga,Sc)ₕAlᵢOⱼ (G3)

(f+g=3, 0≦g≦0.2, 4.5≦h+i≦5.5, 0≦h≦0.2, 10.8≦j≦13.4)

The variation in excitation spectrum intensity of the phosphor mixture is expressed as the difference between a maximum value and a minimum value of excitation spectrum intensity in the range from 435 nm to 465 nm, taking 1.0 as the excitation spectrum intensity of the wavelength conversion member at 450 nm. The variation in excitation spectrum intensity is calculated using the intensity at an emission wavelength of 540 nm.

The variation in excitation spectrum intensity can be measured as described above. More specifically, the variation in excitation spectrum intensity is obtained by monitoring the emission peak at 540 nm, obtaining thereby the excitation spectrum in a wavelength range of 435 nm or more and 465 nm or less, and then calculating the excitation spectrum intensity change upon modifying the excitation wavelength from 435 nm to 465 nm, taking 1.0 as the excitation spectrum intensity at the excitation wavelength of 450 nm.

Preferably, the variation in excitation spectrum intensity of the wavelength conversion member at an emission wavelength of 540 nm is prescribed to be equal to or smaller than 0.23, and more preferably equal to or smaller than 0.20. Adopting the above range elicits the effects of curtailing abrupt changes in the emission spectrum in response to excitation wavelength changes, and obtaining good binning characteristics.

The variation in excitation spectrum intensity is preferably equal to or greater than 0.03, more preferably equal to or greater than 0.05.

If the phosphor is a YAG phosphor, the full width at half maximum is preferably 100 nm or more and 130 nm or less, from the viewpoint of color rendering properties. If the phosphor G is a LuAG phosphor, the full width at half maximum is preferably 30 nm or more and 120 nm or less, from the viewpoint of color rendering properties.

A fifth embodiment is a phosphor mixture, comprising

a phosphor G represented by formula (G4) below and having a peak wavelength of 520 nm or more and 540 nm or less in an emission wavelength spectrum when excited at 450 nm.

The variation in excitation spectrum intensity of the phosphor mixture at an emission wavelength of 540 nm is equal to or smaller than 0.25.

Lu_{f}(Ce,Tb,Y),(Ga,Sc)ₕAlᵢOⱼ (G4)

(f+g=3, 0≦g≦0.2, 4.5≦h+i≦5.5, 0≦h≦0.2, 10.8≦j≦13.4)

The variation in excitation spectrum intensity of the phosphor mixture is expressed as the difference between a maximum value and a minimum value of excitation spectrum intensity in the range from 435 nm to 465 nm, taking 1.0 as the excitation spectrum intensity of the phosphor mixture at 450 nm.

The variation in excitation spectrum intensity can be worked out by measuring the excitation spectrum of the phosphor mixture using a fluorescence spectrophotometer F-4500, by Hitachi, Ltd., at room temperature (25° C.). More specifically, the variation in excitation spectrum intensity is obtained by monitoring the emission peak at 540 nm, obtaining thereby the excitation spectrum in a wavelength range of 435 nm or more and 465 nm or less, and then calculating the excitation spectrum intensity change upon modifying the excitation wavelength from 435 nm to 465 nm, and taking 1.0 as the excitation spectrum intensity at the excitation wavelength of 450 nm.

Preferably, the variation in excitation spectrum intensity of the wavelength conversion member at an emission wavelength of 540 nm is prescribed to be equal to or smaller than 0.23, and more preferably equal to or smaller than 0.20. Adopting the above range elicits the effects of curtailing abrupt changes in the emission spectrum in response to excitation wavelength changes, and obtaining good binning characteristics.

The variation in excitation spectrum intensity is preferably equal to or greater than 0.03, more preferably equal to or greater than 0.05.

The explanation on the first to seventh embodiments of the first invention applies also to other features of the phosphor mixture according to the first to sixth embodiments of the fourth invention. The explanation on the first to sixth embodiments of the second invention above applies to the method of kneading and molding the phosphor mixture with a silicone resin or polycarbonate resin to yield the wavelength conversion member. Specifically, the method described in the Examples can be resorted to herein.

Features of the light-emitting device according to the first to seventh embodiments of the first invention of the present invention will be explained next with reference to accompanying drawings.

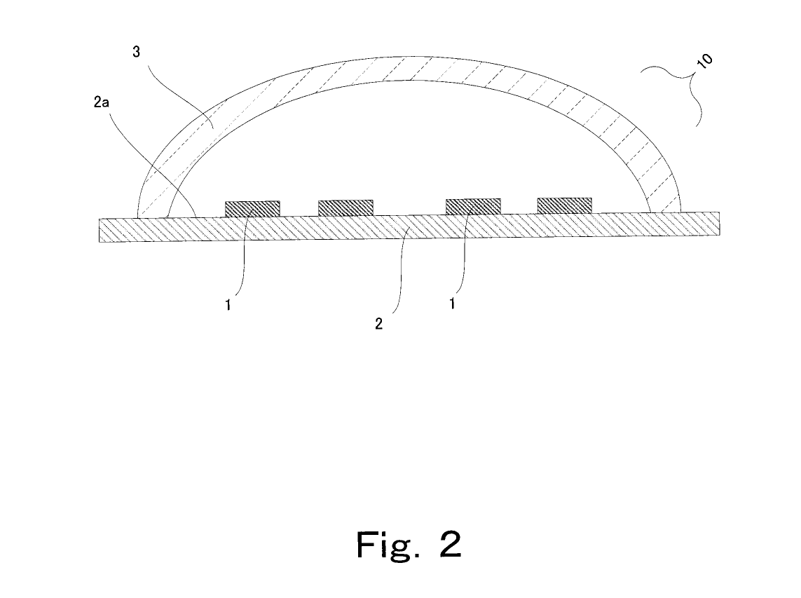

FIG. 2 is a schematic diagram illustrating an example of a light-emitting device comprising a wavelength conversion member according to the first to seventh embodiments of the first invention.

A semiconductor light-emitting device 10 has, as constituent members, at least blue semiconductor light-emitting elements 1 and a wavelength conversion member 3. The blue semiconductor light-emitting elements 1 emit excitation light for exciting phosphors contained in the wavelength conversion member 3.

Ordinarily, the blue semiconductor light-emitting elements 1 emit excitation light having a peak wavelength ranging from 425 nm to 475 nm, preferably excitation light having a peak wavelength ranging from 430 nm to 465 nm. The number of the blue semiconductor light-emitting elements 1 can be set as appropriate depending on the strength of the excitation light that is required by the device.

Violet semiconductor light-emitting elements can be used instead of the blue semiconductor light-emitting elements 1. Ordinarily, violet semiconductor light-emitting elements emit excitation light having a peak wavelength ranging from 390 nm to 425 nm, preferably excitation light having a peak wavelength ranging from 395 to 415 nm.

The blue semiconductor light-emitting elements 1 are mounted on a chip mounting surface 2a of a wiring board 2. The wiring board 2, which constitutes an electric circuit, has formed thereon a wiring pattern (not shown) for supplying an electrode to the blue semiconductor light-emitting elements 1. In FIG. 2, the wavelength conversion member 3 is depicted resting on the wiring board 2, but this configuration is non-limiting, and for instance the wiring board 2 and the wavelength conversion member 3 may be disposed with another member interposed therebetween.

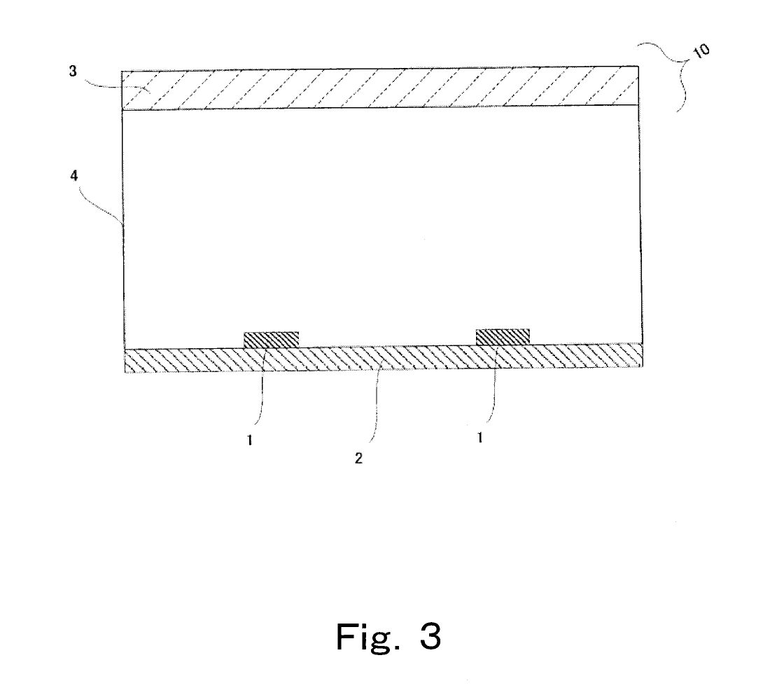

In FIG. 3, for instance, the wiring board 2 and the wavelength conversion member 3 are disposed with a frame body 4 interposed therebetween. The frame body 4 may be tapered, in order to impart directionality to light. The frame body 4 may be a reflective material.

Preferably, the wiring board 2 has excellent electrical insulating properties, good heat dissipation properties, and high reflectance. A high-reflectance reflective plate can be provided at least on part of a face, on the chip mounting surface of the wiring board 2, at which no blue semiconductor light-emitting element 1 is present, or on part of an inner face of another member that connects the wiring board 2 and the wavelength conversion member 3. Preferably, the reflectance of such a wiring board or reflective plate is 80% or higher. Alumina ceramic, resins, glass epoxy, and composite resins including a filler in a resin may be used as such a wiring board. Further, a resin including a white pigment such as an alumina powder, a silica powder, magnesium oxide, titanium oxide, zirconium oxide, zinc oxide, and zinc sulfide can be used as a reflector plate disposed on the chip mounting surface 2a of the wiring board 2. Examples of preferred resins include, for instance, silicone resins, polycarbonate resins, polybutylene terephthalate resins, polyphenylene sulfide resins, fluororesins and the like.

The wavelength conversion member 3 converts the wavelength of part of the incident light emitted by the blue semiconductor light-emitting elements 1, and emits outgoing light having a wavelength different from that of the incident light. The wavelength conversion member 3 contains a transparent material and the phosphor G, and preferably further contains the phosphor Y. Examples of resins in which phosphors are dispersed include, for instance, polycarbonate resins, polyester resins, acrylic resins, epoxy resins, silicone resins and the like.

Preferably, the wavelength conversion member 3 contains a small amount of a diffusing material, together with the phosphors. Examples of the diffusing material include inorganic light diffusing materials, organic light diffusing materials and bubbles. Preferably, the diffusing material comprises at least one type selected from the group consisting of silica, glass, calcium carbonate, mica, crosslinked acrylic (co)polymer particles and siloxane (co)polymer particles.

The wavelength conversion member 3 is at a distance from the blue semiconductor light-emitting elements 1. Specifically, the wavelength conversion member 3 and the blue semiconductor light-emitting elements 1 are present spaced apart from each other. The gap between the wavelength conversion member 3 and the blue semiconductor light-emitting elements 1 may be a void, or may be filled with a filler. Adopting a configuration wherein a distance is kept between the wavelength conversion member 3 and the blue semiconductor light-emitting elements 1 allows suppressing degradation of the wavelength conversion member 3 and of the phosphors comprised in the wavelength conversion member, caused by heat emitted by the blue semiconductor light-emitting elements 1. The distance between the blue semiconductor light-emitting elements 1 and the wavelength conversion member 3 is preferably 10 μm or greater, yet more preferably 100 μm or greater, and particularly preferably 1.0 mm or greater. If the distance between the wavelength conversion member 3 and the blue semiconductor light-emitting elements 1 is excessively large, however, the emitting area of the wavelength conversion member increases, and the phosphor use amount increases as well. Accordingly, the distance between the wavelength conversion member 3 and the blue semiconductor light-emitting elements 1 is preferably 1.0 m or smaller, yet more preferably 500 mm or smaller, and particularly preferably 100 mm or smaller.

The light-emitting device 10 can be appropriately used as a light-emitting device that is utilized in ordinary illumination.

In the light-emitting device 10, the light-emitting device of the first to fifth embodiments of the first invention is preferably used as an ordinary illumination device that emits white light and that is provided in an ordinary illumination device. In a case where the light-emitting device 10 is used for such applications, the light emitted by the light-emitting device 10 exhibits preferably a deviation duv from the black body radiation locus of light color ranging from −0.0200 to 0.0200, and a color temperature of 1800 K or more and 7000 K or less, more preferably a color temperature of 5000 K or lower.

In particular, excellent binning characteristics are brought out in a light-emitting device that emits warm white of 2500 K or more and 3500 K or less.

The light-emitting device according to the first to fifth embodiments of the first invention emits light having high color rendering properties. In the light-emitting device of the first to fifth embodiments of the first invention, the value of the average color rendering index Ra is preferably equal to or greater than 80, more preferably equal to or greater than 82, and still more preferably equal to or greater than 85.

The light-emitting device 10 can be provided in an image display device, and be used as an image display device that emits white light. In a case where the light-emitting device 10 is used for such applications, the light emitted by the light-emitting device in the light-emitting device 10 exhibits preferably a deviation duv from the black body radiation locus of light color ranging from −0.0200 to 0.0200 and a color temperature of 5000 K or more and 20000 K or less, more preferably a color temperature of 15000 K or lower.

The light-emitting device according to the sixth to seventh embodiments of the first invention can be appropriately used as a light-emitting device utilized in ordinary illumination, or as a light-emitting device that is used in a backlight.

An ordinary illumination device comprising the light-emitting device of the sixth to seventh embodiments of the first invention is preferably an ordinary illumination device that emits white light. In a case where the ordinary illumination device is used for such applications, the light-emitting device according to the sixth to seventh embodiments of the first invention exhibits preferably a deviation duv from the black body radiation locus of light color ranging from −0.0200 to 0.0200 and a color temperature of 1800 K or more and 7000 K or less.

In a case where the light-emitting device of the sixth to seventh embodiments of the first invention is used in a backlight, the light emitted by the light-emitting device according to the sixth to seventh embodiments of the first invention has preferably a color temperature higher than 7000 K, up to 20000 K.

### EXAMPLES

The present invention will be explained next in further detail on the basis of Examples and simulations, but the present invention is not limited to the embodiments below alone.

### 1. First Embodiment

<1-1-1. Simulation 1 of Color Rendering Properties and Emission Efficiency>

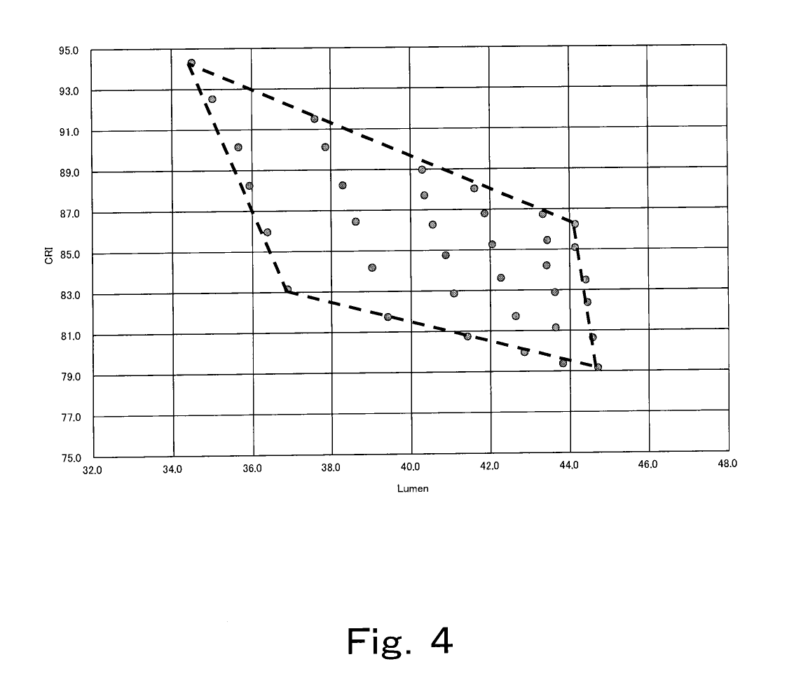

FIG. 4 and Table 3 are results of simulations, by the inventors, of instances where phosphors represented by formula (m1) are used. The figure and the table illustrate the way in which color rendering properties and emission efficiency of light emitted by the light-emitting device vary depending on the type of phosphor.

For the simulations, respective wavelength conversion members were configured using a chip having a peak wavelength of 453 nm as an excitation source, and using three types of phosphor from among four types of phosphor, namely YAG, GYAG, SCASN and CASN (relying on the actually measured data of, for instance, emission spectra of phosphors used in the Experimental Examples described below). The way in which the relationship between color rendering properties and emission efficiency varies was simulated through adjustment of the content of the phosphors, in such a manner that the emission color of the respective wavelength conversion member took on a value of 2700 K.

TABLE 3

| | | | | | Light diffusing | | | | | |
|---|---|---|---|---|---|---|---|---|---|---|
| | | | | | material | Phosphor | Luminous | | Chromaticity | |
| | | | | | concentration | concentration | flux | | coordinates | |
| | YAG | GYAG | SCASN | CASN | (wt %) | (wt %) | (lm) | Ra | x | y |
| Calculation | 0.0 | 64.0 | 0.0 | 36.0 | 1.0 | 8.46 | 34.5 | 94.3 | 0.4696 | 0.4183 |
| Example 1 | | | | | | | | | | |
| Calculation | 0.0 | 66.9 | 6.6 | 26.5 | 1.0 | 7.71 | 37.6 | 91.5 | 0.4707 | 0.4172 |
| Example 2 | | | | | | | | | | |
| Calculation | 0.0 | 70.5 | 11.8 | 17.7 | 1.0 | 7.30 | 40.3 | 89.0 | 0.4694 | 0.4202 |
| Example 3 | | | | | | | | | | |
| Calculation | 0.0 | 71.9 | 16.9 | 11.3 | 1.0 | 6.86 | 41.6 | 88.0 | 0.4703 | 0.4178 |
| Example 4 | | | | | | | | | | |
| Calculation | 0.0 | 74.8 | 20.2 | 5.0 | 1.0 | 6.66 | 43.3 | 86.7 | 0.4690 | 0.4207 |
| Example 5 | | | | | | | | | | |
| Calculation | 0.0 | 76.0 | 24.0 | 0.0 | 1.0 | 6.38 | 44.1 | 86.2 | 0.4692 | 0.4198 |
| Example 6 | | | | | | | | | | |
| Calculation | 13.1 | 52.2 | 0.0 | 34.7 | 1.0 | 8.48 | 35.0 | 92.5 | 0.4684 | 0.4185 |
| Example 7 | | | | | | | | | | |
| Calculation | 13.6 | 54.5 | 6.4 | 25.5 | 1.0 | 7.81 | 37.9 | 90.1 | 0.4705 | 0.4174 |
| Example 8 | | | | | | | | | | |
| Calculation | 14.3 | 57.2 | 11.4 | 17.1 | 1.0 | 7.50 | 40.4 | 87.7 | 0.4712 | 0.4206 |
| Example 9 | | | | | | | | | | |
| Calculation | 14.6 | 58.6 | 16.1 | 10.7 | 1.0 | 6.90 | 41.9 | 86.8 | 0.4693 | 0.4177 |
| Example 10 | | | | | | | | | | |
| Calculation | 15.2 | 60.6 | 19.4 | 4.8 | 1.0 | 6.78 | 43.4 | 85.4 | 0.4692 | 0.4204 |
| Example 11 | | | | | | | | | | |
| Calculation | 15.3 | 61.4 | 23.3 | 0.0 | 1.0 | 6.48 | 44.1 | 85.1 | 0.4698 | 0.4184 |
| Example 12 | | | | | | | | | | |
| Calculation | 26.9 | 40.4 | 0.0 | 32.6 | 1.0 | 8.72 | 35.7 | 90.1 | 0.4692 | 0.4205 |
| Example 13 | | | | | | | | | | |
| Calculation | 27.9 | 41.9 | 6.0 | 24.2 | 1.0 | 7.98 | 38.3 | 88.2 | 0.4703 | 0.4181 |
| Example 14 | | | | | | | | | | |
| Calculation | 29.1 | 43.7 | 10.9 | 16.3 | 1.0 | 7.56 | 40.6 | 86.3 | 0.4701 | 0.4186 |
| Example 15 | | | | | | | | | | |
| Calculation | 29.8 | 44.7 | 15.3 | 10.2 | 1.0 | 7.14 | 42.1 | 85.3 | 0.4700 | 0.4178 |
| Example 16 | | | | | | | | | | |
| Calculation | 30.6 | 46.0 | 18.7 | 4.7 | 1.0 | 6.96 | 43.4 | 84.2 | 0.4700 | 0.4193 |
| Example 17 | | | | | | | | | | |
| Calculation | 31.2 | 46.8 | 21.9 | 0.0 | 1.0 | 6.67 | 44.4 | 83.5 | 0.4697 | 0.4188 |
| Example 18 | | | | | | | | | | |
| Calculation | 41.4 | 27.6 | 0.0 | 31.1 | 1.0 | 8.91 | 35.9 | 88.3 | 0.4697 | 0.4194 |
| Example 19 | | | | | | | | | | |
| Calculation | 42.9 | 28.6 | 5.7 | 22.8 | 1.0 | 8.16 | 38.6 | 86.4 | 0.4707 | 0.4184 |
| Example 20 | | | | | | | | | | |
| Calculation | 44.7 | 29.8 | 10.2 | 15.3 | 1.0 | 7.85 | 40.9 | 84.7 | 0.4705 | 0.4205 |
| Example 21 | | | | | | | | | | |
| Calculation | 45.7 | 30.4 | 14.3 | 9.6 | 1.0 | 7.38 | 42.3 | 83.6 | 0.4706 | 0.4181 |
| Example 22 | | | | | | | | | | |
| Calculation | 46.9 | 31.3 | 17.5 | 4.4 | 1.0 | 7.13 | 43.6 | 82.9 | 0.4698 | 0.4187 |
| Example 23 | | | | | | | | | | |
| Calculation | 47.6 | 31.8 | 20.6 | 0.0 | 1.0 | 6.90 | 44.5 | 82.4 | 0.4702 | 0.4181 |
| Example 24 | | | | | | | | | | |
| Calculation | 56.7 | 14.2 | 0.0 | 29.1 | 1.0 | 9.11 | 36.4 | 86.0 | 0.4697 | 0.4183 |
| Example 25 | | | | | | | | | | |
| Calculation | 58.9 | 14.7 | 5.3 | 21.1 | 1.0 | 8.45 | 39.0 | 84.2 | 0.4705 | 0.4175 |
| Example 26 | | | | | | | | | | |
| Calculation | 60.9 | 15.2 | 9.6 | 14.3 | 1.0 | 8.00 | 41.1 | 82.9 | 0.4697 | 0.4178 |
| Example 27 | | | | | | | | | | |
| Calculation | 62.5 | 15.6 | 13.1 | 8.8 | 1.0 | 7.67 | 42.6 | 81.7 | 0.4695 | 0.4181 |
| Example 28 | | | | | | | | | | |
| Calculation | 63.7 | 15.9 | 16.3 | 4.1 | 1.0 | 7.43 | 43.6 | 81.1 | 0.4703 | 0.4181 |
| Example 29 | | | | | | | | | | |
| Calculation | 64.9 | 16.2 | 18.9 | 0.0 | 1.0 | 7.19 | 44.6 | 80.6 | 0.4703 | 0.4183 |
| Example 30 | | | | | | | | | | |
| Calculation | 73.4 | 0.0 | 0.0 | 26.6 | 1.0 | 9.53 | 36.9 | 83.1 | 0.4704 | 0.4187 |
| Example 31 | | | | | | | | | | |
| Calculation | 76.0 | 0.0 | 4.8 | 19.2 | 1.0 | 8.82 | 39.4 | 81.7 | 0.4699 | 0.4177 |
| Example 32 | | | | | | | | | | |
| Calculation | 78.5 | 0.0 | 8.6 | 12.9 | 1.0 | 8.40 | 41.4 | 80.7 | 0.4699 | 0.4184 |
| Example 33 | | | | | | | | | | |
| Calculation | 80.5 | 0.0 | 11.7 | 7.8 | 1.0 | 8.08 | 42.8 | 79.9 | 0.4696 | 0.4185 |
| Example 34 | | | | | | | | | | |
| Calculation | 81.8 | 0.0 | 14.5 | 3.6 | 1.0 | 7.81 | 43.8 | 79.4 | 0.4703 | 0.4185 |
| Example 35 | | | | | | | | | | |
| Calculation | 83.1 | 0.0 | 16.9 | 0.0 | 1.0 | 7.52 | 44.7 | 79.2 | 0.4691 | 0.4177 |
| Example 36 | | | | | | | | | | |

In FIG. 4, the straight line positioned on the left denotes an instance of a simulation in which three types of phosphor, namely YAG, GYAG and CASN, are used as the phosphor, and indicates that the relationship between the color rendering index (CRI) of light emitted by the light-emitting device and the luminous flux (lumen) of the light is a trade-off relationship. The straight line positioned on the right illustrates results of a simulation of an instance where three types of phosphor, namely YAG, GYAG and SCASN, are used as the phosphor, the straight line positioned at the top illustrates an instance where three types of phosphor, namely GYAG, SCASN and CASN, are used as the phosphor, and the straight line positioned at the bottom illustrates an instance where three types of phosphor, namely YAG, SCASN and CASN, are used as the phosphor. In all instances, the relationship between the color rendering index (CRI) of light emitted by the light-emitting device and the luminous flux (lumen) of the light is a trade-off relationship.

The straight line on the left and the straight line on the right represent color rendering properties and luminous flux of light emitted by a light-emitting device according to the present embodiment comprising YAG and GYAG, and it can be seen that the slopes of the left and right straight lines are steeper than those of the top straight line and the bottom straight line. It is found that although there is a trade-off relationship between the color rendering index (CRI) of light emitted by the light-emitting device and the luminous flux (lumen) of the light, the drop in luminous flux accompanying increases in color rendering properties is curtailed in the light-emitting device.

It is found that the light-emitting device according to the present embodiment comprising YAG and GYAG succeeds thus in exhibiting good binning characteristics and, additionally, in combining color rendering properties and conversion efficiency.

In the case of a light-emitting device that utilizes four types of phosphor, being a light-emitting device according to a preferred embodiment of the present embodiment, the relationship between the color rendering index (CRI) of the light emitted by the light-emitting device and the luminous flux (lumen) of the light can be set arbitrarily to lie within the range encompassed by these four straight lines. In a preferred embodiment of the present embodiment, there is enhanced as a result the degree of freedom in the selection of phosphor for producing a light-emitting device that has binning characteristics and that combines both color rendering properties and conversion efficiency.

<1-1-2. Simulation 2 of Color Rendering Properties and Emission Efficiency>

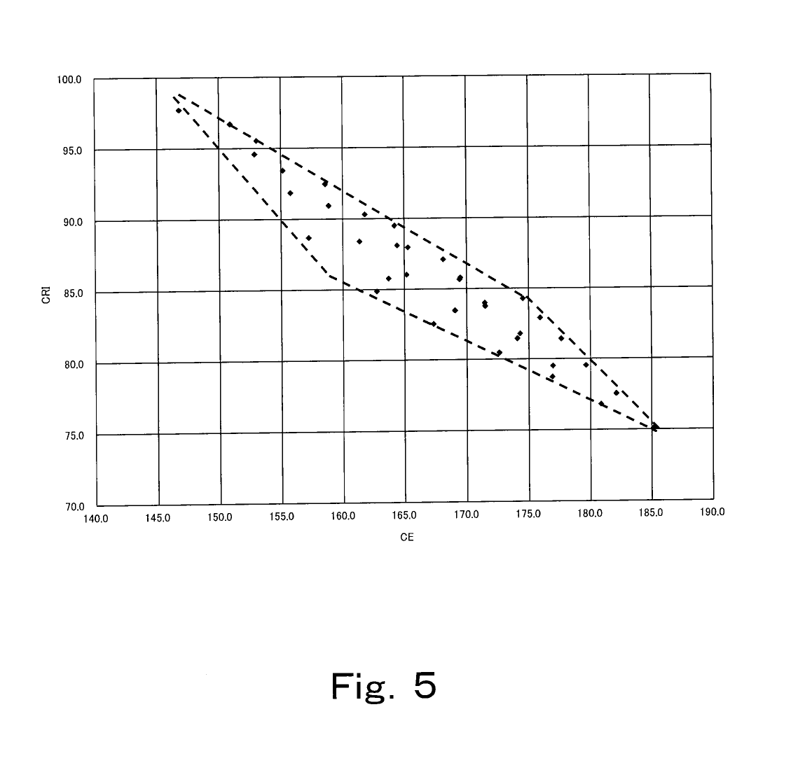

FIG. 5 and Table 4 are results of simulations, by the inventors, of instances where phosphors represented by formula (m2) are used. The figure and the table illustrate the way in which color rendering properties and emission efficiency of light emitted by the light-emitting device vary depending on the type of phosphor.

For the simulation, wavelength conversion members were configured using a chip having a peak wavelength of 453 nm as an excitation source, and using three types of phosphor from among four types of phosphor, namely YAG, LuAG, SCASN and CASN (relying on the actually measured data of, for instance, emission spectra of phosphors used in the Experimental Examples described below). The way in which the relationship between color rendering properties and emission efficiency varies was simulated through adjustment of the content of the phosphors, in such a manner that the emission color of the respective wavelength conversion member took on a value of 2700 K.

TABLE 4

| | | | | | phosphor | | | | | |
|---|---|---|---|---|---|---|---|---|---|---|
| | | | | | conc. | | | | | |
| | YAG | LuAG | SCASN | CASN | [wt %] | CE | Ra | x | y | Lumen |
| 1 | 0.0 | 89.6 | 0.0 | 10.4 | 20.97 | 146.8 | 97.7 | 0.4612 | 0.4098 | 37.2 |
| 2 | 0.0 | 89.3 | 2.1 | 8.5 | 20.82 | 150.9 | 96.7 | 0.4579 | 0.4111 | 38.3 |
| 3 | 0.0 | 88.6 | 4.6 | 6.9 | 20.71 | 152.9 | 94.6 | 0.4587 | 0.4110 | 38.8 |
| 4 | 0.0 | 87.7 | 7.4 | 4.9 | 20.53 | 155.8 | 91.8 | 0.4579 | 0.4106 | 39.5 |
| 5 | 0.0 | 86.5 | 10.8 | 2.7 | 20.52 | 157.2 | 88.7 | 0.4616 | 0.4100 | 39.9 |
| 6 | 0.0 | 86.0 | 14.0 | 0.0 | 20.39 | 162.8 | 84.9 | 0.4587 | 0.4118 | 41.3 |
| 7 | 17.9 | 71.7 | 0.0 | 10.4 | 20.97 | 153.0 | 95.5 | 0.4613 | 0.4095 | 38.8 |
| 8 | 17.8 | 71.2 | 2.2 | 8.8 | 20.88 | 155.2 | 93.4 | 0.4605 | 0.4097 | 39.3 |
| 9 | 17.7 | 70.8 | 4.6 | 6.9 | 20.78 | 158.9 | 90.9 | 0.4587 | 0.4108 | 40.3 |
| 10 | 17.5 | 70.1 | 7.4 | 4.9 | 20.64 | 161.4 | 88.4 | 0.4591 | 0.4107 | 40.9 |
| 11 | 17.3 | 69.2 | 10.8 | 2.7 | 20.39 | 163.7 | 85.8 | 0.4591 | 0.4096 | 41.5 |
| 12 | 17.1 | 68.4 | 14.4 | 0.0 | 20.24 | 167.4 | 82.5 | 0.4595 | 0.4103 | 42.4 |
| 13 | 35.9 | 53.8 | 0.0 | 10.4 | 20.93 | 158.6 | 92.4 | 0.4593 | 0.4093 | 40.2 |
| 14 | 35.7 | 53.6 | 2.1 | 8.6 | 20.99 | 161.8 | 90.3 | 0.4583 | 0.4111 | 41.0 |
| 15 | 35.4 | 53.2 | 4.6 | 6.8 | 20.94 | 164.4 | 88.1 | 0.4586 | 0.4120 | 41.7 |
| 16 | 35.0 | 52.5 | 7.5 | 5.0 | 20.86 | 165.2 | 86.0 | 0.4613 | 0.4112 | 41.9 |
| 17 | 34.7 | 52.0 | 10.6 | 2.7 | 20.65 | 169.1 | 83.4 | 0.4600 | 0.4113 | 42.9 |
| 18 | 34.3 | 51.5 | 14.2 | 0.0 | 20.47 | 172.7 | 80.5 | 0.4600 | 0.4111 | 43.8 |
| 19 | 53.9 | 35.9 | 0.0 | 10.1 | 20.87 | 164.2 | 89.5 | 0.4587 | 0.4093 | 41.6 |
| 20 | 53.4 | 35.6 | 2.2 | 8.8 | 20.91 | 165.3 | 87.9 | 0.4608 | 0.4098 | 41.9 |
| 21 | 53.2 | 35.5 | 4.5 | 6.8 | 20.79 | 169.5 | 85.8 | 0.4581 | 0.4109 | 43.0 |
| 22 | 52.7 | 35.2 | 7.3 | 4.8 | 20.73 | 171.5 | 83.7 | 0.4587 | 0.4109 | 43.5 |
| 23 | 52.1 | 34.8 | 10.5 | 2.6 | 20.61 | 174.1 | 81.4 | 0.4594 | 0.4111 | 44.1 |
| 24 | 51.5 | 34.3 | 14.2 | 0.0 | 20.54 | 176.9 | 78.7 | 0.4614 | 0.4117 | 44.9 |
| 25 | 71.7 | 17.9 | 0.0 | 10.4 | 20.60 | 168.1 | 87.1 | 0.4596 | 0.4091 | 42.6 |
| 26 | 71.1 | 17.8 | 2.2 | 8.9 | 20.63 | 169.4 | 85.6 | 0.4608 | 0.4099 | 43.0 |
| 27 | 70.5 | 17.6 | 4.7 | 7.1 | 20.58 | 171.5 | 84.0 | 0.4606 | 0.4105 | 43.5 |
| 28 | 69.9 | 17.5 | 7.5 | 5.0 | 20.55 | 174.3 | 81.8 | 0.4600 | 0.4117 | 44.2 |
| 29 | 69.2 | 17.3 | 10.8 | 2.7 | 20.48 | 176.9 | 79.5 | 0.4607 | 0.4118 | 44.9 |
| 30 | 68.5 | 17.1 | 14.4 | 0.0 | 20.29 | 180.8 | 76.8 | 0.4606 | 0.4114 | 45.9 |
| 31 | 89.9 | 0.0 | 0.0 | 10.1 | 20.25 | 174.5 | 84.3 | 0.4580 | 0.4101 | 44.3 |
| 32 | 89.2 | 0.0 | 2.2 | 8.6 | 20.29 | 175.9 | 82.9 | 0.4595 | 0.4110 | 44.6 |
| 33 | 88.4 | 0.0 | 4.7 | 7.0 | 20.28 | 177.6 | 81.4 | 0.4604 | 0.4116 | 45.0 |
| 34 | 87.5 | 0.0 | 7.5 | 5.0 | 20.22 | 179.6 | 79.5 | 0.4609 | 0.4121 | 45.6 |
| 35 | 86.5 | 0.0 | 10.8 | 2.7 | 20.09 | 182.1 | 77.5 | 0.4609 | 0.4122 | 46.2 |
| 36 | 85.4 | 0.0 | 14.6 | 0.0 | 19.88 | 185.2 | 75.1 | 0.4607 | 0.4111 | 47.0 |

In FIG. 5, the straight line positioned on the left denotes an instance of a simulation in which three types of phosphor, namely YAG, LuAG and CASN, are used as the phosphor, and indicates that the relationship between the color rendering index (CRI) of light emitted by the light-emitting device and the luminous flux (lumen) of the light is a trade-off relationship. The straight line positioned on the right illustrates results of a simulation of an instance where three types of phosphor, namely YAG, LuAG and SCASN, are used as the phosphor, the straight line positioned at the top illustrates an instance where three types of phosphor, namely LuAG, SCASN and CASN, are used as the phosphor, and the straight line positioned at the bottom illustrates an instance where three types of phosphor, namely YAG, SCASN and CASN, are used as the phosphor. In all instances, the relationship between the color rendering index (CRI) of light emitted by the light-emitting device and the luminous flux (lumen) of the light is a trade-off relationship.

The straight line on the left and the straight line on the right represent color rendering properties and luminous flux of light emitted by the light-emitting device according to the present embodiment, comprising YAG and LuAG, and it can be seen that the slopes of the left and right straight lines are steeper than those of the top straight line and the bottom straight line. It is found that although the relationship between the color rendering index (CRI) of light emitted by the light-emitting device and the luminous flux (lumen) of the light is a trade-off relationship, the drop in luminous flux accompanying increases in color rendering properties is curtailed in the light-emitting device.

It is found that the light-emitting device according to the present embodiment comprising YAG and LuAG succeeds thus in exhibiting good binning characteristics and, additionally, in combining color rendering properties and conversion efficiency.

In the case of a light-emitting device that utilizes four types of phosphor, being a light-emitting device according to a preferred embodiment of the present embodiment, the relationship between the color rendering index (CRI) of the light emitted by the light-emitting device and the luminous flux (lumen) of the light can be set arbitrarily to lie within the range encompassed by these four straight lines. In a preferred embodiment of the present embodiment, there is enhanced as a result the degree of freedom in the selection of phosphor for producing a light-emitting device that has binning characteristics and that combines both color rendering properties and conversion efficiency.

<1-2. Phosphor Synthesis>

<1-2-1. Synthesis of Phosphors GYAG 1 to 4>

Five types of phosphor (YAG, GYAG 1, GYAG 2, GYAG 3 and GYAG 4) shown in Table 6-1 were synthesized in order to measure the way in which the excitation spectrum changes as the value of c varies in phosphors represented by YₐCe_{b}Ga_{c}Al_{d}Oₑ . . . (m3), from among phosphors represented by formula (m1). Herein, a=2.94, b=0.06, c+d=5 and e=12. The synthesis method was the method by Huh et al. (Bull. Korean Chem. Soc. 2002, Vol. 23, No. 1, p. 1435-1438).

<1-2-2. Synthesis of Phosphor LuAG 1>

Herein, 409.57 g of Lu₂O₃, 180.33 g of Al₂O₃ and 10.96 g of CeO₂ of a charge composition of the respective starting materials of the phosphor, so as to yield Lu_{2.91}Ce_{0.09}Al_{5.0}O₁₂, plus 27.6 g of BaF₂ as a flux, were weighed and thoroughly stirred and mixed, and the resulting mixture was close-packed into an alumina crucible. The alumina crucible was placed in a resistance-heating electric furnace equipped with a temperature regulator, and was heated up to 1500° C. in a hydrogen-containing nitrogen atmosphere. Thereafter, the crucible was left to cool to room temperature, and the above phosphor LuAG 1 (average particle size 12 μm) was obtained through sieving and pickling in hydrochloric acid.

<1-2-3. Phosphor Synthesis LuAG 2>

Herein, 401.12 g of Lu₂O₃, 180.33 g of Al₂O₃, and 18.27 g of CeO₂ of a charge composition of the respective starting materials of the phosphor, so as to yield Lu_{2.85}Ce_{0.15}Al_{5.0}O₁₂, plus 27.6 g of BaF₂ as a flux, were weighed and thoroughly stirred and mixed, and the resulting mixture was close-packed into an alumina crucible. The alumina crucible was placed in a resistance-heating electric furnace equipped with a temperature regulator, and was heated up to 1500° C. in a hydrogen-containing nitrogen atmosphere. Thereafter, the crucible was left to cool to room temperature, and the above phosphor LuAG 2 (average particle size 9 μm) was obtained through sieving and pickling in hydrochloric acid.

<1-2-4. Synthesis of a YAG Phosphor, a GLuAG Phosphor, a SCASN Phosphor and a CASN Phosphor>

Herein, a YAG phosphor and a GLuAG phosphor were obtained in accordance with the production method disclosed in Japanese Patent Application Laid-open No. 2006-265542, a SCASN phosphor was obtained in accordance with the production method disclosed in Japanese Patent Application Laid-open No. 2008-7751, and a CASN phosphor was obtained in accordance with the production method disclosed in Japanese Patent Application Laid-open No. 2006-008721.

<1-2-5. Particle Size and Emission Peak Wavelength of the Phosphors>

Table 5 sets out the particle size and emission peak wavelengths of the phosphors synthesized in accordance with the methods above. The table illustrates GYAG 1 alone as the GYAG phosphor, and LuAG 1 alone as the LuAG phosphor.

TABLE 5

| | Particle size | Emission peak |
|---|---|---|
| Phosphor | d50 [μm] | wavelength [nm] |
| GYAG 1 | 6 | 530 |
| LuAG 1 | 9 | 540 |
| GLuAG | 15 | 510 |
| YAG | 17 | 550 |
| SCASN | 10 | 625 |
| CASN | 9 | 645 |

<1-3-1. Measurement 1 of Excitation Spectrum Intensity>

There were measured the chromaticity coordinates and peak wavelengths of the emission spectra of each of the five phosphors, i.e. the YAG phosphor and phosphors GYAG 1 to 4 synthesized as described above. The results are shown in Table 6-1.

TABLE 6-1

| | Y + | | Al + | | CIE Chromaticity | | |
|---|---|---|---|---|---|---|---|
| | Ce = 3 | | Ga = 5 | | Coordinate | | Peak |
| | Y | Ce | Al | Ga | x | y | Wavelength |
| YAG | 2.94 | 0.06 | 5 | 0 | 0.4340 | 0.5455 | 557 nm |
| GYAG 1 | 2.94 | 0.06 | 3.4 | 1.6 | 0.3718 | 0.5671 | 534 nm |
| GYAG 2 | 2.94 | 0.06 | 4 | 1 | 0.3991 | 0.5606 | 540 nm |
| GYAG 3 | 2.94 | 0.06 | 3 | 2 | 0.3575 | 0.5688 | 532 nm |
| GYAG 4 | 2.94 | 0.06 | 2.5 | 2.5 | 0.3413 | 0.5672 | 528 nm |

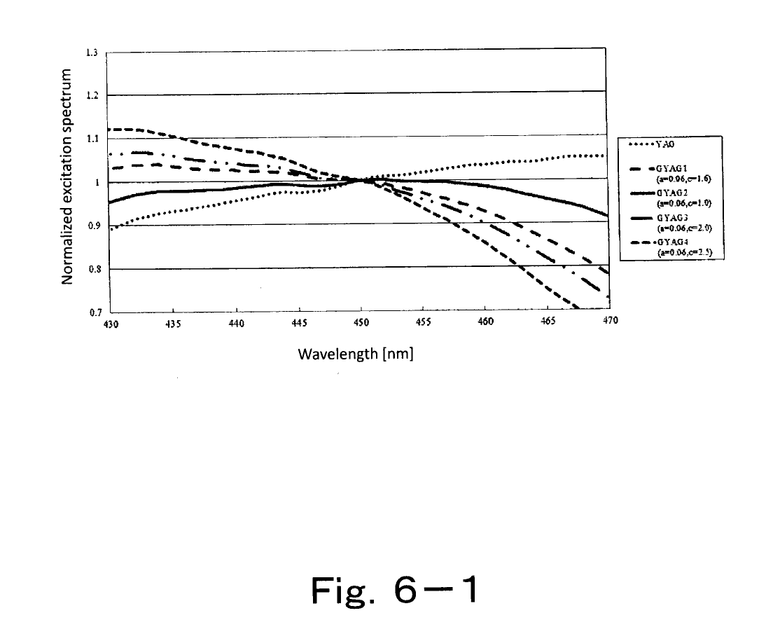

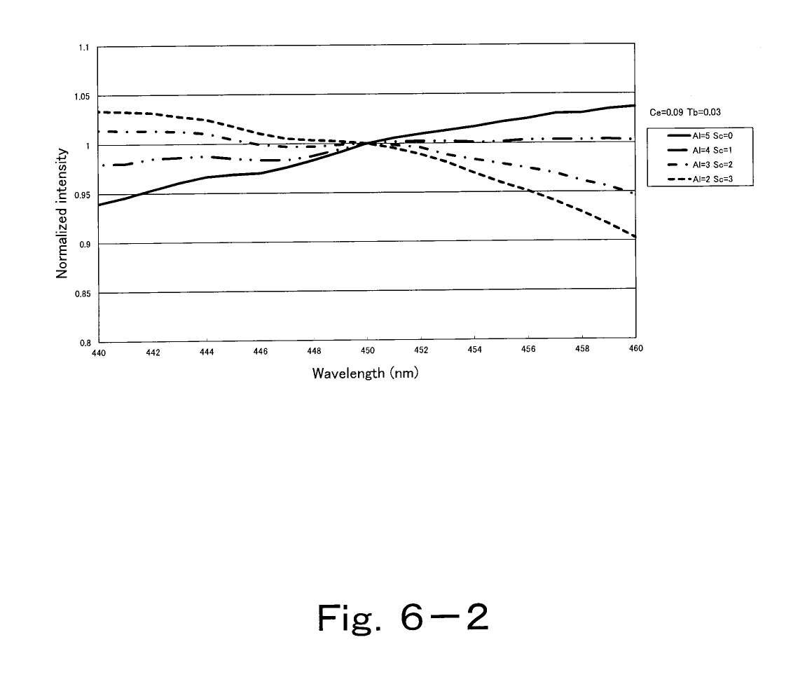

Next, the excitation spectra of the phosphor YAG and the phosphors GYAG 1 to GYAG 4 were measured using a fluorescence spectrophotometer F-4500, by Hitachi, Ltd., at room temperature (25° C.). More specifically, the emission peak at 540 nm was monitored, to obtain the excitation spectrum within the wavelength of 430 nm or more and 470 nm or less. There was further calculated the excitation spectrum intensity change upon modification of the excitation wavelength from 430 nm to 470 nm, taking 1.0 as the excitation spectrum intensity at the excitation wavelength of 450 nm. FIG. 6-1 illustrates excitation intensity change curves of the respective phosphors.

In the GYAG phosphors represented by formula (m3), as illustrated in FIG. 6-1, there is virtually no drop in the normalized excitation spectrum as the excitation wavelength lengthens, when the value of c is small, as in the case of c=1.0, and the spectrum fails to match increases in the normalized excitation spectrum of the YAG phosphor represented by formula (l). On the other hand, when c=1.6, or 2, or 2.5, the spectrum matches increases in the normalized excitation spectrum of the YAG phosphor represented by formula (l).

Accordingly, a light-emitting device excellent in binning characteristics can be provided when GYAG represented by formula (m3) of the present invention has a value of c of 1.2 or more and 2.6 or less. Preferably, the value of c is equal to or smaller than 2.4, and yet more preferably equal to or smaller than 1.8.

Next, five phosphors (SC-1, SC-2, SC-3, SC-4 and SC-5) shown in Table 6-2 below were synthesized in order to measure the way in which the excitation spectrum varied as a result of changes in the value of i, in phosphors represented by Y_{f}(Ce,Tb,Lu)_{g}GaₕScᵢAlⱼOₖ . . . (m5) from among the phosphors represented by formula (m1). A phosphor represented by composition formula Y_{2.88}Ce_{0.09}Tb_{0.03}ScᵢAlⱼO₁₂, with f=2.88, g=0.12, h=0 and k=12, was synthesized in accordance with the method by Huh et al., using Sc₂O₃ as a starting material.

The peak wavelength and chromaticity coordinates of the emission spectrum of each of the five phosphors thus synthesized were measured (Table 6-2). The normalized excitation spectrum of each phosphor upon modification of excitation light from 440 nm to 460 nm was measured and calculated. Herein relative intensity was worked out taking 1 as the intensity of normalized excitation spectrum upon excitation of the phosphor with 450 nm excitation light. The results are shown in FIG. 6-2.

TABLE 6-2

| | | | | | | Excitation wavelength | | |
|---|---|---|---|---|---|---|---|---|
| | | | | | | 455 nm | | |
| | | | | | | Emission | | |
| | | | | | | peak | Chromaticity | |
| Phosphor | Composition | | | | | wavelength | coordinates | |
| name | Y | Ce | Tb | Al | Sc | (nm) | x | y |
| SC-5 | 2.88 | 0.09 | 0.03 | 5 | 0 | 556 | 0.435 | 0.542 |
| SC-1 | 2.88 | 0.09 | 0.03 | 4 | 1 | 551 | 0.422 | 0.548 |
| SC-2 | 2.88 | 0.09 | 0.03 | 3 | 2 | 542 | 0.393 | 0.558 |
| SC-3 | 2.88 | 0.09 | 0.03 | 2 | 3 | 535 | 0.373 | 0.564 |
| SC-4 | 2.88 | 0.09 | 0.03 | 0 | 5 | 529 | 0.345 | 0.53 |

<1-3-2. Measurement 2 of Excitation Spectrum Intensity>

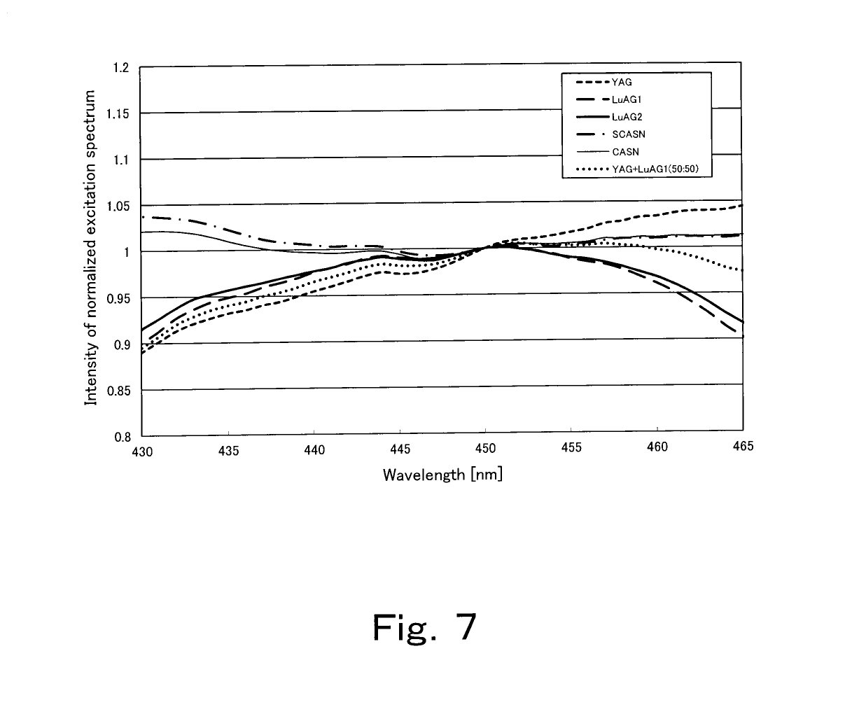

The excitation spectrum intensity change of the phosphors YAG and LuAG 1 to 2 was calculated next in the same way as above, but herein the wavelength range was caused to vary from 430 nm 465 nm. FIG. 7 illustrates excitation intensity change curves of the respective phosphors. Further, FIG. 7 illustrates a combined excitation spectrum intensity change calculated through 50:50 weighted averaging of the excitation spectrum intensities of YAG and LuAG 1 at each wavelength.

The variation in spectrum intensity of each phosphor in the range from 430 nm to 465 nm was worked out. The results are summarized in Table 7-1. The variation in spectrum intensity was calculated as maximum value−minimum value of spectrum intensity in the range from 430 nm to 465 nm, taking 1.0 as the excitation spectrum intensity at the excitation wavelength of 450 nm.

TABLE 7-1

| | | LuAG | LuAG | YAG + LuAG 1 |
|---|---|---|---|---|
| | YAG | 1 | 2 | (50:50) |
| Variation in | 15.4% | 10.2% | 8.6% | 11.1% |
| excitation spectrum | | | | |
| intensity [%] | | | | |

As FIG. 7 and Table 7-1 reveal, YAG represented by formula (l) exhibits an increase in emission intensity as the excitation wavelength increases, for an excitation wavelength from 430 nm up to 465 nm, with a variation in excitation spectrum intensity of 15.4%.

On the other hand, LuAG 1 and LuAG 2 represented by formula (m2) exhibit mountain-like excitation spectrum intensities, with a peak in the vicinity of 450 nm. The variation in excitation spectrum intensities of LuAG 1 and LuAG 2 are 10.2% and 8.6%, respectively.

The variation in spectrum intensity of the combined excitation spectrum calculated through 50:50 weighted averaging of YAG represented by formula (l) and LuAG 1 represented by formula (m2) is 11.1%.

The variation in combined excitation spectrum intensity can thus be adjusted to be equal to or smaller than 12% by incorporating the green phosphor represented by formula (X), or by concomitantly using the green phosphor and the yellow phosphor represented by formula (X) in certain desired proportions.

In order to adjust the variation in combined excitation spectrum intensity to be equal to or smaller than 12%, there may be used for instance the phosphor G having a variation in excitation spectrum intensity equal to or smaller than 12%.

A phosphor Y and a phosphor G having both a variation in excitation spectrum intensity equal to or smaller than 12% are preferably used if the phosphor Y is further incorporated. Alternatively, there is preferably used a phosphor Y having a maximum value of excitation spectrum intensity at 450 nm or longer, in the range from 430 nm to 465 nm, and a phosphor G having a minimum value of excitation spectrum intensity at 450 nm or longer, in the range from 430 nm to 465 nm.

1-3-3. Measurement 3 of Excitation Spectrum Intensity

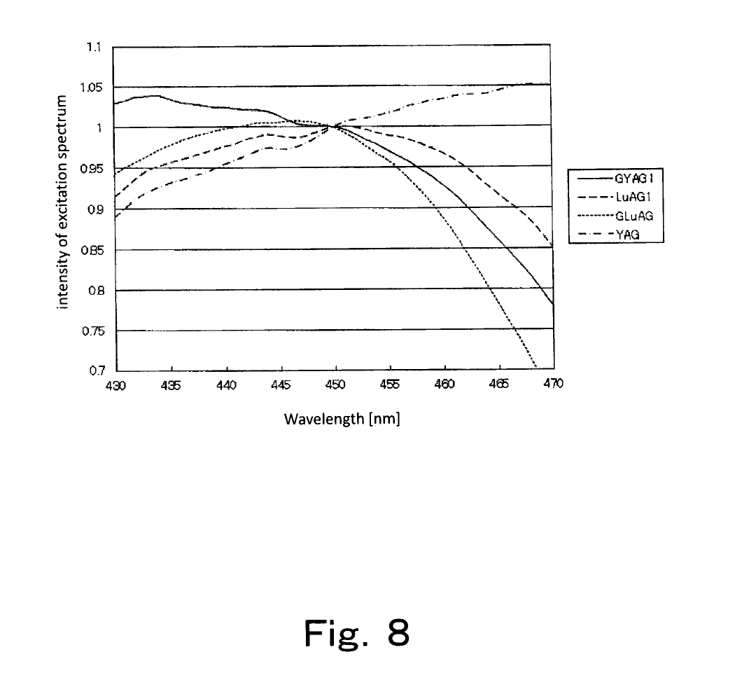

The excitation spectrum intensity change of phosphors YAG, GYAG 1 and LuAG 1 was calculated next in the same way as above, but herein the wavelength range was caused to vary from 430 nm to 470 nm. FIG. 8 illustrates excitation intensity change curves of the respective phosphors.

The variation in spectrum intensity of each phosphor in the range from 430 nm to 470 nm was worked out. The results are summarized in Table 7-2. The variation in spectrum intensity was calculated as maximum value−minimum value of spectrum intensity in the range from 430 nm to 470 nm, taking 1.0 as the excitation spectrum intensity at the excitation wavelength of 450 nm.

TABLE 7-2

| | GYAG 1 | LuAG 1 | YAG |
|---|---|---|---|
| Variation in excitation | 25.7% | 15.1% | 16.2% |
| spectrum intensity [%] | | | |

Further, Table 8 illustrates the variation in spectrum intensity of a combined excitation spectrum at each weight fraction of YAG represented by formula (l), GYAG 1 represented by formula (m1) and LuAG 1 represented by formula (m2).

The variation in spectrum intensity was calculated as maximum value−minimum value of spectrum intensity in the range from 430 nm to 470 nm, taking 1.0 as the excitation spectrum intensity at the excitation wavelength of 450 nm.

TABLE 8

| | | | Variation in combined |
|---|---|---|---|
| Phosphor weight fraction [%] | | | excitation spectrum |
| GYAG 1 | LuAG 1 | YAG | intensity [%] |
| 60 | 0 | 40 | 11.3 |
| 40 | 0 | 60 | 5.8 |
| 25 | 0 | 75 | 13.7 |
| 50 | 50 | 0 | 11.1 |

The variation in combined excitation spectrum intensity can thus be adjusted to be equal to or smaller than 15% by incorporating the GYAG phosphor represented by formula (m1), or by concomitantly using the phosphor GYAG and the phosphor Y represented by formula (l), in certain desired proportions.

In order to adjust the variation in combined excitation spectrum intensity to be equal to or smaller than 15%, there may be used for instance the phosphor G having a variation in excitation spectrum intensity equal to or smaller than 15%.

A phosphor Y and a phosphor G having both a variation in excitation spectrum intensity equal to or smaller than 15% are preferably used if a phosphor Y is incorporated. Alternatively, there is preferably used a phosphor Y having a maximum value of excitation spectrum intensity at 450 nm or longer, in the range from 430 nm to 470 nm, and a phosphor G having a minimum value of excitation spectrum intensity at 450 nm or longer, in the range from 430 nm to 470 nm.

<1-4. Production of a Wavelength Conversion Member and a Light-Emitting Device>

Phosphors were weighed and mixed, so as to yield a total amount of 10 g according to the weight ratios set forth in Phosphor Mixture Examples 1 to 11 shown in Table 9.

TABLE 9

| | Phosphor | | | | | |
|---|---|---|---|---|---|---|
| | GYAG | | | | | |
| | 1 | LuAG 1 | GLuAG | YAG | SCASN | CASN |
| Phosphor Mixture | | 66 | | 22 | | 12 |
| Example 1 | | | | | | |
| Phosphor Mixture | | 86 | | | 7 | 7 |
| Example 2 | | | | | | |
| Phosphor Mixture | 72 | | | | 6 | 22 |
| Example 3 | | | | | | |
| Phosphor Mixture | 45 | | | 30 | 25 | |
| Example 4 | | | | | | |
| Phosphor Mixture | 30 | | | 47 | 23 | |
| Example 5 | | | | | | |
| Phosphor Mixture | 15 | | | 63 | 22 | |
| Example 6 | | | | | | |
| Phosphor Mixture | 44.5 | | | 44.5 | 11 | |
| Example 7 | | | | | | |
| Phosphor Mixture | | | | 78 | 6 | 16 |
| Example 8 | | | | | | |
| Phosphor Mixture | | | | 80 | 7 | 13 |
| Example 9 | | | | | | |
| Phosphor Mixture | | | 76 | 19 | 5 | |
| Example 10 | | | | | | |
| Phosphor Mixture | 22 | | 38 | 32 | 8 | |
| Example 11 | | | | | | |

For Experimental Examples 1 to 3 and 9 to 12 in which resin A was utilized, the materials were weighed to a total weight of 10 g, in the weight ratios shown in Table 10, and were degassed and kneaded using a vacuum-degassing kneader V-mini300, by EME Co., Ltd., for 3 minutes at room temperature and at 1200 rpm, to yield respective phosphor-containing silicone resin compositions.

For Experimental Examples 4 to 8 in which resin B was utilized, the materials were weighed to a total weight of 50 g, in the weight ratios shown in Table 10, and were melt-kneaded using a Laboplastomill 10C100, mixer type (R60), by Toyo Seiki Ltd., for 5 minutes at 260° C. and at 100 rpm, to yield respective phosphor-containing polycarbonate resin compositions.

TABLE 10

| | | | Mixed | Diffusing | Diffusing | Diffusing | | |
|---|---|---|---|---|---|---|---|---|
| | | Mixture | phosphor | material | material | material | Heat stabilizer | Heat stabilizer |
| | Resin | Example | [wt %] | A [wt %] | B [wt %] | C [wt %] | A [wt %] | B [wt %] |
| Experimental | A | 1 | 11.0 | 0 | 4 | 0 | 0 | 0 |
| Example 1 | | | | | | | | |
| Experimental | A | 2 | 11.0 | 0 | 4 | 0 | 0 | 0 |
| Example 2 | | | | | | | | |
| Experimental | A | 8 | 10.0 | 0 | 4 | 0 | 0 | 0 |
| Example 3 | | | | | | | | |
| Experimental | B | 3 | 6.8 | 1 | 0 | 0 | 0.1 | 0.02 |
| Example 4 | | | | | | | | |
| Experimental | B | 4 | 6.5 | 1 | 0 | 0 | 0.1 | 0.02 |
| Example 5 | | | | | | | | |
| Experimental | B | 5 | 7.0 | 1 | 0 | 0 | 0.1 | 0.02 |
| Example 6 | | | | | | | | |
| Experimental | B | 6 | 7.4 | 1 | 0 | 0 | 0.1 | 0.02 |
| Example 7 | | | | | | | | |
| Experimental | B | 9 | 8.3 | 1 | 0 | 0 | 0.1 | 0.02 |
| Example 8 | | | | | | | | |
| Experimental | A | 7 | 5.5 | 0 | 4 | 0 | 0 | 0 |
| Example 9 | | | | | | | | |
| Experimental | A | 10 | 13.0 | 0 | 4 | 0 | 0 | 0 |
| Example 10 | | | | | | | | |
| Experimental | A | 11 | 7.8 | 0 | 4 | 0 | 0 | 0 |
| Example 11 | | | | | | | | |
| Experimental | A | 11 | 6.5 | 0 | 4 | 1 | 0 | 0 |
| Example 12 | | | | | | | | |

Resin A: OE-6336A/B, by Dow Corning Toray Co., Ltd.)
Resin B: Iupilon S3000 by Mitsubishi Engineering-Plastics Corporation
Diffusing material A: Tospearl 120 by Momentive Performance Materials Inc.
Diffusing material B: Aerosil RX-200 by Nippon Aerosil Co., Ltd.
Diffusing material C: AX-3 by Nippon Steel & Sumikin Materials Co., Ltd.
Heat stabilizer A: AO-60 by ADEKA
Heat stabilizer B: ADK STAB 2112 by ADEKA

Table 11 gives the results of a composition analysis performed on the composition of phosphor GYAG 1 above. Molar ratios were calculated on the basis of the analysis results obtained in Table 11. Table 12 summarizes the results along with the charged molar ratios.

TABLE 11
Element concentration (mass %) in sample

| | Al | Ce | Ga | Y |
|---|---|---|---|---|
| GYAG 1 | 13.5 | 1.14 | 15.6 | 38.1 |

TABLE 12
Element molar ratio

| | Al | Ce | Ga | Y |
|---|---|---|---|---|
| Charge GYAG 1 | 3.40 | 0.060 | 1.60 | 2.94 |
| GYAG 1 | 3.43 | 0.056 | 1.54 | 2.94 |

Next, the phosphor-containing silicone resin compositions of Experimental Examples 1 to 3 and 9 to 12 were molded by casting so as to achieve dimensions of diameter 62 mm, thickness 1 mm, and by heat curing at 150° C. for 5 minutes, and subsequently at 200° C. for 20 minutes, to yield test pieces for optical characteristics. The phosphor-containing polycarbonate resin compositions of Experimental Examples 4 to 8 were vacuum-dried at 120° C. for 2 hours, were then melt-pressed at 260° C. and 4 MPa, for 2 minutes, using a hot press molding machine (for instance, by Imoto Machinery Co., Ltd.), and were next cooled at 20° C. and 1 MPa, for 5 minutes, using a water-cooled press (for instance, by Imoto Machinery Co., Ltd.), to produce respective sheets having a thickness of 1.2 mm. Disc-shaped test pieces having a diameter of 15 mm were punched out of the obtained sheets.

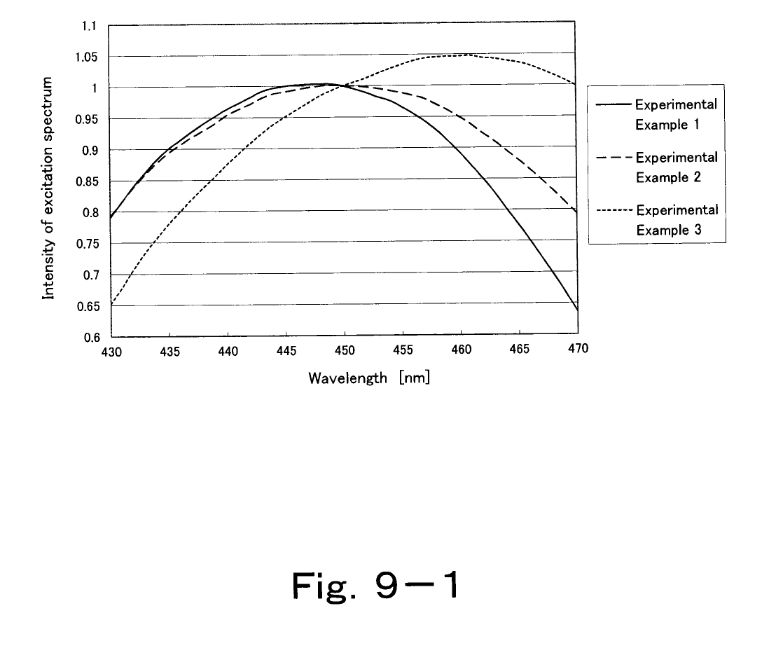

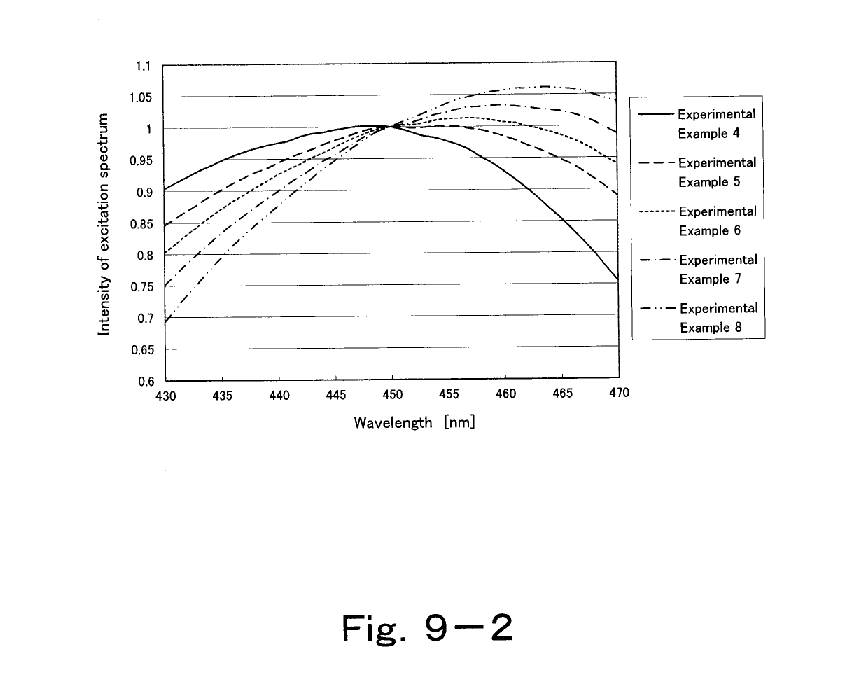

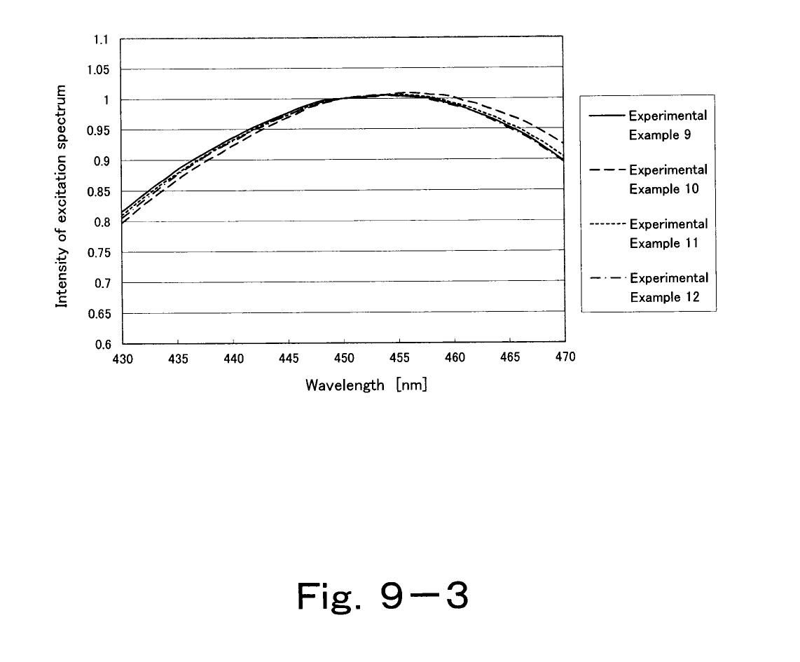

The excitation spectrum intensity, at an emission wavelength of 540 nm, of the disc-like test pieces of the obtained thickness was measured in the range from 430 nm to 470 nm using a fluorescence spectrophotometer F-4500, by Hitachi, Ltd., to calculate the variation in excitation spectrum intensity. The obtained excitation spectrum intensities are illustrated in FIGS. 9-1 to 9-3 and Table 13. Tables 14 to 16 give the respective variation in excitation spectrum intensity in the range from 435 nm to 465 nm, the range from 435 nm to 470 nm and the range from 430 nm to 465 nm, as calculated from the above spectra, for each experimental Example.

TABLE 13

| | | | | | | | | | Experi- | Experi- | Experi- | Experi- |
|---|---|---|---|---|---|---|---|---|---|---|---|---|
| Wave- | Experi- | Experi- | Experi- | Experi- | Experi- | Experi- | Experi- | Experi- | mental | mental | mental | mental |
| length | mental | mental | mental | mental | mental | mental | mental | mental | Exam- | Example | Example | Example |
| [nm] | Example 1 | Example 2 | Example 3 | Example 4 | Example 5 | Example 6 | Example 7 | Example 8 | ple 9 | 10 | 11 | 12 |
| 430 | 0.790 | 0.791 | 0.652 | 0.903 | 0.845 | 0.803 | 0.751 | 0.693 | 0.816 | 0.797 | 0.810 | 0.805 |
| 435 | 0.900 | 0.893 | 0.779 | 0.947 | 0.901 | 0.871 | 0.833 | 0.794 | 0.884 | 0.867 | 0.878 | 0.875 |
| 440 | 0.963 | 0.953 | 0.874 | 0.975 | 0.943 | 0.925 | 0.899 | 0.875 | 0.936 | 0.923 | 0.932 | 0.930 |
| 445 | 1.000 | 0.991 | 0.950 | 0.995 | 0.979 | 0.968 | 0.955 | 0.946 | 0.976 | 0.969 | 0.973 | 0.972 |
| 450 | 1.000 | 1.000 | 1.000 | 1.000 | 1.000 | 1.000 | 1.000 | 1.000 | 1.000 | 1.000 | 1.000 | 1.000 |
| 455 | 0.967 | 0.989 | 1.033 | 0.977 | 1.000 | 1.012 | 1.023 | 1.036 | 1.005 | 1.008 | 1.006 | 1.004 |
| 460 | 0.893 | 0.950 | 1.047 | 0.930 | 0.985 | 1.007 | 1.033 | 1.057 | 0.990 | 1.002 | 0.992 | 0.989 |
| 465 | 0.777 | 0.881 | 1.037 | 0.855 | 0.948 | 0.986 | 1.024 | 1.060 | 0.954 | 0.972 | 0.958 | 0.951 |
| 470 | 0.636 | 0.793 | 0.999 | 0.755 | 0.890 | 0.940 | 0.988 | 1.039 | 0.897 | 0.925 | 0.904 | 0.896 |

TABLE 14

| | | | | | | | | | Experi- | Experi- | Experi- | Experi- |
|---|---|---|---|---|---|---|---|---|---|---|---|---|
| | Experi- | Experi- | Experi- | Experi- | Experi- | Experi- | Experi- | Experi- | mental | mental | mental | mental |
| | mental | mental | mental | mental | mental | mental | mental | mental | Exam- | Exam | Example | Example |
| | Example 1 | Example 2 | Example 3 | Example 4 | Example 5 | Example 6 | Example 7 | Example 8 | ple 9 | ple 10 | 11 | 12 |
| Variation | 0.22 | 0.12 | 0.27 | 0.15 | 0.10 | 0.14 | 0.20 | 0.27 | 0.12 | 0.14 | 0.13 | 0.13 |
| in | | | | | | | | | | | | |
| excitation | | | | | | | | | | | | |
| spectrum | | | | | | | | | | | | |
| intensity | | | | | | | | | | | | |
| (%) | | | | | | | | | | | | |

TABLE 15

| | Experi- | Experi- | Experi- | Experi- | Experi- |
|---|---|---|---|---|---|
| | mental | mental | mental | mental | mental |
| | Example | Example | Example | Example | Example |
| | 4 | 5 | 6 | 7 | 8 |
| Variation | 0.25 | 0.11 | 0.14 | 0.20 | 0.27 |
| in excitation | | | | | |
| spectrum | | | | | |
| intensity (%) | | | | | |

TABLE 16

| | Experi- | Experi- | Experi- |
|---|---|---|---|
| | mental | mental | mental |
| | Example | Example | Example |
| | 1 | 2 | 3 |
| Variation | 0.21 | 0.23 | 0.38 |
| in excitation | | | |
| spectrum | | | |
| intensity (%) | | | |

<1-5. Emission Characteristics>

Further, light-emitting devices were produced in which white light could be achieved through irradiation of blue light emitted from an LED chip (peak wavelength 450 nm) onto the obtained disc-like test pieces. Emission spectra from these devices were observed using a 20-inch integrating sphere, by Sphere Optics GmbH, and a spectroscope USB2000 by Ocean Optics Inc., to calculate chromaticity, luminous flux (lumen) and Ra. The measurement results are shown in Table 17.

TABLE 17

| | | | | | | | | | Experi- | Experi- | Experi- | Experi- |
|---|---|---|---|---|---|---|---|---|---|---|---|---|
| | Experi- | Experi- | Experi- | Experi- | Experi- | Experi- | Experi- | Experi- | mental | mental | mental | mental |
| | mental | mental | mental | mental | mental | mental | mental | mental | Exam- | Example | Example | Example |
| | Example 1 | Example 2 | Example 3 | Example 4 | Example 5 | Example 6 | Example 7 | Example 8 | ple 9 | 10 | 11 | 12 |
| Lumen | 38.8 | 35.7 | 36.3 | 33.9 | 42.8 | 44.8 | 44.3 | 42.2 | 44.2 | 43.7 | 43.9 | 42.8 |
| Ra | 87 | 91 | 86 | 92 | 84 | 82 | 80 | 80 | 83 | 84 | 83 | 84 |
| CIE-x | 0.394 | 0.412 | 0.430 | 0.436 | 0.434 | 0.438 | 0.443 | 0.439 | 0.346 | 0.350 | 0.344 | 0.338 |
| CIE-y | 0.401 | 0.393 | 0.370 | 0.409 | 0.401 | 0.405 | 0.407 | 0.407 | 0.349 | 0.362 | 0.350 | 0.344 |

<1-6. Measurement of Δu′v′>

Next, the excitation light source of the light-emitting devices produced in Experimental Examples 1 to 12 was modified to a xenon spectroscopic light source, and there was measured the change Δu′v′ in chromaticity upon changing the excitation wavelength from 445 nm to 455 nm. A spectroscopic light source by Spectra Co-op was used herein, and the change in chromaticity was observed using a 20-inch integrating sphere (LMS-200), by Labsphere, Inc., and a spectroscope (Solid Lambda UV-Vis, by Carl Zeiss). Chromaticity at a respective excitation wavelength of 445 nm, 448 nm, 450 nm, 452 nm, 454 nm and 455 nm was measured, the average value (u′ₐᵥₑ, v′ₐᵥₑ) of the foregoing was calculated, and the distance to that average value was measured.

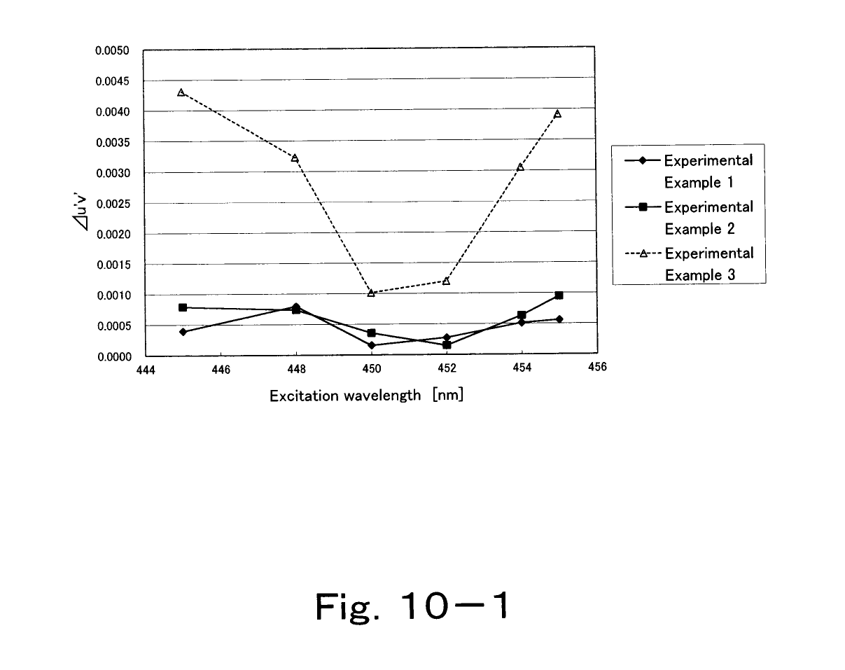

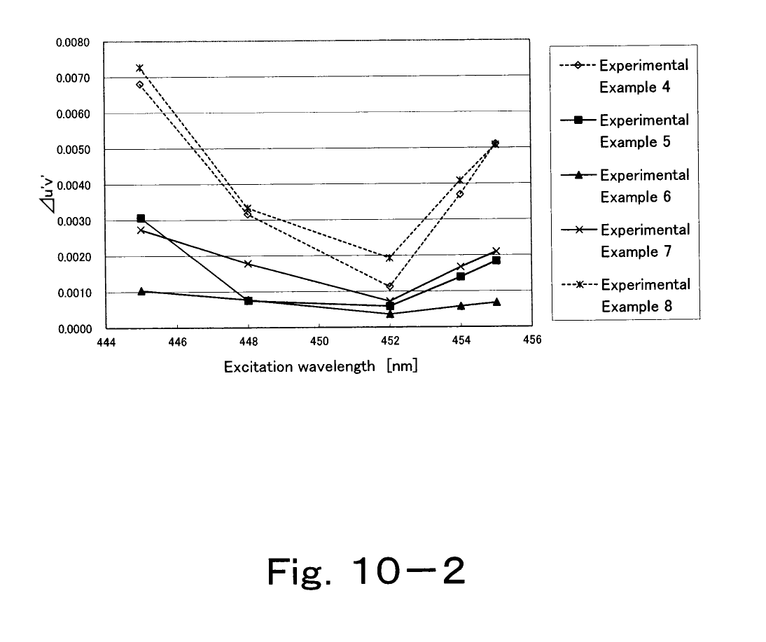

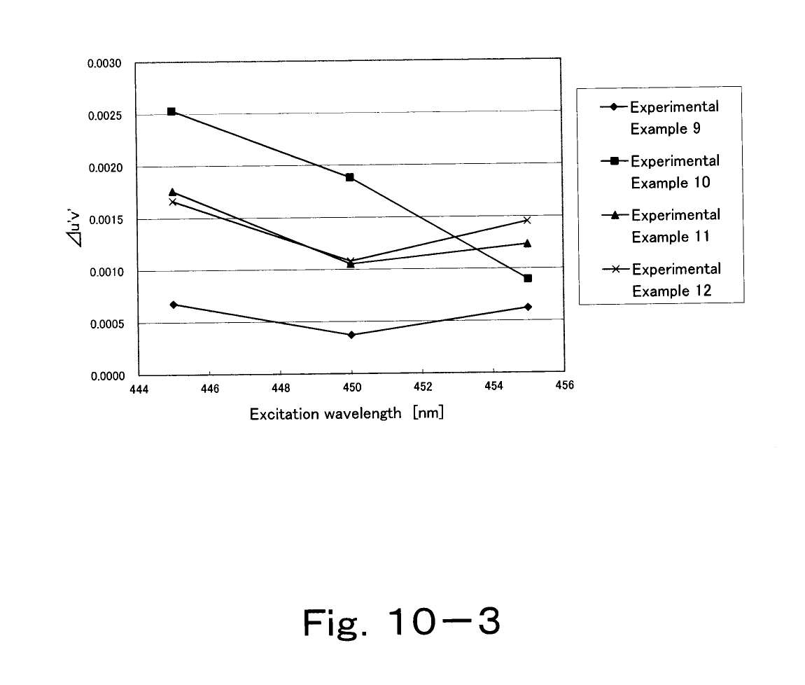

The results are shown in Table 18 and FIGS. 10-1 to 10-3.

The excitation light source of the semiconductor light-emitting devices produced in Experimental Examples 1 to 12 were modified to a xenon spectroscopic light source, and there was measured the change Δu′v′ in chromaticity upon changing the excitation wavelength from 425 nm to 475 nm. A spectroscopic light source by Spectra Co-op was used herein, and the change in chromaticity was observed using a 20-inch integrating sphere (LMS-200) by Labsphere, Inc., and a spectroscope (Solid Lambda UV-Vis, by Carl Zeiss). Chromaticity at a respective excitation wavelength of 430 nm, 440 nm, 450 nm, 460 nm and 470 nm, or an excitation wavelength of 425 nm, 435 nm, 445 nm, 455 nm, 465 nm and 475 nm, was measured, the average value (u′ₐᵥₑ, v′ₐᵥₑ) of the foregoing was calculated, and the respective distance to that average value was measured.

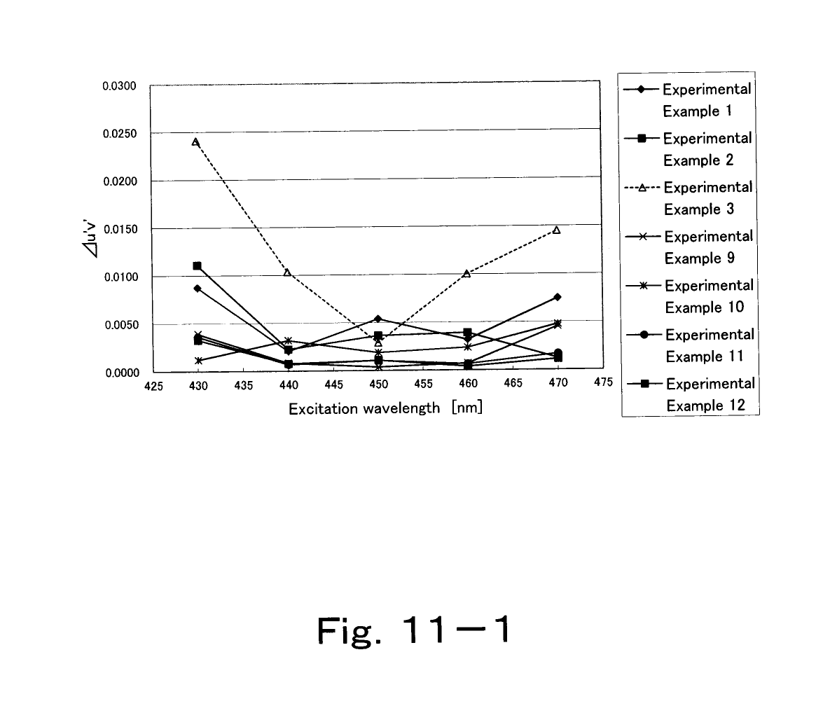

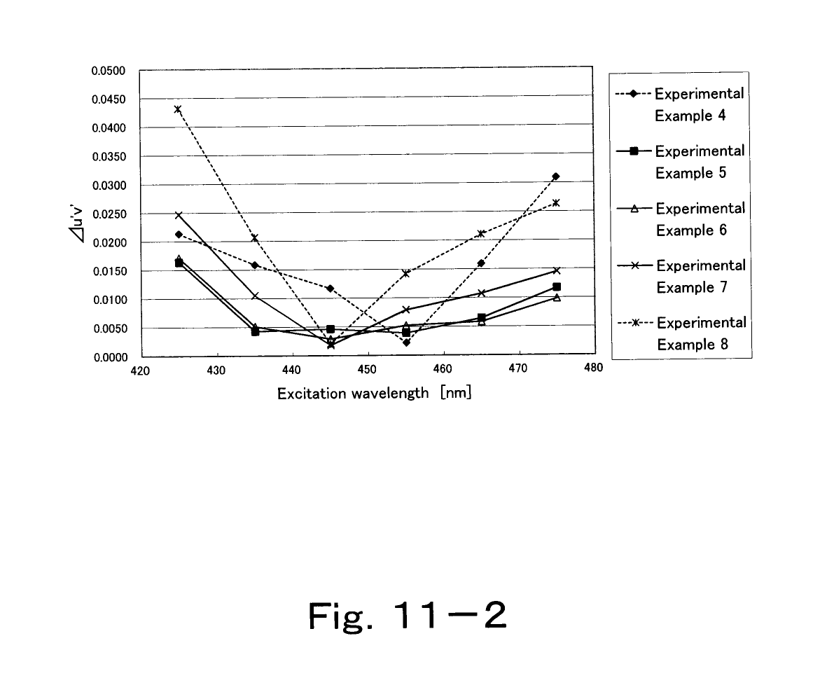

The results are shown in Tables 19 and 20, and FIGS. 11-1 and 11-2.

TABLE 18

| | | | | | | | | | Experi- | Experi- | Experi- | Experi- |
|---|---|---|---|---|---|---|---|---|---|---|---|---|
| Wave- | Experi- | Experi- | Experi- | Experi- | Experi- | Experi- | Experi- | Experi- | mental | mental | mental | mental |
| length | mental | mental | mental | mental | mental | mental | mental | mental | Exam- | Example | Example | Example |
| [nm] | Example 1 | Example 2 | Example 3 | Example 4 | Example 5 | Example 6 | Example 7 | Example 8 | ple 9 | 10 | 11 | 12 |
| 445 | 0.0004 | 0.0008 | 0.0043 | 0.0068 | 0.0031 | 0.0010 | 0.0027 | 0.0073 | 0.0007 | 0.0025 | 0.0018 | 0.0017 |
| 448 | 0.0008 | 0.0007 | 0.0032 | 0.0032 | 0.0008 | 0.0008 | 0.0018 | 0.0033 | — | — | — | — |
| 450 | 0.0002 | 0.0004 | 0.0010 | — | — | 0.0003 | — | 0.0006 | 0.0004 | 0.0019 | 0.0011 | 0.0011 |
| 452 | 0.0003 | 0.0001 | 0.0012 | 0.0011 | 0.0006 | 0.0004 | 0.0007 | 0.0019 | — | — | — | — |
| 454 | 0.0005 | 0.0006 | 0.0031 | 0.0037 | 0.0014 | 0.0006 | 0.0017 | 0.0041 | — | — | — | — |
| 455 | 0.0006 | 0.0009 | 0.0039 | 0.0051 | 0.0018 | 0.0007 | 0.0021 | 0.0051 | 0.0006 | 0.0009 | 0.0012 | 0.0015 |

TABLE 19

| | | | | | Experimental | Experimental | Experimental |
|---|---|---|---|---|---|---|---|
| Wavelength | Experimental | Experimental | Experimental | Experimental | Example | Example | Example |
| [nm] | Example 1 | Example 2 | Example 3 | Example 9 | 10 | 11 | 12 |
| 430 | 0.0087 | 0.0111 | 0.0241 | 0.0039 | 0.0012 | 0.0036 | 0.0033 |
| 440 | 0.0021 | 0.0023 | 0.0104 | 0.0008 | 0.0032 | 0.0007 | 0.0008 |
| 450 | 0.0054 | 0.0036 | 0.0029 | 0.0004 | 0.0019 | 0.0011 | 0.0011 |
| 460 | 0.0032 | 0.0039 | 0.0100 | 0.0007 | 0.0024 | 0.0007 | 0.0004 |
| 470 | 0.0075 | 0.0012 | 0.0145 | 0.0045 | 0.0048 | 0.0017 | 0.0011 |

TABLE 20

| | Experi- | Experi- | Experi- | Experi- | Experi- |
|---|---|---|---|---|---|
| Wave- | mental | mental | mental | mental | mental |
| length | Example | Example | Example | Example | Example |
| [nm] | 4 | 5 | 6 | 7 | 8 |
| 425 | 0.0213 | 0.0164 | 0.0171 | 0.0247 | 0.0432 |
| 435 | 0.0159 | 0.0043 | 0.0051 | 0.0105 | 0.0207 |
| 445 | 0.0117 | 0.0046 | 0.0029 | 0.0018 | 0.0020 |
| 455 | 0.0022 | 0.0039 | 0.0052 | 0.0079 | 0.0142 |
| 465 | 0.0159 | 0.0064 | 0.0058 | 0.0107 | 0.0211 |
| 475 | 0.0309 | 0.0117 | 0.0098 | 0.0145 | 0.0263 |

It is found that high total luminous flux (emission efficiency) can be achieved, in the light-emitting device according to the first to fifth embodiments of the first invention, while preserving high color rendering properties. FIGS. 10-1 to 10-3 and FIGS. 11-1 to 11-2 reveal that the light-emitting device of the present invention boasts good binning characteristics.

1-7. Variation in Excitation Spectrum Intensity of a Phosphor Mixture

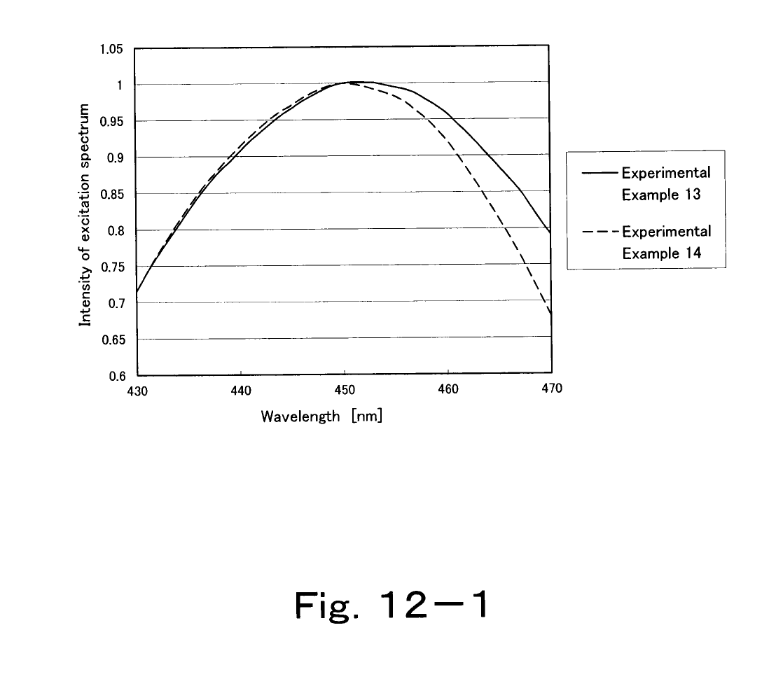

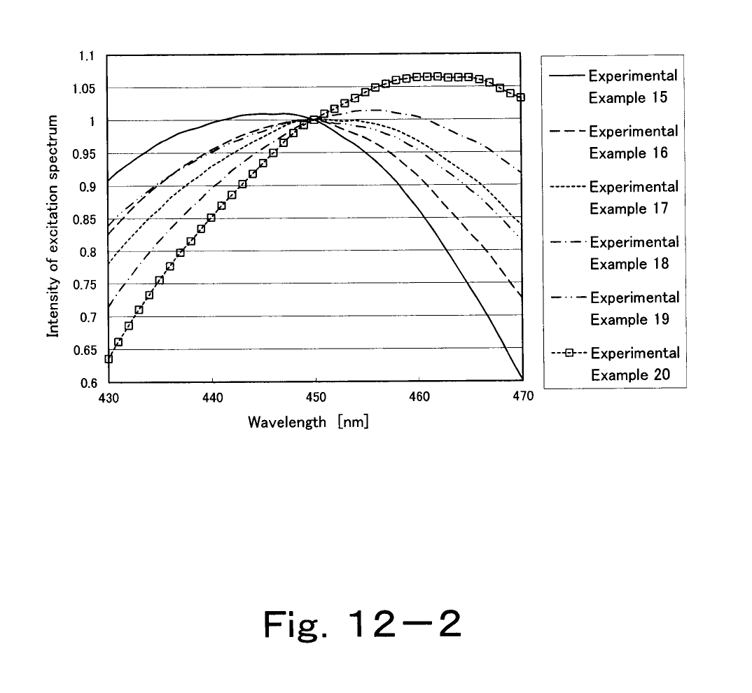

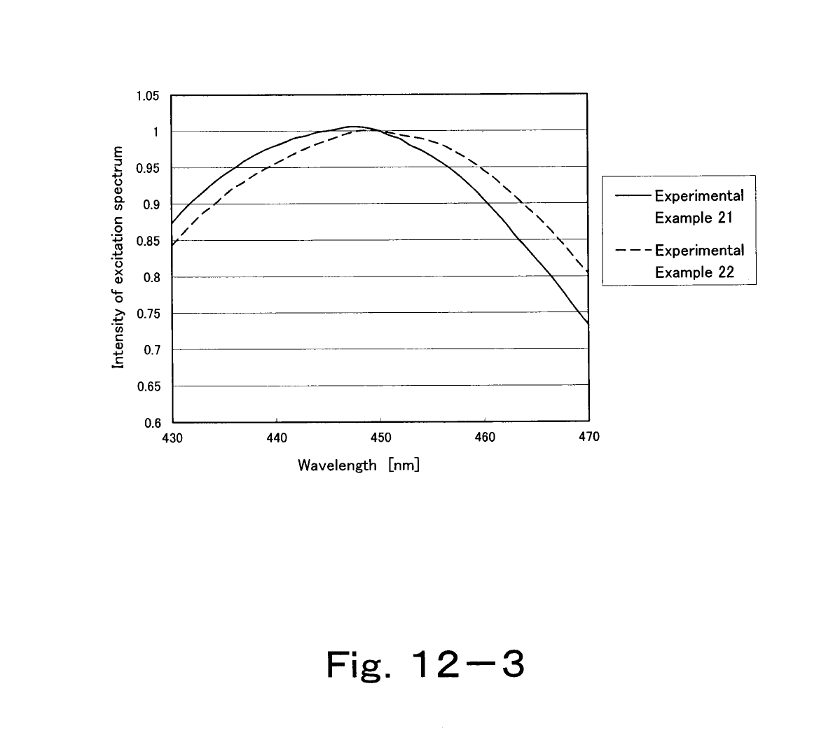

As Experimental Examples 13 to 22, phosphors were weighed and mixed, to a total amount of 1 g, according to the weight ratios in Phosphor Mixture Examples 1 to 7 and 9 to 11. The excitation spectrum intensity of respective obtained mixed powders (mixtures made up of given phosphors alone, comprising no transparent material) at the emission wavelength of 540 nm was measured in the range from 430 nm to 470 nm using a fluorescence spectrophotometer F-4500, by Hitachi, Ltd., to calculate the variation in excitation spectrum intensity. The obtained excitation spectrum intensities are illustrated in FIGS. 12-1 to 12-3 and Table 21. Table 22 sets out the variation in excitation spectrum intensity, in the range from 430 nm to 470 nm, the range from 435 nm to 470 nm and in the range from 435 nm to 465 nm, as calculated from the above spectra, for each Experimental Example.

TABLE 21

| | | | | Experi- | Experi- | Experi- | Experi- | Experi- | Experi- | Experi- | Experi- |
|---|---|---|---|---|---|---|---|---|---|---|---|
| | | Experimental | Experimental | mental | mental | mental | mental | mental | mental | mental | mental |
| | | Example | Example | Example | Example | Example | Example | Example | Example | Example | Example |
| | | 13 | 14 | 15 | 16 | 17 | 18 | 19 | 20 | 21 | 22 |
| | | Mixture | Mixture | Mixture | Mixture | Mixture | Mixture | Mixture | Mixture | Mixture | Mixture |
| | | Example 1 | Example 2 | Example 3 | Example 4 | Example 5 | Example 6 | Example 7 | Example 9 | Example 10 | Example 11 |
| Wavelength | 430 | 0.715 | 0.715 | 0.908 | 0.826 | 0.781 | 0.715 | 0.839 | 0.636 | 0.873 | 0.843 |
| [nm] | 435 | 0.824 | 0.828 | 0.965 | 0.902 | 0.864 | 0.816 | 0.905 | 0.756 | 0.939 | 0.911 |
| | 440 | 0.906 | 0.912 | 0.996 | 0.954 | 0.929 | 0.896 | 0.951 | 0.852 | 0.980 | 0.955 |
| | 445 | 0.965 | 0.969 | 1.010 | 0.988 | 0.974 | 0.957 | 0.983 | 0.934 | 1.000 | 0.987 |
| | 450 | 1.000 | 1.000 | 1.000 | 1.000 | 1.000 | 1.000 | 1.000 | 1.000 | 1.000 | 1.000 |
| | 455 | 0.995 | 0.982 | 0.949 | 0.972 | 0.996 | 1.014 | 0.988 | 1.042 | 0.965 | 0.985 |
| | 460 | 0.959 | 0.922 | 0.864 | 0.914 | 0.968 | 1.004 | 0.954 | 1.064 | 0.906 | 0.946 |
| | 465 | 0.886 | 0.815 | 0.742 | 0.826 | 0.913 | 0.969 | 0.893 | 1.064 | 0.824 | 0.884 |
| | 470 | 0.792 | 0.680 | 0.601 | 0.727 | 0.838 | 0.917 | 0.814 | 1.032 | 0.734 | 0.804 |

TABLE 22

| | Experimental Example | | | | | | | | | |
|---|---|---|---|---|---|---|---|---|---|---|
| | | | Experi- | Experi- | Experi- | Experi- | Experi- | Experi- | Experi- | Experi- |
| | Experimental | Experimental | mental | mental | mental | mental | mental | mental | mental | mental |
| | Example | Example | Example | Example | Example | Example | Example | Example | Example | Example |
| | 13 | 14 | 15 | 16 | 17 | 18 | 19 | 20 | 21 | 22 |
| | Mixture Example | | | | | | | | | |
| | Mixture | Mixture | Mixture | Mixture | Mixture | Mixture | Mixture | Mixture | Mixture | Mixture |
| | Example 1 | Example 2 | Example 3 | Example 4 | Example 5 | Example 6 | Example 7 | Example 9 | Example 10 | Example 11 |
| Variation in | 0.285 | 0.32 | 0.408 | 0.273 | 0.219 | 0.299 | 0.186 | 0.428 | 0.266 | 0.196 |
| excitation spectrum | | | | | | | | | | |
| intensity (%) at | | | | | | | | | | |
| 430 to 470 nm | | | | | | | | | | |
| Variation in | 0.208 | 0.320 | 0.408 | 0.273 | 0.162 | 0.198 | 0.186 | 0.308 | 0.266 | 0.196 |
| excitation spectrum | | | | | | | | | | |
| intensity (%) at | | | | | | | | | | |
| 435 to 470 nm | | | | | | | | | | |
| Variation in | 0.176 | 0.185 | 0.267 | 0.174 | 0.136 | 0.198 | 0.107 | 0.308 | 0.176 | 0.116 |
| excitation spectrum | | | | | | | | | | |
| intensity (%) at | | | | | | | | | | |
| 435 to 465 nm | | | | | | | | | | |

### 2. Second Embodiment

The explanation on the Examples of the first embodiment described above applies to the Examples of the present embodiment.

### 3. Third Embodiment

<3-1. Simulation of Color Rendering Properties and Emission Efficiency>

The explanation on <1-1-1. Simulation 1 of color rendering properties and emission efficiency> of the first embodiment described above applies to the present embodiment.

<3-2. Phosphor Synthesis>

The explanation in <1-2-1. Synthesis of phosphors GYAG 1 to 4> and <1-2-4. Synthesis of a YAG phosphor, a GLuAG phosphor, a SCASN phosphor and a CASN phosphor> of the first embodiment described above applies to the present embodiment.

The explanation on GYAG 1, GLuAG, YAG, SCASN and CASN set forth in <1-2-5. Particle size and emission peak wavelength of the phosphors> of the first embodiment described above applies to the particle size and the emission peak wavelength of the phosphors.

<3-3. Measurement of Excitation Spectrum Intensity>

The explanation on GYAG 1 and YAG set forth in <1-3-1. Measurement 1 of excitation spectrum intensity> and <1-3-3. Measurement 3 of excitation spectrum intensity> of the first embodiment described above applies to the present embodiment.

<3-4. Production of a Wavelength Conversion Member and a Light-Emitting Device>

The explanation on Phosphor Mixture Examples 3 to 11 and Experimental Examples 4 to 9 set forth in <1-4. Production of a wavelength conversion member and a light-emitting device> of the first embodiment described above applies to the present embodiment.

<3-5. Emission Characteristics>

The explanation on Experimental Examples 4 to 8 set forth in <1-5. Emission characteristics> of the first embodiment described above applies to the present embodiment

<3-6. Measurement of Δu′v′>

The explanation on Experimental Examples 4 to 8 set forth in <1-6. Measurement of Δu′v′> of the first embodiment described above applies to the present embodiment.

<3-7. Variation in Excitation Spectrum Intensity of a Phosphor Mixture>

The explanation on Experimental Examples 15 to 20 set forth in <1-7. Variation in excitation spectrum intensity of a phosphor mixture> of the first embodiment described above applies to the present embodiment.

### 4. Fourth Embodiment

<4-1. Simulation of Color Rendering Properties and Emission Efficiency>

The explanation in <1-1-2. Simulation 2 of color rendering properties and emission efficiency> of the first embodiment described above applies to the present embodiment.

<4-2. Phosphor Synthesis>

The explanation in <1-2-2. Phosphor synthesis LuAG 1>, <1-2-3. Phosphor synthesis LuAG 2> and <1-2-4. Synthesis of a YAG phosphor, a GLuAG phosphor, a SCASN phosphor and a CASN phosphor> of the first embodiment described above applies to the synthesis of phosphors in the present embodiment.

The explanation on LuAG 1, GLuAG, YAG, SCASN and CASN set forth in <1-2-5. Particle size and emission peak wavelength of the phosphors> of the first embodiment described above applies to the particle size and the emission peak wavelength of the phosphors.

<4-3. Measurement of Excitation Spectrum Intensity>

The explanation on LuAG 1 and YAG set forth in <1-3-2. Measurement 2 of excitation spectrum intensity> and <1-3-3. Measurement 3 of excitation spectrum intensity> of the first embodiment described above applies to the present embodiment.

<4-4. Production of a Wavelength Conversion Member and a Light-Emitting Device>

The explanation on Phosphor Mixture Examples 1, 2 and 8 to 10 and Experimental Examples 1 to 3 set forth in <1-4. Production of a wavelength conversion member and a light-emitting device> of the first embodiment described above applies to the present embodiment.

<4-5. Emission Characteristics>

The explanation on Experimental Examples 1 to 3 set forth in <1-5. Emission characteristics> of the first embodiment described above applies to the present embodiment

<4-6. Measurement of Δu′v′>

The explanation on Experimental Examples 1 to 3 set forth in <1-6. Measurement of Δu′v′> of the first embodiment described above applies to the present embodiment.

<4-7. Variation in Excitation Spectrum Intensity of a Phosphor Mixture>

The explanation on Experimental Examples 13, 14 and 20 set forth in <1-7. Variation in excitation spectrum intensity of a phosphor mixture> of the first embodiment described above applies to the present embodiment.

### 5. Fifth Embodiment

<5-1. Simulation of Color Rendering Properties and Emission Efficiency>

The explanation in <1-1-2. Simulation 2 of color rendering properties and emission efficiency> of the first embodiment described above applies to the present embodiment.

<5-2. Phosphor Synthesis>

The explanation in <1-2-2. Phosphor synthesis LuAG 1>, <1-2-3. Phosphor synthesis LuAG 2> and <1-2-4. Synthesis of a YAG phosphor, a GLuAG phosphor, a SCASN phosphor and a CASN phosphor> of the first embodiment described above applies to the synthesis of phosphors in the present embodiment.

The explanation on LuAG 1, YAG, SCASN and CASN set forth in <1-2-5. Particle size and emission peak wavelength of the phosphors> of the first embodiment described above applies to the particle size and the emission peak wavelength of the phosphors.

<5-3. Measurement of Excitation Spectrum Intensity>

The explanation on LuAG 1 and YAG set forth in <1-3-2. Measurement 2 of excitation spectrum intensity> and <1-3-3. Measurement 3 of excitation spectrum intensity> of the first embodiment described above applies to the present embodiment.

<5-4. Production of a Wavelength Conversion Member and a Light-Emitting Device>

The explanation on Phosphor Mixture Examples 1, 2 and 8 to 9 and Experimental Examples 1 to 3 set forth in <1-4. Production of a wavelength conversion member and a light-emitting device> of the first embodiment described above applies to the present embodiment.

<5-5. Emission Characteristics>

The explanation on Experimental Examples 1 to 3 set forth in <1-5. Emission characteristics> of the first embodiment described above applies to the present embodiment.

<5-6. Measurement of Δu′v′>

The explanation on Experimental Examples 1 to 3 set forth in <1-6. Measurement of Δu′v′> of the first embodiment described above applies to the present embodiment.

<5-7. Variation in Excitation Spectrum Intensity of a Phosphor Mixture>

The explanation on Experimental Example 13, 14 and 20 set forth in <1-7. Variation in excitation spectrum intensity of a phosphor mixture> of the first embodiment described above applies to the present embodiment.

### 6. Sixth Embodiment

<6-1-1. Synthesis of Phosphor GYAG 5 (Also Referred to as “Synthesis Example 1” Hereafter)>

Herein, 232.44 g of Y₂O₃, 137.04 g of Al₂O₃, 79.56 g of Ga₂O₃ and 10.96 g of CeO₂, of a charge composition of the respective starting materials of the phosphor so as to yield Y_{2.91}Ce_{0.09}Al_{3.8}Ga_{1.2}O₁₂, plus 27.6 g of BaF₂ as a flux, were weighed and thoroughly stirred and mixed, and the resulting mixture was close-packed into an alumina crucible. The alumina crucible was placed in a resistance-heating electric furnace equipped with a temperature regulator, and was heated up to 1450° C. in a hydrogen-containing nitrogen atmosphere. Thereafter, the crucible was left to cool to room temperature, and the above phosphor GYAG 5 (average particle size 15 μm) was obtained through sieving and pickling in hydrochloric acid.

<6-1-2. Synthesis of Phosphor GYAG 6 (Also Referred to as “Synthesis Example 2” Hereafter)>

A phosphor GYAG 6 (average particle size 15 m) was obtained in the same way as in Synthesis Example 1, but herein there were weighed 238.71 g of Y₂O₃, 155.56 g of Al₂O₃, 54.47 g of Ga₂O₃ and 11.25 g of CeO₂, of a charge composition of the starting materials of a phosphor so as to yield Y_{2.91}Ce_{0.09}Al_{4.2}Ga_{0.8}O₁₂, plus 27.6 g of BaF₂ as a flux.

<6-1-3. Synthesis of Phosphor GYAG 7 (Also Referred to as “Synthesis Example 3” Hereafter)>

A phosphor GYAG 7 (average particle size 12 μm) was obtained in the same way as in Synthesis Example 1, but herein there were weighed 245.01 g of Y₂O₃, 156.43 g Al₂O₃, 54.78 g of Ga₂O₃ and 3.77 g of CeO₂, of a charge composition of the starting materials of a phosphor, so as to yield Y_{2.97}Ce_{0.03}Al_{4.2}Ga_{0.8}O₁₂, plus 27.6 g of BaF₂ as a flux.

<6-1-4. Synthesis of Phosphor GYAG 8 (Also Referred to as “Synthesis Example 4” Hereafter)>

A phosphor GYAG 8 (average particle size 11 μm) was obtained in the same way as in Synthesis Example 1, but herein there were weighed 238.62 g of Y₂O₃, 146.58 g of Al₂O₃, 67.37 g of Ga₂O₃ and 7.42 g of CeO₂, of a charge composition of the starting materials of a phosphor, so as to yield Y_{2.94}Ce_{0.06}Al₄Ga₁O₁₂, plus 27.6 g of BaF₂ as a flux.

<6-1-5. Synthesis of a YAG Phosphor, a SCASN Phosphor and a CASN Phosphor (Among these, the Synthesis of the YAG Phosphor Will be Referred to Hereafter as “Synthesis Example 5”)>

A YAG phosphor was obtained in accordance with the production method disclosed in Japanese Patent Application Laid-open No. 2006-265542, a SCASN phosphor was obtained in accordance with the production method disclosed in Japanese Patent Application Laid-open No. 2008-7751, and a CASN phosphor was obtained in accordance with the production method disclosed in Japanese Patent Application Laid-open No. 2006-008721.

<6-2. Powder Characteristic>

Table 23 summarizes the Ga or Ce charge composition of phosphors GYAG 5 to 8 synthesized in Synthesis Examples 1 to 4, and of a YAG phosphor (BY-102 by Mitsubishi Chemical Corporation, average particle size 18 μm), along with powder characteristic results (relative luminance, emission peak, chromaticity, particle size and respective wavelength excitation intensity with 450 nm-excitation intensity set to 100%)

TABLE 23

| | | | | Emission characteristic at 450 nm | | | | | | | | |
|---|---|---|---|---|---|---|---|---|---|---|---|---|
| | | Phosphor | | excitation wavelength | | | | Particle | Excitation intensity at each | | | |
| | | composition | | Relative | Emission | | | size | wavelength, with 450 nm | | | |
| | | Y₃₋ₓCeₓGa_{y}Al_{5-y}O₁₂ | | luminance | peak | Chromaticity | | d50 | excitation intensity as 100% | | | |
| | | y | x | % | nm | CIE x | CIE y | μm | @440 nm | @445 nm | @455 nm | @460 nm |
| Synthesis | GYAG 5 | 1.2 | 0.09 | 99.2 | 545 | 0.409 | 0.555 | 16 | −1.6% | −1.0% | −0.4% | −1.5% |
| Example 1 | | | | | | | | | | | | |
| Synthesis | GYAG 6 | 0.8 | 0.09 | 98.2 | 548 | 0.422 | 0.548 | 19 | −1.0% | 0.0% | −1.1% | −3.5% |
| Example 2 | | | | | | | | | | | | |
| Synthesis | GYAG 7 | 0.8 | 0.03 | 93.3 | 531 | 0.383 | 0.568 | 15 | −0.5% | −0.3% | −0.1% | −0.4% |
| Example 3 | | | | | | | | | | | | |
| Synthesis | GYAG 8 | 1 | 0.06 | 95 | 543 | 0.397 | 0.560 | 14 | 0.7% | 0.2% | −0.9% | −2.3% |
| Example 4 | | | | | | | | | | | | |
| Synthesis | YAG | 0 | 0.06 | 100 | 555 | 0.433 | 0.545 | 18 | −4.5% | −2.7% | 1.7% | 3.4% |
| Example 5 | | | | | | | | | | | | |

(Method for Evaluating Powder Emission Characteristics)

The relative luminance, emission peak and chromaticity of the phosphors of Synthesis Examples 1 to 5 were worked out from respective emission spectra at an excitation wavelength of 450 nm, using a fluorescence spectrophotometer F-4500 by Hitachi Ltd. The relative luminance of the phosphors was set with respect to 100% as the luminance of the YAG phosphor of Synthesis Example 5.

(Method for Measuring Powder Particle Size)

Particle size and weight median diameter d50 were measured using a laser-diffraction particle size analyzer LA-300, by Horiba Ltd. Specifically, the relevant phosphor was dispersed in an aqueous solution, and the values of particle size and weight median diameter were obtained from a frequency-based particle size distribution curve measured by laser diffraction-scattering.

(Wavelength Excitation Intensities with 450 nm-Excitation Intensity as 100%)

Excitation spectra at the emission peaks of phosphors, shown in Table 23, were measured using a fluorescence spectrophotometer F-4500, by Hitachi Ltd., and there was calculated the relative excitation intensity at 440 nm to 460 nm, with the excitation intensity at 450 nm set to 100%.

As Table 23 reveals, the phosphors illustrated in Synthesis Examples 1 to 4 have stable emission spectra for excitation at 440 to 460 nm, with an excitation spectrum intensity change, in the range of wavelength 440 to 460 nm, equal to or smaller than 4.0% of the excitation light spectrum intensity at 450 nm.

<6-3. Production of a Wavelength Conversion Member>

Next, various materials (phosphors, additives, silicone resin) were weighed to a total weight of 10 g, in the weight ratios shown in Table 24, and were degassed and kneaded using a vacuum-degassing kneader V-mini300, by EME Co., Ltd., for 3 minutes at room temperature and at 1200 rpm, to yield respective phosphor-containing silicone resin compositions.

TABLE 24

| | YAG | GYAG 5 | GYAG 6 | GYAG 7 | GYAG 8 | SCASN | CASN | Additive | Resin A | Resin B |
|---|---|---|---|---|---|---|---|---|---|---|
| Experimental | 0.0 | 6.2 | 0.0 | 0.0 | 0.0 | 1.8 | 0.0 | 3.5 | 44.3 | 44.3 |
| Example 23 | | | | | | | | | | |
| Experimental | 0.0 | 0.0 | 6.2 | 0.0 | 0.0 | 1.8 | 0.0 | 3.5 | 44.3 | 44.3 |
| Example 24 | | | | | | | | | | |
| Experimental | 0.0 | 0.0 | 0.0 | 7.5 | 0.0 | 2.0 | 0.0 | 3.5 | 43.5 | 43.5 |
| Example 25 | | | | | | | | | | |
| Experimental | 0.0 | 0.0 | 0.0 | 0.0 | 6.5 | 2.0 | 0.0 | 3.5 | 44.0 | 44.0 |
| Example 26 | | | | | | | | | | |
| Experimental | 7.9 | 0.0 | 0.0 | 0.0 | 0.0 | 0.5 | 1.6 | 3.5 | 43.0 | 43.0 |
| Example 27 | | | | | | | | | | |

YAG phosphor (BY-102 by Mitsubishi Chemical Corporation, average particle size 18 μm)
GYAG 5 (phosphor disclosed in Synthesis Example 1; average particle size 15 μm)
GYAG 6 (phosphor disclosed in Synthesis Example 2; average particle size 15 μm)
GYAG 7 (phosphor disclosed in Synthesis Example 3; average particle size 12 μm)
GYAG 8 (phosphor disclosed in Synthesis Example 4; average particle size 11 μm)
SCASN phosphor (BR-102 by Mitsubishi Chemical Corporation, average particle size 8 μm)
CASN phosphor (BR-101 by Mitsubishi Chemical Corporation, average particle size 8 μm)
Additive (Aerosil, by Nippon Aerosil Co., Ltd.)
Resin A/B (OE-6336A/B, by Dow Corning Toray Co., Ltd.)

6-4. Production and Emission Characteristics of a Light-Emitting Device

Each obtained silicone resin composition was cast in a 20 mm-diameter glass vial, to yield a thickness of 1 mm, and was heat-cured at 150° C. for 5 minutes, and subsequently at 200° C. for 20 minutes, to yield a test piece (wavelength conversion member) for optical characteristics of the respective phosphor-containing silicone resin composition. Further, respective light-emitting devices were produced in which white light could be obtained through irradiation of blue light emitted from an LED chip (peak wavelength 450 nm) onto the obtained 1 mm-thick, 20 mm-diameter test pieces. Emission spectra from the devices were observed using a 20-inch integrating sphere, by Sphere Optics GmbH, and a spectroscope USB2000 by Ocean Optics Inc., to calculate chromaticity, luminous flux (lumen) and Ra. The measurement results are shown in Table 25.

TABLE 25

| | | Color | Correlated | | | | |
|---|---|---|---|---|---|---|---|
| | Lumi- | ren- | color | | | | |
| | nous | dering | tem- | | | | |
| | flux | index | perature | CIE x | CIE y | u′ | v′ |
| Experimental | 104 | 80 | 2848 | 0.452 | 0.416 | 0.255 | 0.528 |
| Example 23 | | | | | | | |
| Experimental | 105 | 78 | 2806 | 0.453 | 0.412 | 0.258 | 0.527 |
| Example 24 | | | | | | | |
| Experimental | 94 | 83 | 2750 | 0.445 | 0.390 | 0.262 | 0.517 |
| Example 25 | | | | | | | |
| Experimental | 99 | 80 | 2843 | 0.453 | 0.415 | 0.256 | 0.528 |
| Example 26 | | | | | | | |
| Experimental | 92 | 79 | 2636 | 0.457 | 0.398 | 0.267 | 0.522 |
| Example 27 | | | | | | | |

Next, the excitation spectra at 540 nm-emission of the light-emitting devices produced in Experimental Examples 23 to 27 were measured using a fluorescence spectrophotometer F-4500, by Hitachi Ltd., and there was calculated the relative excitation intensity at 430 nm to 470 nm, taking 1.0 as the excitation intensity at 450 nm.

As Table 26 illustrates, the phosphors of Experimental Examples 23 to 26 exhibit a difference between the maximum value and the minimum value of relative excitation spectrum intensity, in the wavelength range from 430 to 470 nm, equal to or smaller than 0.25, and a difference between the maximum value and the minimum value of relative excitation spectrum intensity, in the wavelength range from 440 to 460 nm, equal to or smaller than 0.13. Stable emission spectra are obtained for excitation at 430 to 470 nm. In particular, stable emission spectra are obtained for 440 to 460 nm.

TABLE 26

| | | | | | | | | | | Excitation intensity maximum value, minimum value, | | | | | |
|---|---|---|---|---|---|---|---|---|---|---|---|---|---|---|---|
| | | | | | | | | | | and difference, at each wavelength range | | | | | |
| | | | | | | | | | | 430-470 nm | | | 440-460 nm | | |
| | | | | | | | | | | | | Maximum | | | Maximum |
| | Relative excitation intensity at each wavelength | | | | | | | | | | | value − | | | value − |
| | [nm], with 1.0 as intensity at 450 nm | | | | | | | | | Maximum | Minimum | minimum | Maximum | Minimum | minimum |
| | 430 | 435 | 440 | 445 | 450 | 455 | 460 | 465 | 470 | value | value | value | value | value | value |
| Experimental | 0.98 | 1.00 | 1.01 | 1.01 | 1.00 | 0.98 | 0.94 | 0.88 | 0.80 | 1.01 | 0.80 | 0.21 | 1.01 | 0.94 | 0.07 |
| Example 23 | | | | | | | | | | | | | | | |
| Experimental | 0.92 | 0.96 | 0.98 | 0.99 | 1.00 | 1.00 | 0.98 | 0.94 | 0.88 | 1.00 | 0.88 | 0.13 | 1.00 | 0.96 | 0.04 |
| Example 24 | | | | | | | | | | | | | | | |
| Experimental | 0.95 | 0.97 | 0.99 | 1.00 | 1.00 | 0.99 | 0.96 | 0.91 | 0.85 | 1.00 | 0.85 | 0.15 | 1.00 | 0.96 | 0.04 |
| Example 25 | | | | | | | | | | | | | | | |
| Experimental | 0.91 | 0.96 | 0.99 | 1.00 | 1.00 | 0.98 | 0.94 | 0.87 | 0.78 | 1.00 | 0.78 | 0.22 | 1.00 | 0.94 | 0.06 |
| Example 26 | | | | | | | | | | | | | | | |
| Experimental | 0.70 | 0.81 | 0.89 | 0.95 | 1.00 | 1.03 | 1.05 | 1.04 | 1.00 | 1.05 | 0.70 | 0.35 | 1.05 | 0.89 | 0.16 |
| Example 27 | | | | | | | | | | | | | | | |

<6-5. Measurement of Δu′v′>

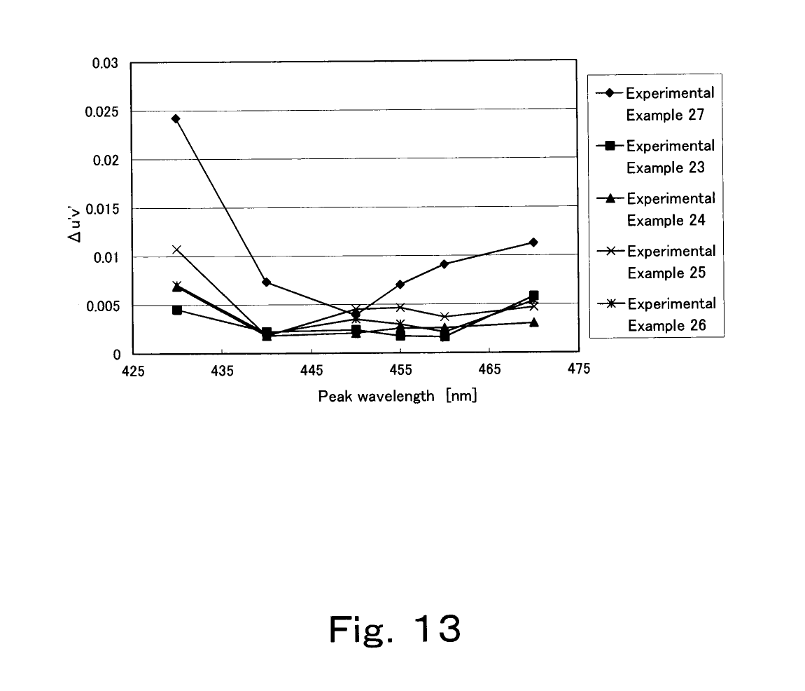

Next, the excitation light source of the light-emitting devices produced in Experimental Examples 23 to 27 was modified to a xenon spectroscopic light source, and there was measured the change Δu′v′ in chromaticity upon changing the excitation wavelength from 445 nm to 455 nm. A spectroscopic light source by Spectra Co-op was used herein, and the change in chromaticity was observed using a 20-inch integrating sphere (LMS-200) by Labsphere, Inc., and a spectroscope (Solid Lambda UV-Vis, by Carl Zeiss). The respective chromaticity and lumen value for excitation wavelengths of 445 nm, 448 nm, 450 nm, 452 nm, 454 nm and 455 nm were measured, and the average value (u′ₐᵥₑ,v′ₐᵥₑ) of chromaticity was measured, and thereafter the distance to the average value was calculated, and the relative luminance taking 1 as the lumens for an excitation wavelength of 455 nm was calculated as the lumen value. The results are shown in FIG. 13 and Table 27.

TABLE 27

| | Relative lumen value at each excitation wavelength | | | | | |
|---|---|---|---|---|---|---|
| | (taking 1 as lumen value at 455 nm excitation) | | | | | |
| | 445 | 448 | 450 | 452 | 454 | 455 |
| Experimental | 0.99 | 0.99 | 1.00 | 1.00 | 1.00 | 1.00 |
| Example 23 | | | | | | |
| Experimental | 0.99 | 0.99 | 0.99 | 1.00 | 1.00 | 1.00 |
| Example 24 | | | | | | |
| Experimental | 0.99 | 0.99 | 0.99 | 1.00 | 1.00 | 1.00 |
| Example 25 | | | | | | |
| Experimental | 0.99 | 0.99 | 1.00 | 1.00 | 1.00 | 1.00 |
| Example 26 | | | | | | |
| Experimental | 0.95 | 0.96 | 0.98 | 0.99 | 1.00 | 1.00 |
| Example 27 | | | | | | |

As Table 25, FIG. 13 and Table 26 reveal, the light-emitting devices that utilize the phosphor of the present invention exhibit high luminance and good binning characteristics.

<6-6. Wavelength Excitation Intensities Taking 1.0 as the 450 nm Excitation Intensity of a Mixed Powder>

Phosphors were weighed in a sealed container, at the blending ratios shown in Table 28, and were thoroughly stirred and mixed, to yield respective mixed phosphors.

The excitation spectra at 575 nm emission of the obtained mixed phosphors were measured using a fluorescence spectrophotometer F-4500, by Hitachi Ltd., and there was calculated the relative excitation intensity at 430 nm to 465 nm, taking 1.0 as the excitation intensity at 450 nm.

As Table 29 illustrates, the phosphors of Experimental Examples 28 to 32 exhibit a difference between the maximum value and the minimum value of relative excitation spectrum intensity, in the wavelength range from 430 to 465 nm, equal to or smaller than 0.12, and a difference between the maximum value and the minimum value of relative excitation spectrum intensity, in the wavelength range from 440 to 460 nm, equal to or smaller than 0.05. Stable emission spectra are obtained for 430 to 465 nm excitation. In particular, stable emission spectra are obtained for 440 to 460 nm.

TABLE 28

| | YAG | GYAG 5 | GYAG 6 | GYAG 7 | GYAG 8 | SCASN | CASN | Total |
|---|---|---|---|---|---|---|---|---|
| Experimental | 79 | 0 | 0 | 0 | 0 | 5 | 16 | 100 |
| Example 23 | | | | | | | | |
| Experimental | 0 | 77 | 0 | 0 | 0 | 23 | 0 | 100 |
| Example 24 | | | | | | | | |
| Experimental | 0 | 0 | 77 | 0 | 0 | 23 | 0 | 100 |
| Example 25 | | | | | | | | |
| Experimental | 0 | 0 | 0 | 79 | 0 | 21 | 0 | 100 |
| Example 26 | | | | | | | | |
| Experimental | 0 | 0 | 0 | 0 | 77 | 23 | 0 | 100 |
| Example 27 | | | | | | | | |

TABLE 29

| | | | | | | | | | Excitation intensity maximum value, minimum value, | | | | | |
|---|---|---|---|---|---|---|---|---|---|---|---|---|---|---|
| | | | | | | | | | and difference, at each wavelength range | | | | | |
| | | | | | | | | | 430-470 nm | | | 440-460 nm | | |
| | | | | | | | | | | | Maximum | | | Maximum |
| | Relative excitation intensity at each | | | | | | | | | | value − | | | value − |
| | wavelength [nm], with 1.0 as intensity at 450 nm | | | | | | | | Maximum | Minimum | minimum | Maximum | Minimum | minimum |
| | 430 | 435 | 440 | 445 | 450 | 455 | 460 | 465 | value | value | value | value | value | value |
| Experimental | 0.86 | 0.91 | 0.95 | 0.98 | 1.00 | 1.02 | 1.03 | 1.02 | 1.03 | 0.86 | 0.17 | 1.03 | 0.95 | 0.08 |
| Example 32 | | | | | | | | | | | | | | |
| Experimental | 1.05 | 1.03 | 1.01 | 1.00 | 1.00 | 1.00 | 1.00 | 0.99 | 1.05 | 0.99 | 0.06 | 1.01 | 1.00 | 0.01 |
| Example 28 | | | | | | | | | | | | | | |
| Experimental | 0.98 | 0.99 | 0.99 | 1.00 | 1.00 | 1.00 | 0.99 | 0.97 | 1.00 | 0.97 | 0.03 | 1.00 | 0.99 | 0.01 |
| Example 29 | | | | | | | | | | | | | | |
| Experimental | 0.99 | 1.00 | 1.00 | 1.00 | 1.00 | 0.99 | 0.98 | 0.95 | 1.00 | 0.95 | 0.05 | 1.00 | 0.98 | 0.02 |
| Example 30 | | | | | | | | | | | | | | |
| Experimental | 0.96 | 0.99 | 0.99 | 1.00 | 1.00 | 0.99 | 0.97 | 0.92 | 1.00 | 0.92 | 0.08 | 1.00 | 0.97 | 0.04 |
| Example 31 | | | | | | | | | | | | | | |

### 7. Seventh Embodiment

The explanation on the Examples of the sixth embodiment described above applies to the Examples of the present embodiment.

While the invention has been described in detail and with reference to specific embodiments thereof, it will be apparent to one skilled in the art that various changes and modifications can be made therein without departing from the spirit and scope thereof.

### REFERENCE SIGNS LIST

10 light-emitting device
1 blue semiconductor light-emitting element
2 wiring board
2a chip mounting surface
3 wavelength conversion member
4 frame body

1. A wavelength conversion member, comprising:
a phosphor Y represented by formula (Y2) below and having a peak wavelength of 540 nm or more and 570 nm or less in an emission wavelength spectrum when excited at 450 nm,
a phosphor G represented by formula (G2) below and having a peak wavelength of 520 nm or more and 540 nm or less in an emission wavelength spectrum when excited at 450 nm, and
a transparent material,
wherein a variation in excitation spectrum intensity of said wavelength conversion member at an emission wavelength of 540 nm is equal to or smaller than 0.20, and
said phosphor Y and said phosphor G exist in a mutual mixture throughout a light emitting part of the wavelength conversion member,
Yₐ(Ce,Tb,Lu)_{b}(Ga,Sc)_{c}Al_{d}Oₑ (Y2)
(a+b=3, 0≦b≦0.2, c+d=5, 0≦c≦0.2, e=12)
Yₐ(Ce,Tb,Lu)_{b}(Ga,Sc)_{c}Al_{d}Oₑ (G2)
(a+b=3, 0≦b≦0.2, c+d=5, 1.2≦c≦2.6, e=12)
where the variation in excitation spectrum intensity of the wavelength conversion member being expressed as the difference between a maximum value and a minimum value of excitation spectrum intensity in the range from 435 nm to 470 nm, taking 1.0 as the excitation spectrum intensity of the wavelength conversion member at 450 nm.

2. The wavelength conversion member according to claim 1,
wherein the excitation spectrum intensity at 430 nm of said phosphor Y is smaller than the excitation spectrum intensity at 470 nm, in the excitation spectrum for an emission wavelength of 540 nm, and
the excitation spectrum intensity at 430 nm of said phosphor G is greater than the excitation spectrum intensity at 470 nm, in the excitation spectrum for an emission wavelength of 540 nm.

3. The wavelength conversion member according to claim 1,
wherein a composition ratio of said phosphor Y and said phosphor G is 10:90 or more and 90:10 or less.

4. The wavelength conversion member according to claim 1,
wherein a variation in combined excitation spectrum intensity combined by calculation expression (Z) below is equal to or smaller than 0.15,
the combined excitation spectrum being an excitation spectrum in which the excitation spectrum intensity at each wavelength is expressed by calculation expression (Z) below,
Combined excitation spectrum intensity=(excitation spectrum intensity of phosphor Y)×(weight fraction of phosphor Y)+(excitation spectrum intensity of phosphor G)×(weight fraction of phosphor G) (Z),
the weight fraction of the phosphor Y being given by phosphor Y/(phosphor Y+phosphor G), and
the same applying to the variation in combined excitation spectrum intensity of the phosphor G and to the weight fraction of the phosphor G,
where the each variation in excitation spectrum intensity being expressed as the difference between a maximum value and a minimum value of the combined excitation spectrum intensity in the range from 430 nm to 470 nm, taking 1.0 as the excitation spectrum intensity at 450 nm in the excitation spectrum.

5. The wavelength conversion member according to claim 1, wherein when the excitation wavelength is caused to vary continuously from 445 nm to 455 nm, a chromaticity change Δu′v′ of light emitted by the wavelength conversion member satisfies Δu′v′≦0.004,
where the value Δu′v′ denotes a distance between chromaticity (u′ᵢ,v′ᵢ) at any wavelength i nm from 445 nm to 455 nm and an average value (u′ₐᵥₑ,v′ₐᵥₑ) of chromaticity at 445 nm to 455 nm.

6. The wavelength conversion member according to claim 1, wherein when the excitation wavelength is caused to vary continuously from 435 nm to 470 nm, a chromaticity change Δu′v′ of light emitted by the wavelength conversion member satisfies Δu′v′≦0.015,
where the value Δu′v′ denotes a distance between chromaticity (u′ᵢ,v′ᵢ) at any wavelength i nm from 435 nm to 470 nm and an average value (u′ₐᵥₑ,v′ₐᵥₑ) of chromaticity at 435 nm to 470 nm.

7. A light-emitting device, comprising the wavelength conversion member according to claim 1.

8. An illumination device, comprising the light-emitting device according to claim 7.
